(19) United States
(12) Patent Application Publication
(10) Pub. No.: US 2024/0201314 A1
(43) Pub. Date: Jun. 20, 2024

(54) AUTOMATIC LOCATION OF DEVICES OF A FACILITY

(71) Applicant: View, Inc., Milpitas, CA (US)

(72) Inventors: Feliciano Vicente Gomez-Martinez, Los Gatos, CA (US); Nitesh Trikha, Pleasanton, CA (US); Mahender Reddy Vangati, San Jose, CA (US); Sajith Kamalnath Gopinathanasari, Milpitas, CA (US); Stephen Clark Brown, San Mateo, CA (US)

(21) Appl. No.: 18/565,563

(22) PCT Filed: Jun. 10, 2022
(86) PCT No.: PCT/US2022/032993

§ 371 Date: Nov. 30, 2023

Related U.S. Application Data
(60) Provisional application No. 63/209,362, filed on Jun. 10, 2021.
(60) Provisional application No. 63/348,836, filed on Jun. 3, 2022.

(51) Int. Cl. G01S 5/02; G01S 5/14; G01S 17/87; G06F 30/20

(52) U.S. Cl. CPC G01S 5/0284; G01S 5/14; G01S 17/87; G06F 30/20

(57) ABSTRACT

The present disclosure describes methods, apparatuses, systems, program instructions, and media, concerning automatic localization and/or identification of devices disposed (e.g., during commissioning) in a facility, using various logic scheme(s). The devices may be operatively coupled to a network and/or to a control network.

### RELATED APPLICATIONS

A PCT Request Form is filed concurrently with this specification as part of the present application. Each application that the present application claims benefit of or priority to as identified in the concurrently filed PCT Request Form is incorporated by reference herein in its entirety and for all purposes. This application relates to U.S. Patent Application Ser. No. 63/109,306 filed Nov. 9, 2020, titled “ACCOUNTING FOR DEVICES IN A FACILITY.” This application is also related to U.S. patent application Ser. No. 16/946,947, filed Jul. 13, 2020, titled, “AUTOMATED COMMISSIONING OF CONTROLLERS IN A WINDOW NETWORK,” which is a National Stage of International Patent Application Serial No. PCT/US17/62634, filed Nov. 20, 2017, titled, “AUTOMATED COMMISSIONING OF CONTROLLERS IN A WINDOW NETWORK,” and is a continuation of U.S. patent application Ser. No. 16/462,916 filed May 21, 2019, titled “AUTOMATED COMMISSIONING OF CONTROLLERS IN A WINDOW NETWORK.” This application is also related to U.S. patent application Ser. No. 15/727,258, filed Oct. 6, 2017, titled, “COMMISSIONING WINDOW NETWORKS.” This application is also related to U.S. patent application Ser. No. 16/696,887 filed Nov. 26, 2019, titled “SENSING SUN RADIATION,” which is a continuation of Ser. No. 15/287,646, filed Oct. 6, 2016, titled “Multi-sensor device and system with a light diffusing element around a periphery of a ring of photosensors and an infrared sensor,” now U.S. Pat. No. 10,533,892 issued on Jan. 14, 2020. This application is also related to U.S. patent application Ser. No. 16/099,424, filed Nov. 6, 2018, titled “WINDOW ANTENNAS,” which is a National Stage Entry of International Patent Application Serial No. PCT/US17/31106, filed May 4, 2017, titled, “WINDOW ANTENNAS.” This application is also related to U.S. patent application Ser. No. 16/980,305, filed Sep. 11, 2020, titled “WIRELESSLY POWERED AND POWERING ELECTROCHROMIC WINDOWS,” which is a national entry of International Patent Application Serial No. PCT/US19/22129 filed Mar. 13, 2019, titled “WIRELESSLY POWERED AND POWERING ELECTROCHROMIC WINDOWS.” This application is also related to U.S. patent application Ser. No. 16/527,554 filed Jul. 31, 2019, titled “APPLICATIONS FOR CONTROLLING OPTICALLY SWITCHABLE DEVICES,” which is a continuation of Ser. No. 16/438,177 filed Jun. 11, 2019, titled “APPLICATIONS FOR CONTROLLING OPTICALLY SWITCHABLE DEVICES.” This application is also related to U.S. patent application Ser. No. 17/247,823 filed Dec. 23, 2020 titled “METHOD OF COMMISSIONING ELECTROCHROMIC WINDOWS,” which is a continuation of U.S. patent application Ser. No. 16/082,793 filed Sep. 6, 2018 titled “METHOD OF COMMISSIONING ELECTROCHROMIC WINDOWS,” now U.S. patent Ser. No. 10/935,864 issued Mar. 2, 2021, which is a national stage entry of PCT/US2017/020805 filed Mar. 3, 2017 titled “METHOD OF COMMISSIONING ELECTROCHROMIC WINDOWS,” which claims priority from U.S. Provisional patent application Ser. No. 62/370,174 filed Aug. 2, 2016 titled “METHOD OF COMMISSIONING ELECTROCHROMIC WINDOWS.” and from U.S. Provisional Patent Application Ser. No. 62/305,892 filed Mar. 9, 2016 titled “METHOD OF COMMISSIONING ELECTROCHROMIC WINDOWS.” This application is also related to International Patent Application Serial No. PCT/US21/12313 filed Jan. 6, 2021, titled “LOCALIZATION OF COMPONENTS IN A COMPONENT COMMUNITY,” which claims priority from U.S. Provisional patent application Ser. No. 63/133,725, filed Jan. 4, 2021, titled, “LOCALIZATION OF COMPONENTS IN A COMPONENT COMMUNITY,” from U.S. Provisional Patent Application Ser. No. 62/958,653, filed Jan. 8, 2020, titled, “Sensor Auto-location,” and from U.S. patent application Ser. No. 29/652,869, filed Dec. 22, 2020, titled “TRANSCEIVER TAG,” PCT/US21/12313 is a Continuation-in-Part of (I) U.S. patent application Ser. No. 16/696,887, filed Nov. 26, 2019, titled, “MULTI-SENSOR DEVICE AND SYSTEM WITH A LIGHT DIFFUSING ELEMENT AROUND A PERIPHERY OF A RING OF PHOTOSENSORS AND AN INFRARED SENSOR,” which claims priority to U.S. patent application Ser. No. 15/287,646, filed Oct. 6, 2016, now U.S. Pat. No. 10,533,892, issued Jan. 14, 2020, titled, “MULTI-SENSOR DEVICE AND SYSTEM WITH A LIGHT DIFFUSING ELEMENT AROUND A PERIPHERY OF A RING OF PHOTOSENSORS AND AN INFRARED SENSOR,” that is a Continuation of U.S. patent application Ser. No. 14/998,019, filed Oct. 6, 2015, now U.S. Pat. No. 10,690,540, issued Jun. 23, 2020, titled, “MULTI-SENSOR HAVING A LIGHT DIFFUSING ELEMENT AROUND A PERIPHERY OF A RING OF PHOTOSENSORS.” (II) U.S. patent application Ser. No. 17/251,100, filed Dec. 10, 2020, titled “OPTICALLY SWITCHABLE WINDOWS FOR SELECTIVELY IMPEDING PROPAGATION OF LIGHT FROM AN ARTIFICIAL SOURCE,” which claims priority to U.S. patent application Ser. No. 16/099,424, filed Nov. 6, 2018, titled, “WINDOW ANTENNAS,” which is a National Stage of International Patent Application Serial No. PCT/US17/31106, filed May 4, 2017, that claims priority to, e.g., U.S. Provisional Patent Application Ser. No. 62/379,163, filed Aug. 24, 2017, titled. WINDOW ANTENNAS,” to U.S. Provisional Patent Application Ser. No. 62/352,508, filed Jun. 20, 2016, titled, WINDOW ANTENNAS,” to U.S. Provisional Patent Application Ser. No. 62/340,936, filed May 24, 2016, titled. WINDOW ANTENNAS,” and to U.S. Provisional Patent Application Ser. No. 62/333,103, filed May 6, 2016, titled. WINDOW ANTENNAS,” (III) U.S. patent application Ser. No. 16/946,947, filed Jul. 13, 2020, titled, “AUTOMATED COMMISSIONING OF CONTROLLERS IN A WINDOW NETWORK.” which is a Continuation of U.S. patent application Ser. No. 16/462,916, filed May 21, 2019, titled, “AUTOMATED COMMISSIONING OF CONTROLLERS IN A WINDOW NETWORK,” which is a Continuation of U.S. patent application Ser. No. 16/082,793, filed Sep. 6, 2018, titled, “METHOD OF COMMISSIONING ELECTROCHROMIC WINDOWS,” which is a National Stage of International Patent Application Serial No. PCT/US17/62634 filed Nov. 20, 2017, titled, “AUTOMATED COMMISSIONING OF CONTROLLERS IN A WINDOW NETWORK,” which claims priority to, e.g., U.S. Provisional Patent Application Ser. No. 62/551,649, filed Aug. 29, 2017, titled, “AUTOMATED COMMISSIONING OF CONTROLLERS IN A WINDOW NETWORK,” and to U.S. Provisional Patent Application Ser. No. 62/426,126, filed Nov. 23, 2016, titled. “AUTOMATED COMMISSIONING OF CONTROLLERS IN A WINDOW NETWORK,” (IV) U.S. patent application Ser. No. 16/980,305, filed Sep. 11, 2020, titled. “WIRELESSLY POWERED AND POWERING ELECTROCHROMIC WINDOWS,” which is a National Stage of International Patent Application Serial No. PCT/US19/22129 filed Mar. 13, 2019, titled, “WIRELESSLY POWERED AND POWERING ELECTROCHROMIC WINDOWS,” which claims priority to U.S. Provisional Patent Application Ser. No. 62/642,478, filed Mar. 13, 2018, titled, “WIRELESSLY POWERED AND POWERING ELECTROCHROMIC WINDOWS.” (V) U.S. patent Application Ser. No. 15/727,258, filed Oct. 6, 2017 titled. “COMMISSIONING WINDOW NETWORKS,” which claims priority to, e.g., U.S. Provisional Patent Application Ser. No. 62/551,649, filed Aug. 29, 2017, titled, “AUTOMATED COMMISSIONING OF CONTROLLERS IN A WINDOW NETWORK,” and to U.S. Provisional Patent Application Ser. No. 62/426,126, filed Nov. 23, 2016, titled, “AUTOMATED COMMISSIONING OF CONTROLLERS IN A WINDOW NETWORK,” and (VI) U.S. patent application Ser. No. 17/083,128, filed Oct. 28, 2020, titled, “BUILDING NETWORK,” which is a Continuation of U.S. patent application Ser. No. 16/664,089, filed on Oct. 25, 2019, titled, “BUILDING NETWORK,” which is a National Stage of International Patent Application Serial No. PCT/US18/29460, filed Apr. 25, 2018, titled, “TINTABLE WINDOW SYSTEM FOR BUILDING SERVICES.” Each of the applications recited above is incorporated herein by reference in its entirety.

### BACKGROUND

Devices may be placed at locations in a facility, e.g., to analyze, detect and/or react to various environmental characteristics. The devices may analyze, detect and/or react to: data, temperature, humidity, sound, electromagnetic waves, position, distance, movement, speed, vibration, volatile compounds. (VOCs), dust, light, glare, color, gases, and/or other aspects of the facility. The devices may be operatively coupled to (e.g., communicatively coupled to and/or powered by) a network. A digital model and/or other file may be associated with the facility and with the devices (e.g., a Building Information Model (BIM) (e.g., Revit file or similar facility related file). The digital model and/or file may be referred to herein as a “digital twin” of the facility.

A discrepancy may exist between a requested installation location of a device and an actual installation location for that device. Such a discrepancy may arise when the locations of one or more of the devices are altered after or when the devices are placed in the facility. Such a discrepancy may arise when one or more of the devices are misplaced. For example, (e.g., generally externally identical) devices may be installed which can (e.g., only) be differentiated from one another, e.g., by consulting an external label having an inscribed serial number, bar code, Quick Response (QR) code, by interrogating a radio frequency identification (RFID) tag, and/or by acquiring other information regarding the particular serial identity of a device.

Knowing the actual (e.g., real world) installation location of a device may be important to its functionality and/or control. For example, knowledge of the actual installation location may be important in order to properly interpret and/or act upon data being acquired by the device. The location of the device may be important to its operation, control, calibration, replacement, maintenance, and/or repair. A lack of knowledge about a device's actual installation location, may make its operation, control, calibration, replacement, maintenance, and/or repair difficult to perform. A lack of knowledge about a device's actual installation location, may compromise use and/or interpretation of its data (e.g., due to misinterpretation due to different location conditions such as facility fixtures and/or non-fixtures).

The actual (e.g., real) installation location of the device may be determined and/or verified externally, e.g., by a traveler such as a person or a machine (e.g., robot such as a drone). Manually locating any misplaced device and/or updating the digital twin (e.g., solutions that are currently used) can be labor-intensive, time-consuming, expensive, and/or prone to errors, e.g., human error due to manual typing and/or judgement errors. Such effort may be increased (i) with increased number of devices, and/or (ii) with increased size and/or complexity of the facility in which the devices are located (e.g., disposed). When a location for a device is requested in advance, significant effort (e.g., labor and cost) may be required to ensure correct placement. If not requested in advance, but manually recorded afterwards, significant effort (e.g., labor, time, and/or cost) may again be required.

At least partially automating the process of locating and/or documenting the devices during and/or after the commissioning process, may afford some relief to such tasks (e.g., deployment of the devices in the facility). In order to solve for random location deviations of installed devices from their requested locations, one faces a combinatorial optimization problem. For an N-device network, there may be N! possible mappings of requested locations to actually installed locations. Exhaustive searches may not be feasible for large values of N.

### SUMMARY

Various aspects disclosed herein alleviate at least in part one or more shortcomings related to localization of one or more devices in a facility. Various aspects disclosed herein may relate to a community (e.g., assembly, group, and/or network) of components configured to analyze, detect and/or react to one or more of the characteristics of the enclosure. The components may be configured to react to various signals. The signals may comprise data (e.g., received). The signals may comprise a (e.g., digital) signal.

According to some embodiments, a method of locating devices installed in a facility, includes: a process (A), the process (A) including measuring signal-to-interference-plus-noise ratio (SINR) for signals received from each device and using the measured SINR to determine a relative location of each of the devices, a process (B), the process (B) including transmitting an incident signal onto a network comprising the devices and analyzing reflections of that signal from each of the devices using time domain reflectometry (TDR) and using the analyzed reflections to determine the relative location of each of the devices, and/or a process (C), the process (C) including (i) using a virtual model of the facility, the virtual model comprising virtual devices disposed in virtual locations corresponding to planned locations of the devices in the facility, wherein each virtual device corresponds to a respective installed device: (ii) identifying actual distances between one or more pairs of installed devices: (iii) comparing the actual distances identified to the virtual locations using a heuristic: and (iv) matching between the virtual locations and an estimate of the real locations of the devices at least in part by using the heuristic.

In some examples one or more of the devices may be a window controller for a tintable window. In some examples, the method may include determining differences between an as-built arrangement of at least a portion of the network with an as-designed arrangement of the portion of the network. In some examples the determining differences includes using network diagnostics available from the window controller.

In some examples the method may include process (C) and one or both of process (A) and/or process (B). In some examples, the signals received from each device may be received by way of a trunk line that couples each device in a network. In some examples, the method may further include using virtual device pair distances to identify a characteristic virtual distance and utilizing the characteristic virtual distance to identify a match between (i) two real devices located at a distance that is precisely or substantially equal to the characteristic virtual distance, and (ii) two virtual devices located at a distance of the characteristic virtual distance. In some examples, the method may further include using the actual distances identified between each pair of the installed devices to calculate real locations of each pair of the installed devices. In some examples, the heuristic may include a computation scheme utilizing digital matrices. In some examples, the heuristic may include a computational scheme that includes a combinatorial solution, a discrete solution, recursive computation, mathematical induction, mathematical optimization, and/or a decision tree. In some examples, the heuristic may include using a computational scheme that includes computing sub-solutions for providing a solution for matching between the virtual distances and the actual distances of the devices by (i) utilizing computational stages each computing the sub-solutions to determine the solution, and (ii) making an optimal choice in each of the computational stages to compute a corresponding sub-solution of the solution. In some examples the computational scheme may include a candidate set from which the solution is created, the candidate set comprising Building Information Modeling data. In some examples, the computational scheme may include providing a solution for matching between the virtual locations and the actual distances of the devices, the providing a solution including representing a set of candidate solutions using a decision tree structure having a plurality of branches comprising a solution space. In some examples the method may further include formulating an initial estimate for a solution, partitioning a solution space into a plurality of subsets, and discarding all subsets that have a less accurate approximation for the solution than the initial estimate. In some examples, the heuristic may include a combination of computational schemes, the combination providing a solution for matching between the virtual locations and the actual distances of the devices by making a local best choice for each of a plurality of sub-solutions of the solution.

In some examples, the method may further include measuring the actual distances using Ultra Wideband (UWB), Global Positioning System (GPS), Radio Frequency Identification (RFID), a communication link that operates in the frequency of from about 2.4 Gigahertz (GHz) to 2.48 GHz radio band, and/or any other geolocation technology.

In some examples, the method may include one or both of process (A) and/or process (B). In some examples, the devices may be communicatively coupled by a network with a control panel or network controller, the network comprising a trunk line that couples the control panel and/or the network controller with each device. In some examples, the method may include process (A) and process (B).

In some examples, the facility comprises one or more buildings.

According to some embodiments, a system for locating devices installed in a facility includes a plurality of devices within a network and a processor configured to control, or direct control of: a process (A), the process (A) including measuring signal-to-interference-plus-noise ratio (SINR) for signals received from each device and using the measured SINR to determine a relative location of each of the devices, a process (B), the process (B) including transmitting an incident signal onto a network comprising the devices and analyzing reflections of that signal from each of the devices using time domain reflectometry (TDR) and using the analyzed reflections to determine the relative location of each of the devices: and/or a process (C), the process (C) including (i) using a virtual model of the facility, the virtual model comprising virtual devices disposed in virtual locations corresponding to planned locations of the devices in the facility, wherein each virtual device corresponds to a respective installed device: (ii) identifying actual distances between one or more pairs of installed devices: (iii) comparing the actual distances identified to the virtual locations using a heuristic: and (iv) matching between the virtual locations and an estimate of the real locations of the devices at least in part by using the heuristic.

In some examples, one or more of the plurality of devices may be a window controller for a tintable window.

In some examples, the processor may be further configured to determine differences between an as-built arrangement of at least a portion of the network with an as-designed arrangement of the portion of the network.

In some examples, the processor may be configured to control, or direct control of, process (C) and one or both of process (A) and/or process (B). In some examples, the processor may be further configured to use virtual device pair distances to identify a characteristic virtual distance and utilize the characteristic virtual distance to identify a match between (i) two real devices located at a distance that is precisely or substantially equal to the characteristic virtual distance, and (ii) two virtual devices located at a distance of the characteristic virtual distance. In some examples, the processor may be further configured to use the actual distances identified between each pair of the installed devices to calculate real locations of each pair of the installed devices. In some examples, the heuristic may include a computational scheme that includes a combinatorial solution, a discrete solution, recursive computation, mathematical induction, mathematical optimization, and/or a decision tree. In some examples, the heuristic may include using a computational scheme that includes computing sub-solutions for providing a solution for matching between the virtual distances and the actual distances of the devices by (i) utilizing computational stages each computing the sub-solutions to determine the solution, and (ii) making an optimal choice in each of the computational stages to compute a corresponding sub-solution of the solution. In some examples, the computational scheme may include one or both of a feasibility function for determining when a candidate of the candidate set can be used to contribute to the solution and/or an objective function for assigning a value to each of the sub-solutions. In some examples, the processor may be further configured to locate a specific signature corresponding to a respective one of the virtual devices, and the specific signature may include the respective one of the virtual device being situated to form a numerical series with reference to distances of one or more other virtual devices and/or one or more other real devices. In some examples, the numerical series may include a Fibonacci, square, cubed, telescopic, triangular, geometric, twin, or an arithmetic series. In some examples, the heuristic may include a combination of computational schemes, the combination providing a solution for matching between the virtual locations and the actual distances of the devices by making a local best choice for each of a plurality of sub-solutions of the solution.

In some examples, the processor may be configured to control, or direct control of, one or both of process (A) and/or process (B).

In some examples, the processor may be configured to control, or direct control or, process (A) and process (B).

According to some implementations, an apparatus for locating devices in a facility includes at least one controller having circuitry, wherein the at least one controller is configured to control, or direct control of: a process (A), the process (A) including measuring signal-to-interference-plus-noise ratio (SINR) for signals received from each device and using the measured SINR to determine a relative location of each of the devices: a process (B), the process (B) including transmitting an incident signal onto a network comprising the devices and analyzing reflections of that signal from each of the devices using time domain reflectometry (TDR) and using the analyzed reflections to determine the relative location of each of the devices: and/or a process (C), the process (C) including (i) using a virtual model of the facility, the virtual model comprising virtual devices disposed in virtual locations corresponding to planned locations of the devices in the facility, wherein each virtual device corresponds to a respective installed device: (ii) identifying actual distances between one or more pairs of installed devices: (iii) comparing the actual distances identified to the virtual locations using a heuristic: and (iv) matching between the virtual locations and an estimate of the real locations of the devices at least in part by using the heuristic.

In some examples, one or more of the devices may be a window controller for a tintable window.

In some examples, the at least one controller may be configured to determine differences between an as-built arrangement of at least a portion of the network with an as-designed arrangement of the portion of the network.

In some examples, the at least one controller may be configured to control, or direct control of, process (C) and one or both of process (A) and/or process (B). In some examples, the at least one controller may be further configured to use virtual device pair distances to identify a characteristic virtual distance and utilize the characteristic virtual distance to identify a match between (i) two real devices located at a distance that is precisely or substantially equal to the characteristic virtual distance, and (ii) two virtual devices located at a distance of the characteristic virtual distance. In some examples, the at least one controller may be further configured use the actual distances identified between each pair of the installed devices to calculate real locations of each pair of the installed devices. In some examples, the at least one controller may be further configured to locate a specific signature corresponding to a respective one of the virtual devices and the specific signature comprises the respective one of the virtual device being situated to form a numerical series with reference to distances of one or more other virtual devices and/or one or more other real devices.

In some examples, the at least one controller may be further configured to control, or direct control of, one or both of process (A) and/or process (B).

In some examples, the at least one controller may be further configured to control, or direct control or, process (A) and process (B).

According to some implementations, a computer readable medium includes program instructions stored thereon for locating devices in a facility and the instructions, when executed by one or more processors cause the one or more processors to execute one or more processes, including a process (A), the process (A) including measuring signal-to-interference-plus-noise ratio (SINR) for signals received from each device and using the measured SINR to determine a relative location of each of the devices, a process (B), the process (B) including transmitting an incident signal onto a network comprising the devices and analyzing reflections of that signal from each of the devices using time domain reflectometry (TDR) and using the analyzed reflections to determine the relative location of each of the devices, and/or a process (C), the process (C) including (i) using a virtual model of the facility, the virtual model comprising virtual devices disposed in virtual locations corresponding to planned locations of the devices in the facility, wherein each virtual device corresponds to a respective installed device: (ii) identifying actual distances between one or more pairs of installed devices: (iii) comparing the actual distances identified to the virtual locations using a heuristic: and (iv) matching between the virtual locations and an estimate of the real locations of the devices at least in part by using the heuristic.

In some examples, wherein one or more of the devices may be a window controller for a tintable window.

In some examples, the instructions may be configured to cause the one or more processors to determine differences between an as-built arrangement of at least a portion of the network with an as-designed arrangement of the portion of the network.

In some examples, the instructions may be configured to cause the one or more processors to execute process (C) and one or both of process (A) and/or process (B).

In some examples, the instructions may be configured to cause the one or more processors to execute one or both of process (A) and/or process (B).

In some examples, the instructions may be configured to cause the one or more processors to execute process (A) and process (B).

The content of this summary section is provided as a simplified introduction to the disclosure and is not intended to be used to limit the scope of any invention disclosed herein or the scope of the appended claims.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

These and other features and embodiments will be described in more detail with reference to the drawings.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings or figures (also “Fig.” and “Figs.” herein), of which:

FIG. 1 schematically shows a control system for a building:

FIG. 2 schematically depicts a control system architecture and perspective view of a building:

FIG. 3 delineates examples of components and possible uses thereof:

FIG. 4 delineates examples of components and possible uses thereof:

FIG. 5 depicts a hierarchal structure in which devices may be arranged:

FIG. 6 schematically depicts a network coupled to components in various enclosures:

FIG. 7 schematically depicts a perspective view of an enclosure:

FIG. 8 depicts an interconnect drawing of a portion of an enclosure:

FIG. 9 schematically depicts component communities;

FIG. 10 depicts elevation views of an interconnect drawing:

FIG. 11A illustrates a use case example to which the presently disclosed techniques may be applied:

FIG. 11B schematically depicts an example of a network showing a set of requested device locations and a set of installed device locations:

FIG. 12A illustrates a method for determining a relative location of each of a plurality of devices within a network, according to some implementations:

FIG. 12B is a flowchart showing an illustrative Greedy type procedure for mapping a set of requested device locations to a set of installed device locations:

FIG. 13 is a flowchart showing an illustrative Greedy type procedure for mapping a set of requested device locations to a set of installed device locations:

FIG. 14 schematically depicts a graphical depiction illustrating an initial device location before correction, and an optimized device location after correction;

FIG. 15 is a flowchart showing a first illustrative Branch and Bound procedure for mapping a set of requested device locations to a set of installed device locations:

FIG. 16 is a flowchart showing a second illustrative Branch and Bound procedure for mapping a set of requested device locations to a set of installed device locations:

FIG. 17 depicts an illustrative set of requested device locations and installed device locations for a portion of an enclosure:

FIG. 18 depicts some examples of closely-spaced device pairs in a portion of an enclosure;

FIG. 19 is a graph showing an illustrative relationship between an average number of mapping errors and a distance error for matching a set of requested device locations to a set of installed device locations using a greedy algorithm;

FIG. 20 is a graph showing an illustrative relationship between an average number of mapping errors and a distance error for matching a set of requested device locations to a set of installed device locations using a greedy algorithm applied to a portion of an enclosure:

FIG. 21 depicts a portion of an enclosure showing requested device locations according to a system plan, and installed device locations based at least in part on visual inspection:

FIG. 22 depicts a set of correction error vectors relating requested device locations according to the system plan to device locations based at least in part on visual inspection:

FIG. 23 is a flowchart showing an illustrative procedure for mapping a set of requested device locations to a set of actually installed device locations:

FIG. 24A shows the relationship between the matrices that represent locations of virtual devices (A), locations of real devices (B), distances between virtual devices (a) and distances between real devices (b), and FIG. 24B shows various device arrangements and related distances:

FIG. 25 schematically shows a block diagram related to commissioning:

FIG. 26 schematically shows a block diagram related to commissioning:

FIG. 27 shows a schematic example of a computer system that is programmed to perform one or more operations of any of the methods provided herein:

FIG. 28 shows one example of a schematic cross-section of an electrochromic device; and

FIG. 29 shows another example of a schematic cross-section of an electrochromic device.

The figures and components therein may not be drawn to scale. Various components of the figures described herein may not be drawn to scale.

### DETAILED DESCRIPTION

While various embodiments of the invention are shown, and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

Terms such as “a”, “an” and “the” are not intended to refer to only a singular entity but include the general class of which a specific example may be used for illustration. The terminology herein is used to describe specific embodiments of the invention(s), but their usage does not delimit the invention(s).

When ranges are mentioned, the ranges are meant to be inclusive, unless otherwise specified. For example, a range between value 1 and value 2 is meant to be inclusive and include value 1 and value 2. The inclusive range will span any value from about value 1 to about value 2. The term “adjacent” or “adjacent to,” as used herein, includes next to,” “adjoining,” “in contact with,” and “in proximity to.”

As used herein, including in the claims, the conjunction “and/or” in a phrase such as “including X, Y, and/or Z”, refers to in inclusion of any combination or plurality of X, Y, and Z. For example, such phrase is meant to include X. For example, such phrase is meant to include Y. For example, such phrase is meant to include Z. For example, such phrase is meant to include X and Y. For example, such phrase is meant to include X and Z. For example, such phrase is meant to include Y and Z. For example, such phrase is meant to include a plurality of Xs. For example, such phrase is meant to include a plurality of Ys. For example, such phrase is meant to include a plurality of Zs. For example, such phrase is meant to include a plurality of Xs and a plurality of Ys. For example, such phrase is meant to include a plurality of Xs and a plurality of Zs. For example, such phrase is meant to include a plurality of Ys and a plurality of Zs. For example, such phrase is meant to include a plurality of Xs and Y. For example, such phrase is meant to include a plurality of Xs and Z. For example, such phrase is meant to include a plurality of Ys and Z. For example, such phrase is meant to include X and a plurality of Ys. For example, such phrase is meant to include X and a plurality of Zs. For example, such phrase is meant to include Y and a plurality of Zs. The conjunction “and/or” is meant to have the same effect as the phrase “X, Y, Z, or any combination or plurality thereof.” The conjunction “and/or” is meant to have the same effect as the phrase “one or more X, Y, Z, or any combination thereof.”

The term “operatively coupled” or “operatively connected” refers to a first element (e.g., mechanism) that is coupled (e.g., connected) to a second element, to allow the intended operation of the second and/or first element. The coupling may comprise physical or non-physical coupling (e.g., communicative coupling). The non-physical coupling may comprise signal-induced coupling (e.g., wireless coupling). Coupled can include physical coupling (e.g., physically connected), or non-physical coupling (e.g., via wireless communication). Operatively coupled may comprise communicatively coupled.

An element (e.g., mechanism) that is “configured to” perform a function includes a structural feature that causes the element to perform this function. A structural feature may include an electrical feature, such as a circuitry or a circuit element. A structural feature may include an actuator. A structural feature may include a circuitry (e.g., comprising electrical or optical circuitry). Electrical circuitry may comprise one or more wires. The electrical circuitry may be configured to coupe to an electrical power source (e.g., to the electrical grid). For example, the electrical circuitry may comprise a socket. Optical circuitry may comprise at least one optical element (e.g., beam splitter, mirror, lens and/or optical fiber). A structural feature may include a mechanical feature. A mechanical feature may comprise a latch, a spring, a closure, a hinge, a chassis, a support, a fastener, or a cantilever, and so forth. Performing the function may comprise utilizing a logical feature. A logical feature may include programming instructions. Programming instructions may be executable by at least one processor. Programming instructions may be stored or encoded on a medium accessible by one or more processors. Additionally, in the following description, the phrases “operable to,” “adapted to,” “configured to,” “designed to,” “programmed to,” or “capable of” may be used interchangeably where appropriate.

In some embodiments, a distributed network of controllers is used to control the optically-switchable (e.g., tintable) windows. For example, a network system may be operable to control a plurality of integrated glass units (e.g., IGUs) in accordance with some implementations. One function of the network system may be to control the optical states of the electrochromic devices (or other optically-switchable devices) as part of the tintable windows (e.g., within the IGUs).

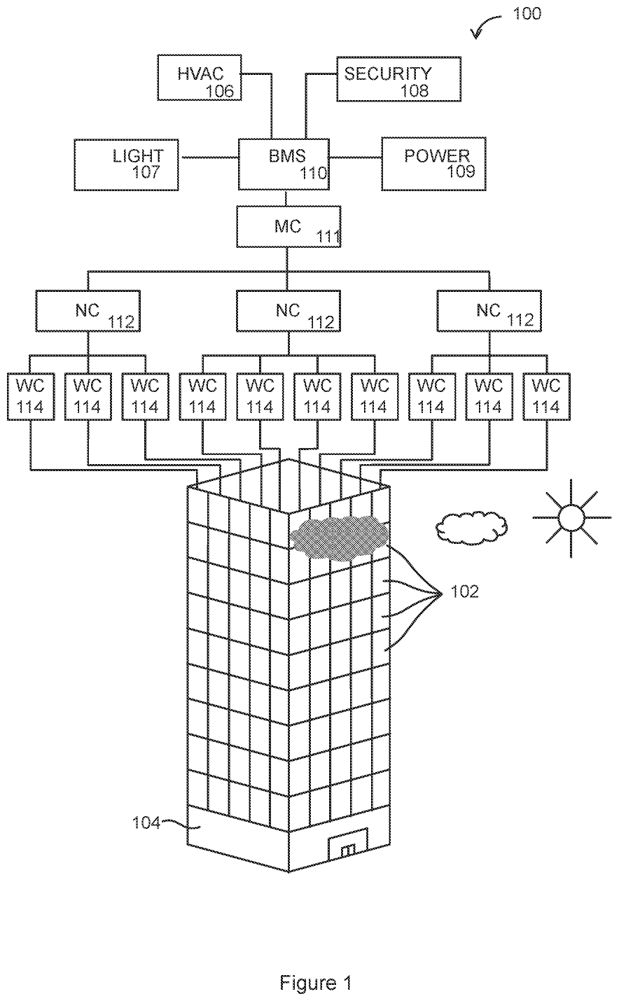

FIG. 1 shows an example of a system 100 for controlling and driving a plurality of tintable windows such as 102. It may be employed to control the operation of one or more devices associated with a tintable window such as a window antenna. The system 100 can be adapted for use with a facility (e.g., a building 104) that can be a commercial office building or a residential building. In some embodiments, the system 100 is designed to function in conjunction with heating, ventilation, and air conditioning (HVAC) systems 106, interior lighting systems 107, security systems 108, and power systems 109, e.g., as a single holistic and efficient energy control system for the entire building 104, or for a facility such as a campus of buildings, e.g., 104. Some embodiments of the system 100 are particularly well-suited for integration with a building management system (BMS) 110. The BMS 110 is a computer-based control system that can be installed in a building to monitor and control the building's mechanical and electrical equipment such as HVAC systems, lighting systems, power systems, elevators, fire systems, and security systems. The BMS 110 can include hardware and associated firmware and/or software for maintaining conditions in the building according to preferences set by the occupants or by a building manager or other administrator. The software can be based at least in part on, for example, internet protocols or open standards.

A BMS can be used in large buildings where it functions to control the environment within the building. For example, the BMS may control lighting, temperature, carbon dioxide levels, and/or humidity within the building. There can be several (e.g., numerous) mechanical and/or electrical devices that are controlled by the BMS including, for example, furnaces or other heaters, air conditioners, blowers, and/or vents. To control the building environment, the BMS can turn on and off these various devices, e.g., according to rules and/or in response to conditions. Such rules and/or conditions may be selected and/or specified by a user (e.g., building manager and/or administrator). One function of the BMS may be to maintain a comfortable environment for the occupants of the building, e.g., while minimizing heating and cooling energy losses and costs. In some embodiments, the BMS is configured not (e.g., only) to monitor and control, but also to optimize the synergy between various systems, for example, to conserve energy and lower building operation costs.

Some embodiments are designed to function responsively or reactively based at least in part on feedback. The feedback control scheme may comprise measurements sensed through, for example, thermal, optical, or other sensors. The feedback control scheme may comprise input from one or more sensors and/or mechanisms. For example, the feedback control scheme may comprise input from an HVAC, interior lighting system, and/or an input from a user control Examples of control system, methods of its use, and its related software, may be found in U.S. patent application Ser. No. 13/449,235, filed Apr. 17, 2012, now U.S. Pat. No. 8,705,162, issued Apr. 22, 2014, titled “CONTROLLING TRANSITIONS IN OPTICALLY SWITCHABLE DEVICES,” which is incorporated herein by reference in its entirety. Some embodiments are utilized in existing structures, including commercial and/or residential structures, e.g., having traditional or conventional HVAC and/or interior lighting systems. Some embodiments are retrofitted for use in older facilities (e.g., residential homes).

In some embodiments, the control system (e.g., 100) includes network controllers (e.g., 112) configured to control a plurality of window controllers (e.g., 114). For example, one network controller may control at least several, tens, hundreds, or thousands of window controllers. Each window controller, in turn, may control and drive one or more devices such as electrochromic windows. In some embodiments, the network controller can issue high-level instructions such as the final tint state of a tintable window. The window controllers may receive these commands and directly control their associated devices (e.g., windows), e.g., by applying electrical stimuli to appropriately drive tint state transitions and/or maintain tint states. The number and size of the tintable (e.g., electrochromic) windows that each window controller can drive, may be generally limited by the voltage and/or current characteristics of the load on the window controller controlling the respective electrochromic windows. In some embodiments, a window controller controls one or more tintable windows. In some embodiments, the maximum window size that the window controller can drive (e.g., alter the tint of) is limited by the voltage, current, and/or power requirements, to cause the requested optical transitions in the electrochromic window within a requested time-frame (e.g., to effectuate tint transition). Such requirements are, in turn, a function of the material properties of the tintable window. The material properties may include a surface area of the window; a thickness of the one or more layers of the optically switchable construct, and the concentration of coloring entities in (e.g., a layer of) the optically switchable construct (e.g., electrochromic construct). In some embodiments, this relationship is nonlinear. For example, the voltage, current, and/or power requirements can increase nonlinearly with the surface area of the electrochromic window. Without wishing to be bound to theory, in some cases the relationship is nonlinear at least in part because the sheet resistance of the first and second conductive layers increases nonlinearly with distance across the length and width of the first and/or second conductive layers. In some embodiments, the relationship between the voltage, current, and/or power requirements required to drive multiple electrochromic windows of equal size and shape is directly proportional to the number of the electrochromic windows being driven for tint transition.

FIG. 1 shows an example of a master controller 111. The master controller 111 communicates and functions in conjunction with multiple network controllers 112, each of which network controllers 112 is capable of addressing a plurality of window controllers 114. In some embodiments, the master controller 111 issues the high level instructions (such as the final tint states of the tintable windows) to the network controllers 112, and the network controllers 112 then communicate the instructions to the corresponding window controllers 114. Thus, FIG. 1 shows an example of a hierarchical control system with three hierarchy levels having lower hierarchy controllers (e.g., window controllers), and higher hierarchy controllers (e.g., master controller). FIG. 1 shows controllers and devices coupled to a network (e.g., local network of a facility comprising the building 104).

FIG. 1 shows an example of a hierarchical control system comprising the master controller 111, the network controllers 112, and the window controllers 114. In some implementations, the various electrochromic windows 102, antennas, and/or other target devices of the facility (e.g., comprising a building or other structure) are (e.g., advantageously) grouped into zones or groups of zones (e.g., wherein each of which includes a subset of the electrochromic windows 102). For example, each zone may correspond to a set of electrochromic windows in a specific location or area of the facility that should be tinted (or otherwise transitioned) to the same or similar optical states, based at least in part on their location. As another example, consider a building having four faces or sides: A North face, a South face, an East Face and a West Face. Consider that the building has ten floors. In such an example, each zone can correspond to the set of electrochromic windows on a particular floor and on a particular one of the four faces. In some such embodiments, each network controller can address one or more zones or groups of zones. For example, the master controller can issue a final tint state command for a particular zone or group of zones to a respective one or more of the network controllers. For example, the final tint state command can include an abstract identification of each of the target zones. The designated network controllers receiving the final tint state command may then map the abstract identification of the zone(s) to the specific network addresses of the respective window controllers that control the voltage or current profiles to be applied to the electrochromic windows in the zone(s).

In some embodiments, another function of the network system is to acquire status information (e.g., data) from the windows. For example, the status information for a given window can include an identification of, or information about, a current tint state of the tintable device(s) within the window (e.g., IGU). The network system may be operable to acquire data from various sensors, such as temperature sensors, photosensors (referred to herein as light sensors), humidity sensors, air flow sensors, and/or occupancy sensors, antennas, whether integrated on or within the tintable windows or located at various other positions in, on or around the building. At least one sensor may be configured (e.g., designed) to measure one or more environmental characteristics, for example, temperature, humidity, ambient noise, carbon dioxide, VOC, particulate matter, oxygen, and/or any other aspects of an environment (e.g., atmosphere thereof). The sensors may comprise electromagnetic sensors.

In some embodiments, the facility comprises a sensor or a transceiver, operatively couped to the control system. The sensor may comprise an electromagnetic sensor. The transceiver may be configured to sense and/or emit electromagnetic waves. The transceiver may be a radio. The electromagnetic sensor may be configured to sense ultraviolet, visible, infrared, and/or radio wave energy. The infrared energy may be passive infrared radiation (e.g., black body radiation). The electromagnetic sensor may sense radio waves. The radio waves may comprise wide band, or ultra-wideband radio signals. The radio waves may comprise pulse radio waves. The radio waves may comprise radio waves utilized in communication. The radio waves may be at a medium frequency of at least about 300 Kilohertz (KHz), 500 KHz, 800 KHz, 1000 KHz, 1500 KHz, 2000 KHz, or 2500 KHz. The radio waves may be at a medium frequency of at most about 500 KHz, 800 KHz, 1000 KHZ, 1500 KHz, 2000 KHz, 2500 KHz, or 3000 KHz. The radio waves may be at any frequency between the aforementioned frequency ranges (e.g., from about 300 KHz to about 3000 KHz). The radio waves may be at a high frequency of at least about 3 Megahertz (MHz), 5 MHz, 8 MHZ, 10 MHZ, 15 MHZ, 20 MHZ, or 25 MHZ. The radio waves may be at a high frequency of at most about 5 MHZ, 8 MHZ, 10 MHZ, 15 MHZ, 20 MHZ, 25 MHZ, or 30 MHZ. The radio waves may be at any frequency between the aforementioned frequency ranges (e.g., from about 3 MHz to about 30 MHZ). The radio waves may be at a very high frequency of at least about 30 Megahertz (MHz), 50 MHz, 80 MHZ, 100 MHZ, 150 MHZ, 200 MHZ, or 250 MHz. The radio waves may be at a very high frequency of at most about 50 MHZ, 80 MHz, 100 MHZ, 150 MHZ, 200 MHZ, 250 MHZ, or 300 MHz. The radio waves may be at any frequency between the aforementioned frequency ranges (e.g., from about 30 MHz to about 300 MHz). The radio waves may be at an ultra-high frequency of at least about 300 Kilohertz (MHz), 500 MHZ, 800 MHZ, 1000 MHZ, 1500 MHz, 2000 MHZ, or 2500 MHZ. The radio waves may be at an ultra-high frequency of at most about 500 MHZ, 800 MHZ, 1000 MHZ, 1500 MHZ, 2000 MHz, 2500 MHZ, or 3000 MHZ. The radio waves may be at any frequency between the aforementioned frequency ranges (e.g., from about 300 MHz to about 3000 MHz). The radio waves may be at a super high frequency of at least about 3 Gigahertz (GHz), 5 GHZ, 8 GHZ, 10 GHZ, 15 GHZ, 20 GHZ, or 25 GHZ. The radio waves may be at a super high frequency of at most about 5 GHZ, 8 GHZ, 10 GHZ, 15 GHZ, 20 GHZ, 25 GHZ, or 30 GHz. The radio waves may be at any frequency between the aforementioned frequency ranges (e.g., from about 3 GHZ to about 30 GHZ).

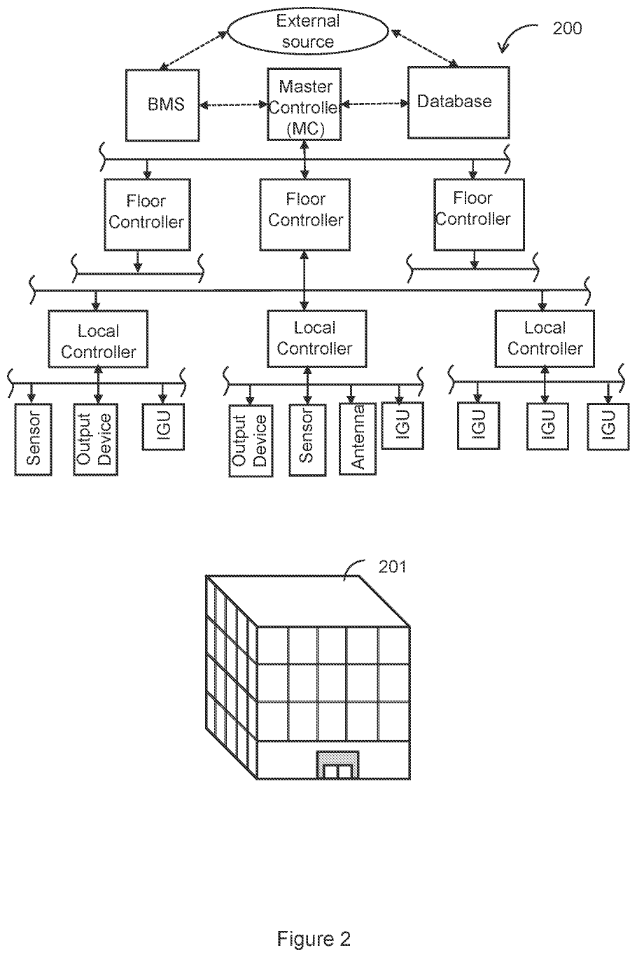

In some embodiments, one or more devices operatively coupled to the control system and/or to the network of the facility, may be disposed in or on a fixed in space enclosure. In some embodiments, one or more components may be mobile. An enclosure may comprise a portion of a building (e.g., having a geographical location, e.g., having a municipal address). A building may be a residential building and/or a commercial building. An enclosure may comprise and/or enclose one or more sub-enclosures. An enclosure may include a room, a lobby, hall, a duct, a foyer, an attic, a basement, a balcony (e.g., inner or outer balcony), a stairwell, a corridor, an elevator shaft, a mezzanine, a penthouse, a garage, a porch (e.g., enclosed porch), a terrace (e.g., enclosed terrace), and/or a cafeteria. An enclosure may include a floor and/or a level. An enclosure may include one or more elements. An element may comprise interior facing wall, exterior facing wall, ceiling, floor, window, entrance, door, opening, beam, stair, facade, molding, mullion, or transom. The enclosure may be stationary or movable. In some embodiments, one or more components are disposed in or on a moveable enclosure (e.g., a train, a plane, a ship, a vehicle, or a rocket). FIG. 2 schematically depicts a control system architecture 200 and a perspective view of a stationary enclosure 201 in the form of a building. The control system architecture depicts a hierarchical control system in which the local controllers are connected to various devices including a sensor, IGU, antenna, and an output device (e.g., lighting, HVAC, speaker, etc.). FIG. 2 shows an example of a control system architecture 200 comprising a master controller that controls floor controllers, that in turn control local controllers. In some embodiments, a local controller controls one or more IGUs, one or more sensors, one or more output devices (e.g., one or more emitters), or any combination thereof. FIG. 2 shows an example of a configuration in which the master controller is operatively coupled (e.g., wirelessly and/or wired) to a building management system (BMS) and to a database. Arrows in FIG. 2 represents communication pathways. A controller may be operatively coupled (e.g., directly/indirectly and/or wired and/wirelessly) to an external source. The external source may comprise a network. The external source may comprise one or more sensor or output device. The external source may comprise a cloud-based application and/or database. The communication may be wired and/or wireless. The external source may be disposed external to the facility. For example, the external source may comprise one or more sensors and/or antennas disposed, e.g., on a wall or on a ceiling of the facility. The communication may be monodirectional or bidirectional. All communication arrows in 200 are meant to be bidirectional.

In some embodiments, an enclosure comprises an area defined by at least one structure. The at least one structure may comprise at least one wall. An enclosure may comprise and/or enclose one or more sub-enclosures. In some embodiments, an enclosure comprises one or more sensors. An enclosure can comprise at least one wall that defines the enclosure. The at least one wall may comprise metal (e.g., steel), clay, stone, plastic, glass, plaster (e.g., gypsum), polymer (e.g., polyurethane, styrene, or vinyl), asbestos, fiber-glass, concrete (e.g., reinforced concrete), wood, paper, or a ceramic. The at least one wall may comprise wire, bricks, blocks (e.g., cinder blocks), tile, drywall, or frame (e.g., steel frame).

In some embodiments, the enclosure comprises one or more openings. The one or more openings may be reversibly closable. The one or more openings may be permanently open. A fundamental length scale of the one or more openings may be smaller relative to the fundamental length scale of the wall(s) that define the enclosure. A fundamental length scale may comprise a diameter of a bounding circle, a length, a width, or a height. A surface of the one or more openings may be smaller relative to the surface the wall(s) that define the enclosure. The opening surface may be a percentage of the total surface of the wall(s). For example, the opening surface can measure at most about 30%, 20%, 10%, 5%, or 1% of the walls(s). The wall(s) may comprise a floor, a ceiling, or a side wall. The closable opening may be closed by at least one window or door. The enclosure may be at least a portion of a facility. The facility may comprise a building. The enclosure may comprise at least a portion of a building. The building may be a private building and/or a commercial building. The building may comprise one or more floors. The building (e.g., floor thereof) may include at least one of: a room, hall, foyer, attic, basement, balcony (e.g., inner or outer balcony), stairwell, corridor, elevator shaft, façade, mezzanine, penthouse, garage, porch (e.g., enclosed porch), terrace (e.g., enclosed terrace), cafeteria, and/or Duct. In some embodiments, an enclosure may be stationary and/or movable (e.g., a train, an airplane, a ship, a vehicle, or a rocket).

In some embodiments, the enclosure encloses an atmosphere. The atmosphere may comprise one or more gases. The gases may include inert gases (e.g., comprising argon or nitrogen) and/or non-inert gases (e.g., comprising oxygen or carbon dioxide). The enclosure atmosphere may resemble an atmosphere external to the enclosure (e.g., ambient atmosphere) in at least one external atmosphere characteristic that includes: temperature, relative gas content, gas type (e.g., humidity, and/or oxygen level), debris (e.g., dust and/or pollen), and/or gas velocity. The enclosure atmosphere may be different from the atmosphere external to the enclosure in at least one external atmosphere characteristic that includes: temperature, relative gas content, gas type (e.g., humidity, and/or oxygen level), debris (e.g., dust and/or pollen), and/or gas velocity. For example, the enclosure atmosphere may be less humid (e.g., drier) than the external (e.g., ambient) atmosphere. For example, the enclosure atmosphere may contain the same (e.g., or a substantially similar) oxygen-to-nitrogen ratio as the atmosphere external to the enclosure. The velocity of the gas in the enclosure may be (e.g., substantially) similar throughout the enclosure. The velocity of the gas in the enclosure may be different in different portions of the enclosure (e.g., by flowing gas through to a vent that is coupled with the enclosure).

Certain disclosed embodiments provide a network infrastructure in the enclosure (e.g., a facility such as a building). The network infrastructure is available for various purposes such as for providing communication and/or power services. The communication services may comprise high bandwidth (e.g., wireless and/or wired) communications services. The communication services can be to occupants of a facility and/or users outside the facility (e.g., building). The network infrastructure may work in concert with, or as a partial replacement of, the infrastructure of one or more cellular carriers. The network infrastructure can be provided in a facility that includes electrically switchable windows. Examples of components of the network infrastructure include a high speed backhaul. The network infrastructure may include at least one cable, switch, physical antenna, transceivers, sensor, transmitter, receiver, radio, processor and/or controller (that may comprise a processor). The network infrastructure may be operatively coupled to, and/or include, a wireless network. The network infrastructure may comprise wiring. One or more sensors can be deployed (e.g., installed) in an environment as part of installing the network and/or after installing the network. The network may be a local network. The network may comprise a cable configured to transmit power and communication in a single cable. The communication can be one or more types of communication. The communication can comprise cellular communication abiding by at least a second generation (2G), third generation (3G), fourth generation (4G) or fifth generation (5G) cellular communication protocol. The communication may comprise media communication facilitating stills, music, or moving picture streams (e.g., movies or videos). The communication may comprise data communication (e.g., sensor data). The communication may comprise control communication, e.g., to control the one or more nodes operatively coupled to the networks. The network may comprise a first (e.g., cabling) network installed in the facility. The network may comprise a (e.g., cabling) network installed in an envelope of the facility (e.g., such as in an envelope of an enclosure of the facility. For example, in an envelope of a building included in the facility).

In various embodiments, a network infrastructure supports a control system for one or more windows such as tintable (e.g., electrochromic) windows. The control system may comprise one or more controllers operatively coupled (e.g., directly or indirectly) to one or more windows. While the disclosed embodiments describe tintable windows (also referred to herein as “optically switchable windows,” or “smart windows”) such as electrochromic windows, the concepts disclosed herein may apply to other types of switchable optical devices comprising a liquid crystal device, an electrochromic device, suspended particle device (SPD), NanoChromics display (NCD), Organic electroluminescent display (OELD), suspended particle device (SPD), NanoChromics display (NCD), or an Organic electroluminescent display (OELD). The display element may be attached to a part of a transparent body (such as the windows). The tintable window may be disposed in a (non-transitory) facility such as a building, and/or in a transitory facility (e.g., vehicle) such as a car, RV, bus, train, airplane, helicopter, ship, or boat.

In some embodiments, a tintable window exhibits a (e.g., controllable and/or reversible) change in at least one optical property of the window, e.g., when a stimulus is applied. The change may be a continuous change. A change may be to discrete tint levels (e.g., to at least about 2, 4, 8, 16, or 32 tint levels). The optical property may comprise hue, or transmissivity. The hue may comprise color. The transmissivity may be of one or more wavelengths. The wavelengths may comprise ultraviolet, visible, or infrared wavelengths. The stimulus can include an optical, electrical and/or magnetic stimulus. For example, the stimulus can include an applied voltage and/or current. One or more tintable windows can be used to control lighting and/or glare conditions, e.g., by regulating the transmission of solar energy propagating through them. One or more tintable windows can be used to control a temperature within a building, e.g., by regulating the transmission of solar energy propagating through the window. Control of the solar energy may control heat load imposed on the interior of the facility (e.g., building). The control may be manual and/or automatic. The control may be used for maintaining one or more requested (e.g., environmental) conditions, e.g., occupant comfort. The control may include reducing energy consumption of a heating, ventilation, air conditioning and/or lighting systems. At least two of heating, ventilation, and air conditioning may be induced by separate systems. At least two of heating, ventilation, and air conditioning may be induced by one system. The heating, ventilation, and air conditioning may be induced by a single system (abbreviated herein as “HVAC”). In some cases, tintable windows may be responsive to (e.g., and communicatively coupled to) one or more environmental sensors and/or user control. Tintable windows may comprise (e.g., may be) electrochromic windows. The windows may be located in the range from the interior to the exterior of a structure (e.g., facility, e.g., building). However, this need not be the case. Tintable windows may operate using liquid crystal devices, suspended particle devices, microelectromechanical systems (MEMS) devices (such as microshutters), or any technology known now, or later developed, that is configured to control light transmission through a window. Windows (e.g., with MEMS devices for tinting) are described in U.S. Pat. No. 10,359,681, issued Jul. 23, 2019, filed May 15, 2015, titled “MULTI-PANE WINDOWS INCLUDING ELECTROCHROMIC DEVICES AND ELECTROMECHANICAL SYSTEMS DEVICES,” and incorporated herein by reference in its entirety. In some cases, one or more tintable windows can be located within the interior of a building, e.g., between a conference room and a hallway. In some cases, one or more tintable windows can be used in automobiles, trains, aircraft, and other vehicles, e.g., in lieu of a passive and/or non-tinting window.

In some embodiments, the tintable window comprises an electrochromic device (referred to herein as an “EC device” (abbreviated herein as ECD), or “EC”). An EC device may comprise at least one coating that includes at least one layer. The at least one layer can comprise an electrochromic material. In some embodiments, the electrochromic material exhibits a change from one optical state to another, e.g., when an electric potential is applied across the EC device. The transition of the electrochromic layer from one optical state to another optical state can be caused, e.g., by reversible, semi-reversible, or irreversible ion insertion into the electrochromic material (e.g., by way of intercalation) and a corresponding injection of charge-balancing electrons. For example, the transition of the electrochromic layer from one optical state to another optical state can be caused, e.g., by a reversible ion insertion into the electrochromic material (e.g., by way of intercalation) and a corresponding injection of charge-balancing electrons. Reversible may be for the expected lifetime of the ECD. Semi-reversible refers to a measurable (e.g., noticeable) degradation in the reversibility of the tint of the window over one or more tinting cycles. In some instances, a fraction of the ions responsible for the optical transition is irreversibly bound up in the electrochromic material (e.g., and thus the induced (altered) tint state of the window is not reversible to its original tinting state). In various EC devices, at least some (e.g., all) of the irreversibly bound ions can be used to compensate for “blind charge” in the material (e.g., ECD).

In some implementations, suitable ions include cations. The cations may include lithium ions (Li+) and/or hydrogen ions (H+) (i.e., protons). In some implementations, other ions can be suitable. Intercalation of the cations may be into an (e.g., metal) oxide. A change in the intercalation state of the ions (e.g., cations) into the oxide may induce a visible change in a tint (e.g., color) of the oxide. For example, the oxide may transition from a colorless to a colored state. For example, intercalation of lithium ions into tungsten oxide (WO3-y (0<y≤˜0.3)) may cause the tungsten oxide to change from a transparent state to a colored (e.g., blue) state. EC device coatings as described herein are located within the viewable portion of the tintable window such that the tinting of the EC device coating can be used to control the optical state of the tintable window.

In some embodiments, a community of components such as devices includes specialized and/or non-specialized components. The specialized components may include anchor components, and/or coordinator components. The anchor component and the coordinator may be the same component or may be different components. The components may include one or more: sensors, actuators, transmitters, receivers, transceivers, processors, memories, emitters, and/or controllers. The non-specialized components may be stationary or mobile. The coordinator component may be stationary or mobile. The coordinator component may be a virtual component (e.g., reside in a cloud), for example, when the coordinator component is pre-assigned to a community (e.g., network) of components.

In some embodiments, an enclosure includes one or more sensors. The sensor may facilitate controlling the environment of the enclosure such that inhabitants of the enclosure may have an environment that is more comfortable, delightful, beautiful, healthy, productive (e.g., in terms of inhabitant performance), easer to live (e.g., work) in, or any combination thereof. The sensor(s) may be configured as low or high resolution sensors. Sensor may provide on/off indications of the occurrence and/or presence of a particular environmental event (e.g., one pixel sensors). In some embodiments, the accuracy and/or resolution of a sensor may be improved via artificial intelligence analysis of its measurements. Examples of artificial intelligence techniques that may be used include: reactive, limited memory, theory of mind, and/or self-aware techniques know to those skilled in the art). Sensors may be configured to process, measure, analyze, detect and/or react to one or more of: data, temperature, humidity, sound, force, pressure, electromagnetic waves, position, distance, movement, flow, acceleration, speed, vibration, dust, light, glare, color, gas(es), and/or other aspects (e.g., characteristics) of an environment (e.g., of an enclosure). The gases may include volatile organic compounds (VOCs). The gases may include carbon monoxide, carbon dioxide, water vapor (e.g., humidity), oxygen, radon, and/or hydrogen sulfide. The gas(es) may be present in an ambient environment. The gas(es) may comprise an inert gas.

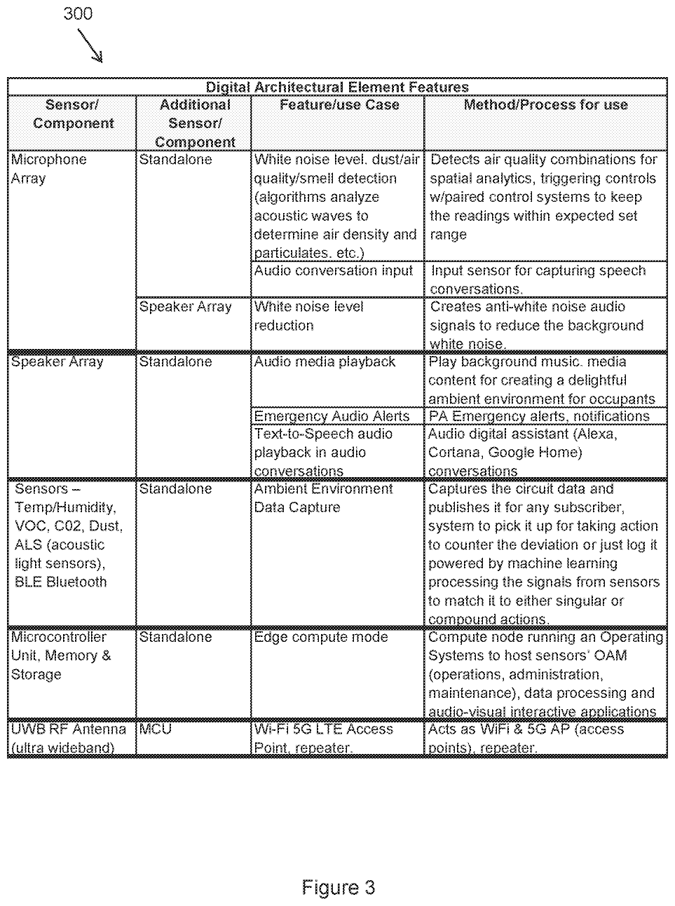

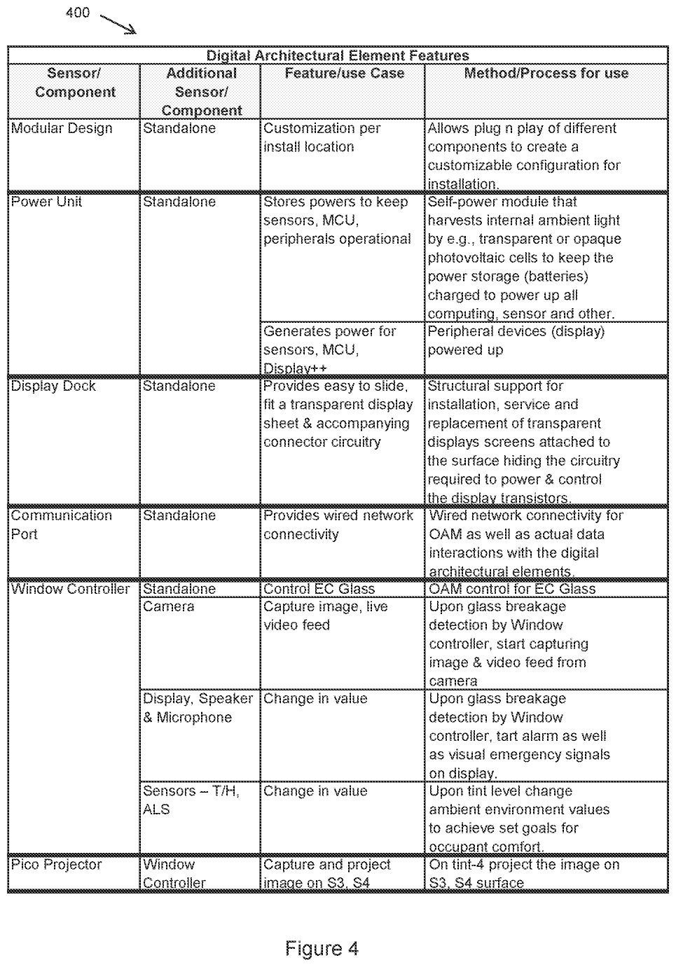

FIG. 3 delineates in table 300 examples of various types of devices (e.g., components) and some possible uses in a facility. FIG. 4 delineates in table 400 examples of various types of devices (e.g., components) and some possible uses in a facility.

In some embodiments, one or more component are coupled to (e.g., installed on, or in) an enclosure of the facility. For example, the one or more components may be coupled to elements of the enclosure. The element of the enclosure may include a wall, a door, a window; a door frame, a window frame, and/or a duct (e.g., air duct and/or an electrical duct). A component may be included in the element of the enclosure. A component may be coupled to an element directly or indirectly. A component may be a device, e.g., as disclosed herein. Coupled to may include fastened to, glued to, contacted with, electronically connected to, wired to, and/or tied to. A component may be easy to remove from an element such as a fixture (e.g., the component may be removable), or it may be permanently coupled to the element (e.g., hard to remove from an element without causing damage to the element). Easy to remove may include reversibly removable. For example, the component may be attached and detached to the element reversibly, e.g., with no aesthetic and/or detectable damage to the element and/or to the component. A component may be configured to attach (e.g., reversibly) to one or more element of an enclosure. The component may be reversibly or irreversibly attached to the element of the enclosure. A component may be configured to fit into and/or snap onto an element (e.g., fit into and/or attached on to a mullion). At least two components may be coupled to the same circuit board. At least two components may be coupled to separate circuit boards. A component ensemble may comprise two or more components (e.g., one or more sensor and one or more processor). In some embodiments, a component ensemble is coupled (e.g., disposed in) to a single circuit board. Two or more components may be part of a larger system (e.g., a module). Examples of components and modules are provided in U.S. patent application Ser. No. 16/447,169, titled “SENSING AND COMMUNICATIONS UNIT FOR OPTICALLY SWITCHABLE WINDOW SYSTEMS,” filed Jun. 20, 2019, which is incorporated herein by reference in its entirety. A component may communicate with, or be operatively (e.g., functionally) coupled, to other components wirelessly or via one or more wires (e.g., one or more wireless camera may communicate with one or more processor via radio waves).

In some embodiment, tintable windows may be arranged in a hierarchical structure. A hierarchical structure can help facilitate the control of tintable windows at a particular site by allowing rules or user control to be applied to various groupings of tintable windows or IGUs. Further, for aesthetics, multiple contiguous windows in a room and/or other site location (e.g., in an enclosure) may sometimes need to have their optical states correspond and/or tint at the same rate. Treating a group of contiguous windows as a zone can facilitate these goals.

In some embodiments, windows (e.g., IGUs) are grouped into zones of tintable windows, each of which zones includes at least one window controller and its respective windows. Each zone of windows may be controlled by one or more respective NCs and one or more respective WCs controlled by these NCs. For example, each zone can be controlled by a single NC and two or more WCs controlled by the single NC.

In some embodiments, at least one device (e.g., component) is operated in coordination with at least one other device, which devices are coupled to the network. Control of the at least one device may be via the network (e.g., comprising Ethernet). For example, A tint level of tintable windows may be adjusted concurrently. When the devices are in use, a zone of devices may have at least one characteristic that is the same. For example, when the tintable windows are in a zone, a zone of tintable windows may have its tint level (automatically) altered (e.g., darkened or lightened) to the same level. For example, when sounds sensors are in a zone, they may sample sound at the same frequency and/or at the same time window. A zone of devices may comprise a plurality of devices (e.g., of the same type). The zone may comprise (i) devices (e.g., tintable windows) facing a particular direction of an enclosure (e.g., facility), (ii) a plurality of devices disposed on a particular face (e.g., façade) of the enclosure, (iii) devices on a particular floor of a facility, (iv) devices in a particular type of room and/or activity (e.g., open space, office, conference room, lecture hall, corridor, reception hall, or cafeteria), (v) devices disposed on the same fixture (e.g., internal or external wall), and/or (vi) devices that are user defined (e.g., a group of tintable windows in a room or on a façade that are a subset of a larger group of tintable windows. The adjustment of the devices may be done automatically and/or by a user. The automatic changing of device properties and/or status in a zone, may be overridden by a user (e.g., by manually adjusting the tint level). A user may override the automatic adjustment of the devices in a zone using an app installed on a mobile circuitry (e.g., a remote controller, a virtual reality controller, a cellular phone, an electronic notepad, a laptop computer and/or by a similar mobile device).

In some embodiments, when instructions relating to the control of a device (e.g., instructions for a window controller and/or an IGU) are passed through the network system, they are accompanied with a unique network ID of the device they are sent to. Networks IDs may be helpful to ensure that instructions reach and are carried out on the intended device. For example, a window controller that controls the tint states of more than one IGU, may determine which IGU to control based upon a network ID such as a Controller Area Network (CAN) ID (a form of network ID) that is passed along with the tinting command. In a window network such as those described herein, the term network ID includes but is not limited to CAN IDs, and BACnet IDs. Such network IDs may be applied to window network nodes such as window controllers, network controllers, and master controllers. A network ID for a device may include the network ID of every device that controls it in the hierarchical structure. For example, the network ID of an IGU may include a window controller ID, a network controller ID, and a master controller ID in addition to its own CAN ID.

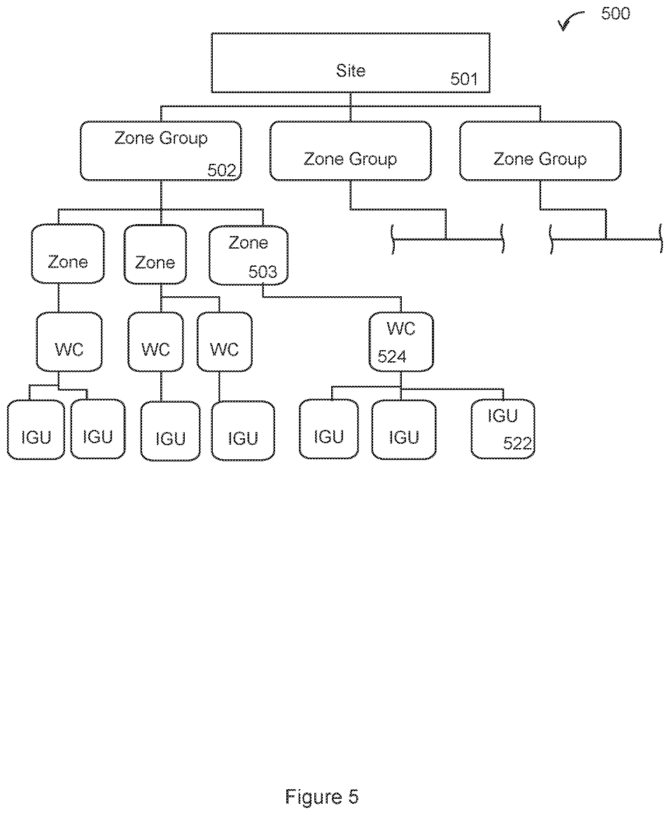

FIG. 5 shows various IGUs 522 grouped into zones 503 of tintable windows, each of which zones 503 includes at least one window controller 524 and its respective IGUs 522. In some embodiments, each zone of IGUs 522 is controlled by one or more respective NCs and one or more respective WCs 524 controlled by these NCs. Each zone 503 may be controlled by a single NC and two or more WCs 524 controlled by the single NC. Thus, a zone 503 can represent a logical grouping of the IGUs 522. For example, each zone 503 may correspond to a set of IGUs 522 in a specific location or area of the building that are driven together based at least in part on their location. As a more specific example, consider a site 501 that is a building having four faces or sides: A North face, a South face, an East Face and a West Face. Consider that the building has ten floors. In such an example, each zone 503 may correspond to the set of tintable windows 522 on a particular floor and on a particular one of the four faces. Each zone 503 may correspond to a set of IGUs 522 that share one or more physical characteristics (for example, device parameters such as size or age). In some embodiments, a zone 503 of IGUs 522 is grouped based at least in part on one or more non-physical characteristics comprising a security designation or a business hierarchy (for example, IGUs 522 bounding managers' offices can be grouped in one or more zones while IGUs 522 bounding non-managers' offices can be grouped in one or more different zones).

In some such implementations, each NC can address all of the IGUs 522 in each of one or more respective zones 503. For example, the MC can issue a primary tint command to the NC that controls a target zone 503. The primary tint command can include an abstract identification of the target zone (hereinafter referred to as a “zone ID”). In some such implementations, the zone ID can be a first protocol ID such as that just described in the example above. The NC may receive the primary tint command including the tint value and the zone ID and may map the zone ID to the second protocol IDs associated with the WCs 524 within the zone. In some embodiments, the zone ID can be a higher level abstraction than the first protocol IDs. In such cases, the NC can first map the zone ID to one or more first protocol IDs, and subsequently map the first protocol IDs to the second protocol IDs.

In some embodiments, the control system is configured to control one or more devices of the facility. In order to facilitate controlling the facility using the devices (e.g., components) disclosed herein, the control system may utilize the network address of the devices connected to that a specific local controller. A function of commissioning may be used to provide correct assignment of local controller addresses and/or other identifying information to specific devices, as well the physical locations of the devices and/or their associated local controllers. For example, for tint controls to work (e.g., to allow the window control system to change the tint state of one or a set of specific windows or IGUs), a master controller, network controller, and/or other controller responsible for tint decisions, may utilize the network address of the window controller(s) connected to that specific window or set of windows. For example, a function of commissioning may be used to provide correct assignment of the window controller addresses and/or other identifying information to specific windows, as well the physical locations of the windows and/or window controllers in the facility. In some embodiments, a goal of commissioning is to correct mistakes and/or other problems made in installing devices such as windows in the wrong locations, and/or connecting cables to the wrong controllers (e.g., to a local controller such as a window controller). In some embodiments, a goal of commissioning is to provide semi- or fully-automated installation, e.g., to allow installation with little or no location guidance for installers.

In some embodiments, the commissioning process for a particular device (e.g., window or IGU) may involve associating an ID for a device (e.g., the window and/or other window-related component), with its corresponding local (e.g., window) controller. The process may assign a location in the facility such as a relative location, and/or am absolute location (e.g., latitude, longitude and elevation) to the device (e.g., window or another component). Examples relating to commissioning and/or configuring a network of tintable windows can be found in U.S. patent application Ser. No. 14/391,122, filed Oct. 7, 2014, titled “APPLICATIONS FOR CONTROLLING OPTICALLY SWITCHABLE DEVICES,” U.S. patent application Ser. No. 14/951,410, filed Nov. 24, 2015, titled “SELF-CONTAINED EC IGU,” U.S. Provisional Patent Application Ser. No. 62/305,892, filed Mar. 9, 2016, titled “METHOD OF COMMISSIONING ELECTROCHROMIC WINDOWS,” and U.S. Provisional Patent Application Ser. No. 62/370,174, filed Aug. 2, 2016, titled “METHOD OF COMMISSIONING ELECTROCHROMIC WINDOWS,” each of which is herein incorporated by reference in its entirety.

After a network of devices (e.g., including optically switchable windows) is physically installed, the network can be commissioned to correct any incorrect assignment of local controllers to the wrong devices (e.g., windows (often as IGUs)) and/or facility locations. In some embodiments, commissioning maps pairs (e.g., links) individual devices (e.g., windows) and their locations with associated local (e.g., window) controllers. In some embodiments, a local controller is a controller that is directly connected to a device without any intervening controller between the local controller and the device. The local controller can be connected directly or indirectly to the higher hierarchy controller(s) such as master controller and/or local controller.

In some embodiments, commissioning is intended to address mis-pairing of local (e.g., window) controllers and associated devices (e.g., windows), for example, during installation (e.g., during commissioning). For example, before installation, a local (e.g., window) controller may be assigned to a particular device (e.g., window), which may be assigned to a particular location in the facility. However, during installation a local (e.g., window) controller and/or devices (e.g., window) may be installed in an incorrect location. For instance, a local (e.g., window) controller may be paired with the wrong device (e.g., window), and/or the device (e.g., window) may be installed in the wrong location. These mis-pairings can be difficult to address and/or require substantial (e.g., manual) labor, time and/or cost to address and/or rectify. Additionally, during the construction process, the physical device (e.g., window) installation and the wiring installation in the facility may be done by different teams at different times. Recognizing this challenge, in some implementations, the devices (e.g., windows) and/or local controllers are not pre-assigned to one another, but rather are paired during a commissioning process. Even if mis-pairing is not a problem because, for example, local (e.g., window) controllers are physically affixed to their corresponding devices (e.g., windows), the installer might not know (or care) which device (e.g., window) (and hence which local controller) is installed at which location. For example, devices may be identical in size, shape, and/or optical properties, and hence be visibly interchangeable. The installer may install such devices at any convenient location, without regard for the unique local controller associated with each such device. Various commissioning embodiments described herein may permit flexible installation.

Some examples of issues that can arise during installation are the following: (I) Mistakes in placing devices (e.g., windows) in correct locations: for example, electrically controllable windows may be susceptible to mis-installation, e.g., by technicians who are not accustomed to working with electrically controllable windows. These technicians may include tradespeople such as glaziers and/or low voltage electricians (LVE's): (II) Misconnecting cables to local controllers: for example, this can be occur, e.g., when multiple visibly identically devices are disposed in close proximity: (III) Malfunctioning (e.g., broken) devices (e.g., tintable windows) and/or controllers: for example, an installer can install an available device and/or controller in place of the malfunctioning (e.g., broken) one. The new device and/or controller may not be in the installation and/or facility (e.g., BIM) plan, and thus may not be accounted for and/or recognized during commissioning: and (IV) The process of installing many devices (e.g., windows) at the correct locations may be intellectually and/or physically complicated. It would be advantageous to replace the paradigm of having installers be responsible for installing many unique but visibly identical devices in their designated locations, which installation may be prone to human error. Therefore, it could be useful to do away with (e.g., some, much, or all of) the device and/or controller location and accurate identification considerations, which can complicate the installation process. The device can be any device (e.g., component) disclose herein, including windows. The controller can be a lower or a higher hierarchy controller.

In one example, installation and attendant problems requiring improved methods of commissioning may arise from any of the following operations:
(a) A unique network address (e.g., a CANID, or Internet Protocol (IP) Address) is assigned to each local controller when the local controllers are manufactured. The local controller can be a device controller. For example, when the device is a window, the local controller is a window controller. For example, when the device is a sensor, the local controller is a sensor controller. For example, when the device is an emitter, the local controller is an emitter controller.
(b) The device manufacturer (that is not necessarily the local device controller manufacturer), a facility designer, or other entity, specifies information about the device controller (with specified network address) and the device. For example, the window manufacturer (that is not necessarily the window controller manufacturer), a building designer, or other entity, specifies information about the window controller (with specified network address) and window (IGU). The device manufacturer does this by assigning a device controller ID (DCID), which is not (e.g., which differs from) the device controller's network address. The device manufacturer and/or other entity specifies which device is associated with the local controller (DCID). To this end, the entity specifies device IDs (DIDs) for the device. In certain cases, the manufacturer and/or other entity does not specify a correlation between a device and a controller, e.g., to which specific device(s) a controller needs to be connected to. For example, the device manufacture need not specify that a local controller (with a CANID (e.g., 19196997)) needs to connect to any particular device ID (e.g., 04349′0524 0071′0017′00). Instead, the manufacturer or other entity specifies that a local controller (with CANID (e.g., 19196997)) has a local controller ID of, e.g., LC10. The device controller ID may be reflected (e.g., appear) as a location tag (e.g., an arbitrary number such as an arbitrary serial number assigned to devices in an installation) on an interconnect drawing, architectural drawing or other representation of a facility, which may specify that the device controller connects to particular device identified by device IDs (e.g., D31 and D32 (location tag for IGs)). For example, the window device manufacturer does this by assigning a window controller ID (WCID), which is not (e.g., which differs from) the window controller's network address. The window manufacturer and/or other entity specifies which IGU(s) are associated with the window controller (WCID). To this end, the entity specifies window IDs (WIDs) for the windows. In certain cases, the manufacturer and/or other entity does not specify a correlation between IGU and controllers, e.g., to which specific IGU(s) a controller needs to be connected. For example, the window manufacture need not specify that a WC (with a CANID (e.g., 19196997)) needs to connect to any particular WID (e.g., 04349′0524 0071′0017 00). Instead, the manufacturer or other entity specifies that a WC (with CANID (e.g., 19196997)) has a window controller ID of, e.g., WC10. The window controller ID may be reflected (e.g., appear) as a location tag (e.g., an arbitrary number assigned to windows in an installation) on an interconnect drawing, architectural drawing or other representation of a building, which may specify that the window controller connects to particular IGUs identified by window IDs (e.g., W31 and W32 (location tag for IGs)).
(c) As indicated, the manufacturer or other entity applies a device controller ID (DCxx label) on each local device controller. The entity enters a DCxx/CAN ID pair information in a configuration file used by master controller/network controller or other device containing logic responsible for issuing individual tint decisions.
(d) This process requires that an installing technician (e.g., such as a low voltage engineer (LVE)) charged with installing and/or connecting electrically controllable devices (e.g., windows) to select a specific local controller from the boxes of local controllers and install it in a specific location in the facility.
(e) Any errors made in operations (c) or (d) lead to difficult troubleshooting in the field to find the mis-mapping and correct it.
(f) Even if operations (c) and (d) are executed correctly, a local controller and/or device can be damaged and/or otherwise malfunction, in which case it should be replaced during the installation. This again can cause problems unless the change is tracked manually and reflected in the configuration file. This discussion can apply to a window or to any other device (substituting the window), and any local controller that controls the device (substituting the window controller). The device can by any device (e.g., component), e.g., as disclosed herein.

As indicated, in various embodiments, the commissioning process pairs individual devices (e.g., tintable windows, device ensemble, or any other individual device) with individual local (e.g., window) controllers responsible for controlling various attributes of the device (e.g., for controlling the optical states of the tintable windows). In some embodiments, the commissioning process pairs a device and/or local controller locations with local controller IDs and/or controller network identifiers (e.g., CANIDs) for controllers that are directly control the devices (e.g., with no intervening controller) and/or for controllers disposed on or proximate to devices. For example, the commissioning process pairs window and/or window controller locations with window controller IDs and/or window controller network identifiers (e.g., CANIDs) for controllers that are disposed on or proximate to windows. Such controllers may be configured to control one or more properties of the device (e.g., the optical states of windows). The local controllers may directly control the device, may be located on or proximate to the device (e.g., may be located on the window or device ensemble housing or proximate to). In some embodiments, the commissioning process specifies the type of controller in a hierarchical network and/or the logical position of the controller in that network's topology. Each individual device (e.g., sensor, device ensemble, and/or optically switchable window) may have a physical ID (e.g., the window or lite ID (WID) mentioned herein) and an associated controller with a unique network ID (e.g., CANID). In some embodiments, the local controller includes a physical ID (e.g., the WCID). In general, a commissioning process may be used to link (e.g., pair) any two related network components including but not limited to IGUs (or lites in IGUs), window controllers, network controllers, master controllers, sensors, emitters, antenna, receivers, transceivers, processors, memory (e.g., sever), and/or device ensembles. In some embodiments, the commissioning process involves pairing network identifiers associated with devices (e.g., IGUs) and/or controllers, to fixtures, surfaces and/or any other features on a three-dimensional building model (e.g., BIM file). Device ensembles may be referred to herein as “digital architectural element.” The device ensemble may comprise (i) sensors, (ii) a sensor and an emitter, (iii) a transceiver, (iv) a processor, (v) network connectivity, or (vi) a memory.

In some embodiments, a commissioning linkage is made by comparing an architecturally determined location of a first component (e.g., device) with a wirelessly measured location of a second component, which second component is associated with the first component. For example, the first component may be an optically switchable window and the second component may be a window controller configured to control the optical state of the optically switchable component. In another example, the first component may be a sensor that provides measured radiation data to a local (e.g., window or sensor) controller, which is the second component. At times, the location of the first component may be known with greater accuracy than the location of the second component. The location may be determined by a wireless measurement. The location may be determined by a traveler such as a field service engineer or a robot such as a drone. While the accurate location of the first component may be determined from architectural drawings or a similar source (e.g., BIM file), the commissioning process may employ alternative sources such as manually-measured post-installation locations of the devices (e.g., windows or other components). Geographic auto location technology (also referred to as geolocation technologies, e.g., Global positioning system (GPS), ultrawide band radio waves (UWB), infrared radiation, Bluetooth technology, and the like) may be used. The location may be determined using dead reckoning. In various embodiments, the component whose location is determined by wireless measurement (e.g., a local controller) has a network ID. The network ID can be made available during the commissioning process, e.g., via a configuration (e.g., BIM) file. In such cases, the commissioning process may pair the accurate physical location of the first component with the network ID of the second component. In some embodiments, the first and second components are a single component. For example, a window controller may be such component: e.g., its position may be both determined from an architectural drawing and from wireless measurement. The commissioning process may ascribe the physical location from the architectural drawing (e.g., BIM file) with the network ID from the configuration file. The BIM file may constitute a digital twin of the facility (e.g., building).

In some embodiments, the linkages determined during commissioning are stored in a file, data structure, database, or the like (e.g., BIM file) that can be consulted by various window network components and/or associated systems such as mobile applications, window control intelligence algorithms, Building Management Systems (BMSs), security systems, lighting systems, and the like. In some embodiments, the commissioning linkages are stored in a network configuration file which may be included in the digital twin of the facility. In some embodiments, a network configuration file is used by the network to send appropriate commands between components on the network: e.g., a master controller sends a tint command to the local (e.g., window) controller for a designated device (e.g., tintable window), by its location in a structure, for a (e.g., configuration and/or tint) change.

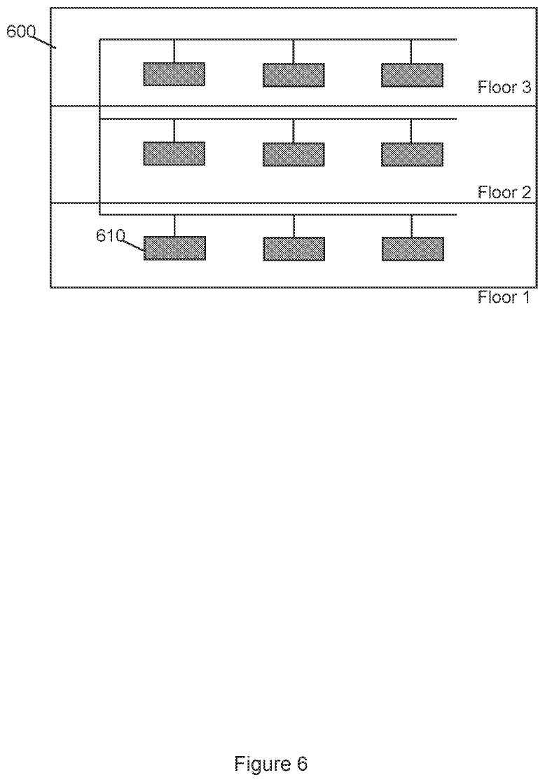

FIG. 6 shows a schematic example of a network within an enclosure. In the example of FIG. 6, the enclosure 600 is a building having floor 1, floor 2, and floor 3. The enclosure 600 includes a network 620 (e.g., wired network) that is provided to communicatively couple a community of components 610. In the example shown in FIG. 6, the three floors are sub enclosures within the enclosure 600.

In some embodiments, the facility has a community of components (e.g., devices) operatively coupled to each other, to a (e.g., local) network, and/or to a control system. Communication within the community of components coupled to a network may be coordinated by at least one component. The component may be part of the community. The component may comprise a controller. A controller may be located within an enclosure that houses the components being controlled by the controller, or the controller may be disposed outside of the enclosure that houses the components (e.g., outside of a device ensemble). For example, the controller may be located remotely relative to the enclosure housing the controller. The remote location may be physical or virtual (e.g., in the cloud). A controller may communicate with a community of components wirelessly and/or via one or more wires. A controller may comprise, but is not limited to, a processor, a local or distributed server, a building management system, a sensor management system, an environmental management system, a component controller, and a window controller. Examples of window controllers, and methods of use of are provided in U.S. patent application Ser. No. 16/096,557, filed Oct. 25, 2018, titled “CONTROLLING OPTICALLY-SWITCHABLE DEVICES,” which is incorporated herein by reference in its entirety. In some embodiments, the component comprises a controller. In some embodiments, the component may function as a controller. The controller may be temporarily assigned to the community of components. The controller may be permanently assigned to the community of the components (e.g., during the operative life of the community and of the controller).

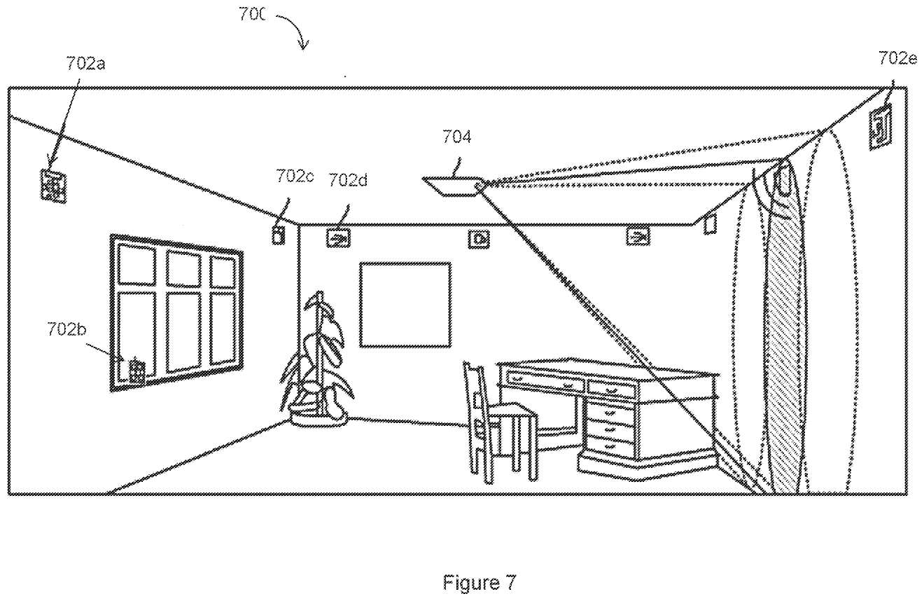

FIG. 7 shows an example of a community of components coupled to elements of an enclosure. In the example shown in FIG. 7, a community of components 702a-702e is coupled to elements of an enclosure 700 comprised of interior facing walls, a ceiling and a window. Component 702a can represent one or more gas sensors configured to measure, analyze, and/or provide indications of ambient CO2 levels within an enclosure. Component 702b can represent one or more controller configured to control functions of one or more window. A window may comprise an optically switchable window, e.g., an electrochromic window. Examples of optically switchable windows, controllers, and methods of use of are provided in U.S. patent application Ser. No. 16/462,916, titled “AUTOMATED COMMISSIONING OF CONTROLLERS IN A WINDOW NETWORK,” filed May 21, 2019, which is incorporated herein by reference in its entirety. Component 702c can represent one or more sound sensors configured to measure, analyze, and/or provide indications of sound levels present within the enclosure. Component 702d can represent one or more light sensor configured to measure, analyze, and/or provide indications of light and/or glare present within the enclosure. Component 702e can represent one or more transceiver configured to receive and transmit radio waves within the enclosure. Component 702f can represent one or more processor configured to process signals transmitted by one or more of components 702a-702e. Some community of components may have at least two components of the same type (e.g., two temperature sensors). For example, all members of the community of components may be of the same type. Some community of components may have at least two components of different type (e.g., a temperature sensor and a pressure sensor). For example, all members of the community of components may be of different types. In some embodiments, a single component may provide the functionality of two or more components (e.g., a force sensor that is used to detect vibration and movement). In some embodiments, components with functionalities other than disclosed herein may be used. In some embodiments, components may be provided on, or in, elements other than disclosed herein.

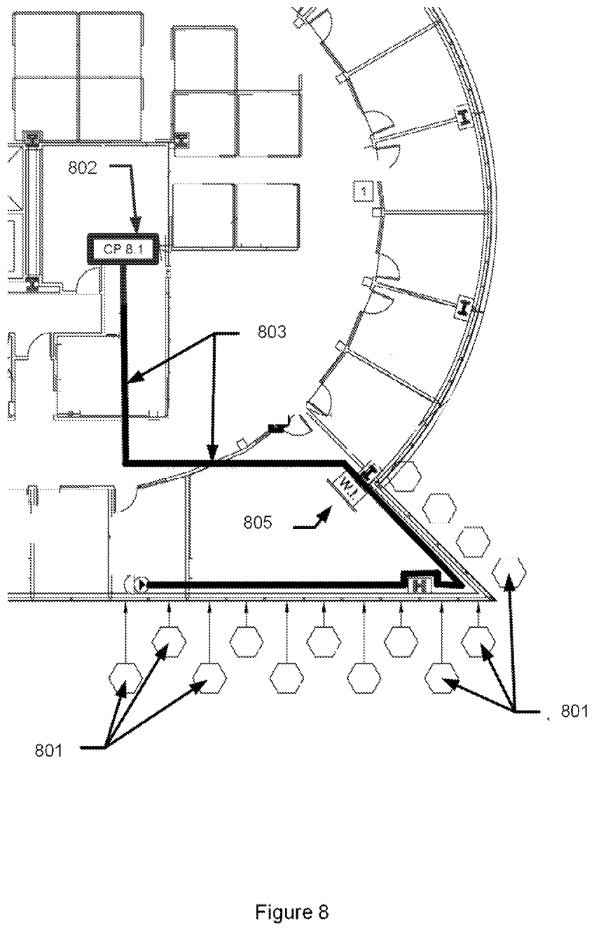

FIG. 8 provides one example of an interconnect drawing which is created from architectural drawing (e.g., floorplan) of the building. Interconnect drawings include the placement of IGUs and window controllers 801, control panels 802, trunk lines 803, wall interfaces 805, and various other network components such as master controllers, network controllers, sensors. Although not shown, interconnect drawings (e.g., a BIM such as a Revit file) may include additional information such as structural information, structural dimensions, and information such as the network IDs of various network components depicted.

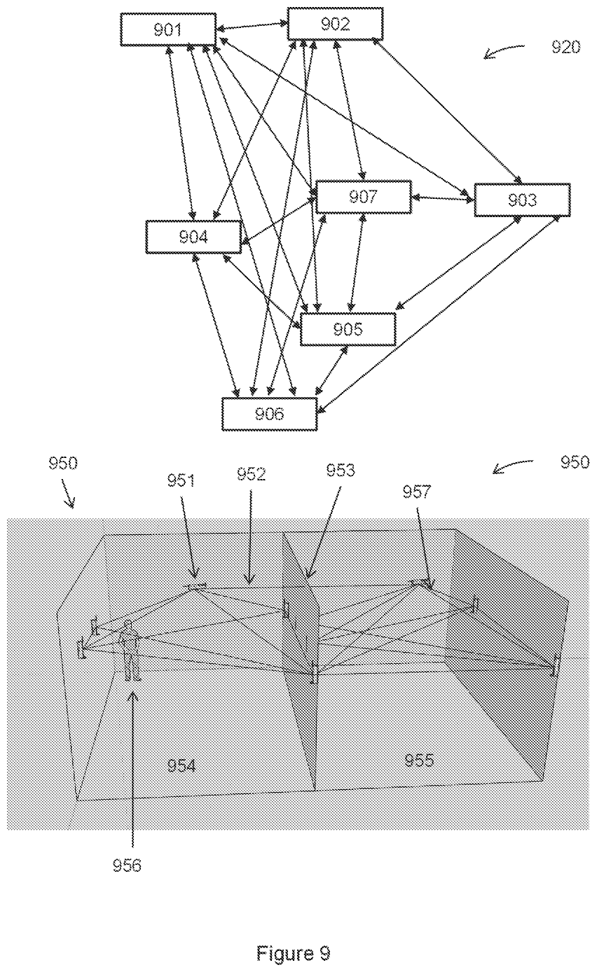

FIG. 9 shows an example of a community of components 901-907 that are communicatively coupled to form a communication network of components 920. The community of components 901-907 can be configured to communicate via a network, and/or form a communication network. The arrows of the network shown in the example of FIG. 9, depict a possible (e.g., allowed) direction of communication (e.g., a direction of signal propagation). A network may be a wired and/or a wireless network. One or more component of a community of components may be powered by an onboard power source and/or powered by a remote power source. Power to one or more component of a community of components may be provided wirelessly (e.g., harvested energy) and/or via wires. The power may be from a renewable energy source (e.g., from a solar panel). The power may be from a non-renewable energy source (e.g., from a power plant using non-renewable energy).

FIG. 9 shows an example of a network of components disposed in an enclosure 950 comprising two sub enclosures 954 and 955 (e.g., two rooms). Component 951 is part of the community of components disposed in the first sub-enclosure 954 (e.g., room) in which a person 956 is presently located, and component 957 is part of the community of components disposed in a second sub-enclosure 955 (e.g., room) that is not occupied by any person. A wall 953 separates the two sub-enclosures in the example shown in FIG. 9, that also shows possible (e.g., allowed) communication routes between the components, schematically depicted as lines (e.g., 952). At times, the community of components may span more than one enclosure or sub-enclosures. For example, at least part of (e.g., all of) the components from the two sub-enclosures 954 and 955 constitute one community of components. At times, the community of components may span one enclosure or sub-enclosures. For example, at least part of (e.g., all of) the components from sub-enclosure 954 constitute one community of components, that excludes the components in enclosure 955. The physical fundamental length scale of the community of components may depend on the range of signal transmission and/or receipt by a coordinator of the community of components.

In some embodiments, a topology of a community of components is determined. The topology may be determined, at least in part, by a moving or stationary person and/or a machine. A traveler may be a moving person or machine. The topology may be absolutely determined or relatively determined. An absolute determination of the topology may require a traveler or a third party (e.g., third party accessory) to verify an absolute coordination of at least one of the community members. The absolute coordination may be determined based at least in part on geolocation technology configured to determine absolute coordination (e.g., on global positioning system (GPS) coordinates) and/or on location determination using a traveler. A relative determination of coordinates may include relative position of the components in relation to one another (e.g., based at least in part on geolocation technology). A topology of a community of components may be determined from distances and/or angles measured between the community of components. A topology of a community of components may be determined by one or more processor configured to perform (or direct performance of) (I) measurements and/or analysis of: (I) time of flight of one or more signals propagating between the components (e.g., signal between component 902 and 907 of FIG. 9), (II) response times of components, (III) distances and/or angles between components. The one or more processors may be of a component or of two or more components. Measurements and/or analysis may be stored as data in one or more memory associated with, or operatively coupled to, one or more processor. The memory may be disposed in the enclosure, or outside of the enclosure. The memory may be disposed in the cloud, or in another facility (e.g., in another building). Measurements between a community of components may define constraints. The constraints may be utilized by at least one processor to determine a relative distance between the community members. The processor may utilize data stored in at least one memory. The processor may utilize one or more calculations (e.g., triangulation) to determine the relative position of the components. In one embodiment, once distances between at least three (3) components (e.g., anchor components) disposed in a common plane are determined, the positions of the other components of the community may be determined relative to the three components. Each of the three components may have associated Cartesian coordinates (e.g., X, Y, and Z). The three components may have at least two of their Cartesian coordinates different from each other (e.g., the three components are different in at least two dimensions). For example, the three components may have all three of their Cartesian coordinates different (e.g., the three components are different in three dimensions). As the number of components is increased, a topology's (e.g., relative) positional accuracy may improve. The topology may be displayed (e.g., on a user interface communicatively coupled to the community of components).

In some embodiments, one or more component of a community of components comprises a transceiver. In some embodiments, a transceiver may be configured transmit and receive one or more signals using a personal area network (PAN) standard (e.g., and protocol), for example such as IEEE 802.15.4. In some embodiments, signals may comprise Bluetooth, Wi-Fi, or EnOcean signals (e.g., wide bandwidth). The one or more signals may comprise ultra-wide bandwidth (UWB) signals (e.g., having a frequency in the range from about 2.4 to about 10.6 Gigahertz (GHz), or from about 7.5 GHz to about 10.6 GHZ). An Ultra-wideband signal can be one having a fractional bandwidth greater than about 20%. An ultra-wideband signal can have a bandwidth greater than about 500 Megahertz (MHz). The one or more signals may use a very low energy level for short-range. Signals (e.g., having radio frequency) may employ a spectrum capable of penetrating solid structures (e.g., wall, door, and/or window). Low power may be of at most 25 milliwatts (mW), 50 mW, 75 mW, or 100 mW. Low power may be any value between the aforementioned values (e.g., from 25 mW to 100 mW, from 25 mW to 50 mW, or from 75 mW to 100 mW).

Signals may be transmitted at predetermined times and/or intervals. The predetermined time may be fixed or changing. The time may be predetermined, e.g., by a controller. FIG. 9 shows an example of signal transmission between components. In the example of FIG. 9, signals are sent over network of components 920 by a transmitter of component 901 and are received by receivers of components 902-907. In the example of FIG. 9, signals are sent by transmitters of components 902-907 and are received by a receiver of component 901. In the example of FIG. 9, signals are sent over network of components 920 by transmitter and receivers of the other components 902-907. Time of flight of signals between transmitters of components and receivers of components may be (i) stored as distance data in at least one memory and/or (ii) may be retrieved to determine a relative distance between the components. The relative distance may be utilized to create a map or topology of the community of components. The retrieval from memory may utilize data processing, e.g., by at least one processor. Other data types may include, but are not limited to: angle data, position data, location data, control data, sensor data, and/or component identification information data. The data may be stored in at least one memory. The data may be communicated over the network.

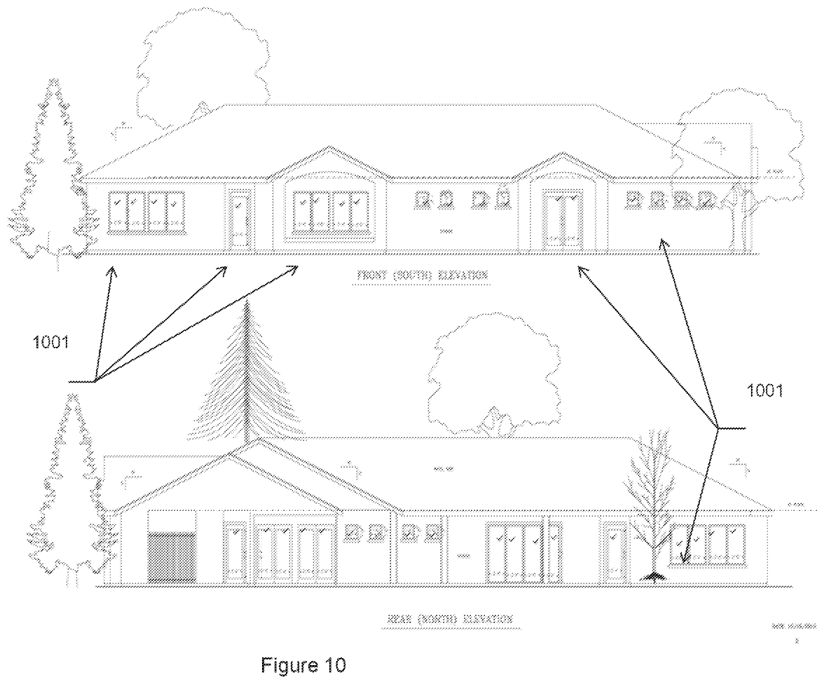

In some embodiments, an interconnect drawing is a package of drawings depicting many views of a structure. In some embodiments, an interconnect drawing package includes drawings that are similar but provide different information. For example, two drawings may depict the same floor plan, and one drawing may provide dimensional information, while another provides network IDs of components on the network. FIG. 10 provides an example of an interconnect drawing that depicts an elevation view of a structure from which the coordinates of IGUs 1001 and other network components may be determined. In some embodiments, interconnect drawings provide information relating to power distribution networks for electrochromic devices such as has been described in U.S. patent application Ser. No. 15/268,204, filed Sep. 16, 2016, now U.S. Pat. No. 10,253,558, issued Apr. 9, 2019, titled “POWER DISTRIBUTION NETWORKS FOR ELECTROCHROMIC DEVICES,” which is incorporated herein by reference in its entirety.

Modifications to interconnect drawings may be required in certain situations. For example, an installer might determine that a window opening is too small for the window prescribed by the instructions in the digital twin (e.g., interconnect drawings and/or BIM) and decide to install a smaller window. To correct for the change, the digital twin may need to be updated. A network configuration file or other structure storing mappings between devices (e.g., optically switchable windows) and associated controllers may be created or modified to reflect the real-world installation. With the correct mapping in place, the network will function properly. In some cases, if a network configuration file is not representative of the physical network, then device configuration instructions (e.g., window tinting instructions) may be sent to the wrong component, or communications may not be received at all.

In some embodiments, the facility has an associated digital twin. When the digital twin (e.g., interconnect drawing) of the facility is revised, the corresponding (e.g., linked) network configuration file may be revised as well. Such revision may be manual and/or automatic. Such revisions may be done in real-time (e.g., during update of the digital twin file, at a predetermined time, or at a whim. In some embodiments, a network configuration file is not created until physical installation has been completed, e.g., to ensure that any changes in the digital twin are reflected in the network configuration file. In cases where the interconnect file is modified after the network file is created, care should be taken to ensure that the network configuration file is updated to reflect changes. Failure to update an interconnect drawing or failure to update a network configuration file to reflect changes made to the digital twin (e.g., an interconnect drawing) may result in a network that does not respond to instructions as intended. Further, the digital twin (e.g., an interconnect drawing) may be updated when commissioning takes place (e.g., in real time). To correct for changes made during installation that deviate from an interconnect drawing, device (e.g., optically switchable window) information may be obtained from a file containing the device ID (lite ID for a window, for example). When the digital twin (e.g., an interconnect drawing) has been created, or when the digital twin has been updated to account for a change in installation, a (e.g., respective) network configuration file may be created or updated. The configuration file may be further updated when commissioning takes place (e.g., in real time), or at a (e.g., designated) time thereafter. The network configuration file when initially rendered, may not include network IDs for controllers or other components (e.g., devices) on, or operatively (e.g., communicatively) coupled to, the network.

In some embodiments, a network configuration file is a transcript of the digital twin (e.g., an interconnect drawing) in a computer readable format (e.g., comprising program instructions) that can be read, interpreted, and in some cases updated by controller(s) (e.g., via control logic software). At least some (e.g., all) of the network components (e.g., windows, window controllers, network controllers, sensors, emitters, and/or sensor ensembles) may be represented in a network configuration file. The network configuration file may contain information regarding how various devices on the network relate to each other, e.g., in a hierarchical structure.

In some embodiments, a network configuration file is a textual description of the digital twin (e.g., the interconnect drawings). Network configuration files may have a flat file format (e.g., with no facility structural information for indexing and/or no structural relationship between records). Examples of flat types include plain text files, comma-separated value files, and delimiter-separated value files. A JavaScript object notation format (JSON), or other object notation format that uses human-readable text to transmit data objects consisting of attribute-value pairs, may be used for a network configuration file. The information in a network configuration file can be stored in other formats and/or locations.

In some embodiments, a network configuration file takes a JSON format. Various devices and groupings of devices may be defined as JSON objects. For example, when defining a zone of windows as an object, comma-separated text may be used to encode what zone group the zone is a part of, what network controller or controllers the zone group reports to, and the master controller in charge of the network. The object may provide what window controllers, windows, and/or any additional network components (e.g., a photo sensor or window antenna) are included in the zone. Network components may be referenced in an object by at least a network ID. When initially generated from the digital twin (e.g., the interconnect drawing), a network configuration file may be incomplete in the sense that it does not yet include network IDs for at least one of the controllers.

Network configuration files may be stored at various locations in the window network. For example, a network configuration file may be stored on memory attached to a master controller, a network controller, a remote wireless device, or in the cloud. In some embodiments, a network configuration file is stored in one location from which all other devices on the network can access it. In another embodiment, network configuration files are stored locally on a plurality of devices on the window controller network: when a network configuration file is updated at one location, as when a new device is added to the network, the updated network configuration file is used to replace the out-of-date network files at other locations.

Using information from the network configuration file, control logic may send instructions to windows and/or other components (e.g., devices) on the network. Control logic can transmit instructions to a master controller 111 (FIG. 1), which in turn may transmit instructions to the appropriate network controller 112. In some embodiments, the network controller 111 transmits instructions to the appropriate local controller (e.g., window controller 114) over the network, e.g., using a BACnet communication protocol (building automation and control networks protocol, ISO16484-5). Local controllers may apply electrical signals to control the configuration of the device(s) based at least in part upon a local controller's control area network identification (CAN ID). For example, the window controllers may apply electrical signals to control the tint state of optically switching windows based at least in part upon a window controller's CAN ID.

In some embodiments, the control system utilizes control logic. Control logic (e.g., in the form of software and/or programmed hardware) may be stored and/or used at various places on a network. For example, control logic may be stored and used on a master controller. In some embodiments, software containing the control logic is run, locally, on the cloud, or on a remote device, e.g., which sends instructions to a higher hierarchy (e.g., master) controller. In some embodiments, a control logic is at least partially implemented via a facility management application that be operated from an electronic device.

In some embodiments, the control system is configured to receive user's input. One purpose of control logic may be to present controllable options to a user in the form of a graphical user interface that may enable a user to choose and/or control one or more electrochromic windows, and/or any other device, operatively coupled to the network. For example, a user may be presented with a list of lite IDs on the network from which the user may select and/or modify the attributes and/or configurations of the device, e.g., the tint state of a particular window. A user may send instructions (e.g., provide input) to control a grouping of devices (e.g., windows) based at least in part upon a zone of devices that has been predetermined or selected, e.g., by a user.

In some embodiments, the control logic communicates with other systems or modules such as window control intelligence, a BMS, and/or a security system. For example, a BMS may configure all windows to their tinted state in order to save cooling costs in the event of a power outage.

In some embodiments, automated device (e.g., window) location is determined after installation. Various devices (e.g., sensor ensembles, window controllers, windows configured with antennas and/or onboard controllers) may be configured with a transmitter to communicate via various forms of wireless electromagnetic transmission: e.g., time-varying electric, magnetic, or electromagnetic fields. Various wireless protocols and wavelengths used for electromagnetic communication include, but are not limited to, Bluetooth (BLE), Wi-Fi, and/or ultra-wideband (UWB). The electromagnetic radiation may comprise radio frequency (RF) radiation.

The relative location between two or more devices may be determined from information relating to received transmissions at one or more antennas and/or one or more transceivers: such as the received signal strength or power, time of arrival or phase, frequency, and/or angle of arrival of wirelessly transmitted signals. When determining a device's location from these metrics, a triangulation algorithm may be implemented that in some instances to account for the physical layout of a building, e.g., fixtures such as walls and non-fixtures such as mobile furniture. Ultimately, an accurate location of individual network components (e.g., devices) can be obtained using such or similar technologies. For example, the location of a window controller having a UWB micro-location chip can be determined to an accuracy of at least about 2.5 cm, 5 cm, 10 cm, 15 cm, 20) (cm) centimeters of its actual location, or a higher accuracy. In some instances, the location of one or more devices (e.g., windows) may be determined using geo-positioning methods such as those described in International Patent Application Serial No. PCT/US2017/031106, filed on May 4, 2017 titled “WINDOW ANTENNAS,” which is hereby incorporated by reference in its entirety. As used herein, geo-positioning and geolocation may refer to any method in which the position or relative position of a window or device is determined in part by analysis of electromagnetic signals.

In some embodiments, at least one device of the facility is located via UWB geolocation technology. Ultra-wideband (UWB) technology (ECMA-368, ECMA-369, and IEEE 802.15.3a) is a wireless technology for transmitting large amounts of data at low power. For example, in the United States, the Federal Communications Commission (FCC) limits power to no greater than −41.3 dBm/MHz within the frequency range of from about 3.1 to about 10.6 GHZ (see 47 CFR Part 15.209, Table 1). This power limitation enables UWB communication to take place over short distances (e.g., of at most about 200′, 230′, 250′, 500′, 600′, or 1000 feet (′)). UWB may transmit information using either single-carrier (pulse-based) or multi-carrier techniques. Single-carrier multiband systems can transmit information by modulating the phase of a (very) narrow pulse. One advantage of this type of system is that the transmitter may have a relatively simple design. In contrast to pulse-based systems, multi-carrier, multi-band systems can use orthogonal frequency division multiplexing (OFDM) techniques to transmit the information on one or more sub-bands within the from about 3.1 GHZ to about 10.6 GHz spectrum allocated to UWB by the FCC. OFDM may have some advantageous properties, including high spectral efficiency, inherent resilience to RF interference, robustness to multi-path, and the ability to efficiently capture multi-path energy. In some orthogonal frequency-division multiplexing (OFDM) UWB systems, the average transmit power can be from about −12 to about −8 dBm, with a typical peak-to-average power ratio of from about 8 to about 10 dB, yielding a peak power less than about, or equal to, zero (0)) dBm.

In some embodiment, a characteristic of single-carrier and/or multi-carrier UWB signals may be that the signal occupies at least about 500 MHz of bandwidth spectrum, or at least about 20% of its center frequency. A UWB component or device broadcasting digital signal pulses may be timed (e.g., precisely) on a carrier signal across a number of frequency channels at the same time (e.g., simultaneously). Information may be transmitted by modulating the timing and/or positioning of pulses. Information may be transmitted by encoding the polarity of the pulse, its amplitude and/or by using orthogonal pulses.

Aside from being a low-power information transfer protocol, UWB technology may provide several advantages for indoor location applications over other wireless protocols. In some embodiments, the broad frequency range of the UWB spectrum comprises lower frequencies having longer wavelengths, which allows UWB signals to penetrate a variety of materials, including fixtures such as walls. The wide range of frequencies, including these lower and more penetrating frequencies, decreases the chance of multipath propagation errors as some wavelengths will have a line-of-sight trajectory. Another advantage of pulse-based UWB communication may be that pulses are short (e.g., at most about 50 cm, 60 cm, or 70 cm for an about 500 MHz-wide pulse: or at most about 20 cm, 23 cm, or 25 cm for an about 1.3 GHZ-wide pulse). This may reduce chances that reflecting pulses will overlap with the original pulse.

The relative locations devices and/or respective controller having geo-location technology (e.g., having a micro-location chip) can be determined using a geolocation technology such as using the UWB protocol. For example, using the geolocation technology (e.g., embedded in circuitry such as in a micro-location chip), the relative position of such device may be determined to an accuracy of at least about 2.5 cm, 5 cm, 10 cm, 15 cm, 20 cm, or higher accuracy. In some embodiments, the devices (e.g., device ensembles, controllers) are configured to communicate via the geo location technology (e.g., embedded in circuitry such as in a micro-location chip). The device may include an antenna disposed on or proximate a window or a local controller). In some embodiments, a controller is equipped with a tag having the geo location technology (e.g., embedded in circuitry such as in a micro-location chip). The circuitry may be configured to broadcast (e.g., UWB) signals. The signals may comprise omnidirectional signals or unidirectional signals. Receiving stationary geo-location technology (e.g., circuitry), may be located at a variety of locations such as a wireless router, a network controller, or a window controller. The stationary circuitry comprising the geo-location technology (e.g., referred to herein as “stationary geolocation circuitry” abbreviated herein as “SGC”) may have a known (e.g., absolute or relative) location in the facility. When the SGC has an absolute location, it is referred to as an anchor. The tags may be stationary or mobile. For example, the tag may be embedded in a device ensemble. For example, the tag may be embedded in a furniture or a service machine (e.g., an asset). The tag may be embedded in a fixture or in a non-fixture. For example, the tag may be carried by an occupant. By analyzing the time taken for a broadcast signal to reach the SGCs within the transmittable distance of the tag, the location of the tag may be determined, e.g., relative to the SGCs.

In some embodiments, an installer places temporary SGCs within a building for the purpose of commissioning which are then removed after the commissioning process is complete. In some embodiments in which there are a plurality of devices (e.g., optically switchable windows, window controllers) are equipped with SGC configured to send and/or receive UWB signals. The circuitry of the SGC can be any circuitry disclosed herein, e.g., comprised in a chip such as a microchip. By analysis of the received UWB signals at each device (e.g., window controller), the relative distance between the devices (e.g., window controller) located within the transmission range limits, may be determined. By aggregating this information, the relative locations between (e.g., all) the devices (e.g., window controllers) may be determined. When the location of at least one device (e.g., window controller) is known, and/or if an SGC is used, the relative location of other devices having a micro-location chip, may be determined. Such technology may be employed in an auto-commissioning procedure as described herein. It should be understood that the disclosure is not limited to UWB technology: any technology for automatically reporting (e.g., high-resolution) geographic location information may be used. Such technology may employ one or more antennas associated with the components to be automatically located.

A digital twin (e.g., Interconnect drawings or other sources of architectural information) of the facility may include location information for various network components. For example, devices (e.g., windows) may have their physical location coordinates listed in x, y, and z dimensions, with the technology prescribed accuracy: e.g., to within at least about one (1) centimeter. Files or documents derived from such digital twin (e.g., comprising drawings), such as network configuration files, may contain accurate physical locations of network components. In certain embodiments, coordinates correspond to one corner of (e.g., of a lite or IGU as installed in) the facility structure. The choice of a particular corner or other feature for specifying in the digital twin (e.g., interconnect drawing) coordinates may be influenced by the placement of an antenna or other location aware component. For example, a window and/or paired window controller may have a SGC (e.g., placed near a first corner of an associated IGU (e.g., the lower left corner)); in which case the interconnect drawing coordinates for the lite may be specified for the first corner. In the case where an IGU has a window antenna, listed coordinates on a digital twin (e.g., interconnect drawing) may represent the location of the antenna on the surface of an IGU lite or a corner proximate the antenna. In some embodiments, coordinates are obtained from architectural drawings and knowledge of the antenna placement on larger window components such as an IGU. In some embodiments, a window's orientation is included in the interconnect drawing.

While this specification often refers to digital twin (e.g., interconnect drawing) as a source of accurate physical location information for windows, the disclosure is not limited to digital twin (e.g., interconnect drawing). Any similarly accurate representation of component locations in a building or other structure having optically switchable windows may be used. This includes files derived from interconnect drawings (e.g., network configuration files) as well as files or drawings produced independently of interconnect drawings, e.g., via manual and/or automated measurements made during construction of a building. In some cases where coordinates cannot be determined from architectural drawings, e.g., the vertical position of a window controller on a wall, unknown coordinates can be determined by personnel responsible for installation and/or commissioning. Because architectural and interconnect drawings are widely used in building design and construction, they are used here for convenience, but the disclosure is not limited to interconnect drawings as a source of physical location information.

In some embodiments using (i) interconnect drawing (e.g., BIM) of the enclosure and (ii) geo-positioning, a logic scheme pairs component locations with network IDs (or other information not available in interconnect drawings) of components (e.g., devices). The locations can be indicated in the interconnecting drawing. The interconnected drawing may be a digital twin of the enclosure. The interconnected drawing may be a detailed representation of component locations. The logic scheme may be employed during commissioning. The devices may comprise a controller such as a local (e.g., window) controller. In some embodiments, this is done by comparing the measured relative distances between device locations provided by geo-positioning (e.g., using the SGC) and the listed coordinates provided on an interconnect drawing. When the location of network components may be determined with high accuracy (e.g., as disclosed herein for UWB such as better than about 10 cm) automatic commissioning may be performed in a manner that avoids the complications that may be introduced by manually commissioning of devices such as windows and/or window controllers.

The controller network IDs or other information paired with the physical location of a device (e.g., window or other component) may come from various sources. In some embodiments, a controller's network ID is stored on a memory device. The memory device can be operatively coupled to the network. The memory can be attached to a window (e.g., a dock for the window controller or a pigtail) or may be downloaded from the cloud based upon a device serial number. One example of a controller's network ID is a CAN ID (an identifier used for communicating over a CAN bus). In addition to the controller's network ID, other stored device information may include the controller's ID (not its network ID), the device component ID (e.g., a serial number for the lite), device type, device (e.g., window) dimensions, manufacturing date, bus bar length, zone membership, current firmware, and/or various other device details (e.g., layer makeup of an electrochromic device and their (e.g., relative) dimensionality). Regardless of which information is stored, at least part of this information (e.g., all the information) may be accessed during device use and/or during the commissioning process. Permission to access the information may comprise security layers. Once accessed, any or all portions of such information may be linked to the physical location information obtained from the digital twin (e.g., interconnect drawing), partially completed network configuration file, or other source.

In some embodiments, the logic scheme compares requested device locations to actual device locations. The logic scheme may include distances between the devices. For example, the logic scheme may include relative distances between requested device locations. For example, the logic scheme may include relative distances between actual device locations. The locations and/or relative distances can be incorporated in a table format or in any other format. For example, the locations can be incorporated in a vector form. For example, the locations can be incorporated in a matrix form. In some embodiments, the logic scheme utilizes one or more matrices. In some embodiments, the logic scheme performs one or more (e.g., algebraic) manipulation of matrices. A matrix can include device locations. For example, the matrix may include a column of actual device locations and a column of requested device locations. The logic scheme may compare the relative distances between any two requested device locations to relative distances between any two actual device locations (e.g., respectively). The logic scheme may search to identify patterns and/or significant differences in the relative distances (I) of the requested device locations and (II) of the actual device donations. The logic scheme may try to match identified patterns and/or significant differences (i) of the relative distances of the requested device locations with (ii) those of the actual device donations. Significant may be relative to an acceptable measuring error. Significant may be relative to an acceptable installation error in device installation. The patterns may comprise mathematical patterns. The patterns may comprise a mathematical series. The patterns may comprise repetitive distances, e.g., at a specific spatial arrangement. The significant differences may comprise a markedly large distance, or a markedly small distance, as compared to the other relative device distances. The logic scheme may consider locations (e.g., relative locations) of fixtures in the facility (e.g., adjacent to which, in which, or on which, the devices are installed). The logic scheme may consider locations (e.g., relative locations) of non-fixtures in the facility (e.g., adjacent to which, in which, or on which, the devices are installed). The non-fixtures may comprise furniture such as a table, a cubicle, locker, cabinet, closet, cupboard, machinery, or a sofa. The fixtures may comprise a wall, a ceiling, a floor, a framing, a shaft, a pipe, shelf, ledge, or rack. The framing can be a door framing or a window framing. The machinery can be an industrial (e.g., heavy) machinery, or an office or home machinery (e.g., printer, or vending machine). The machine can be a service machine.

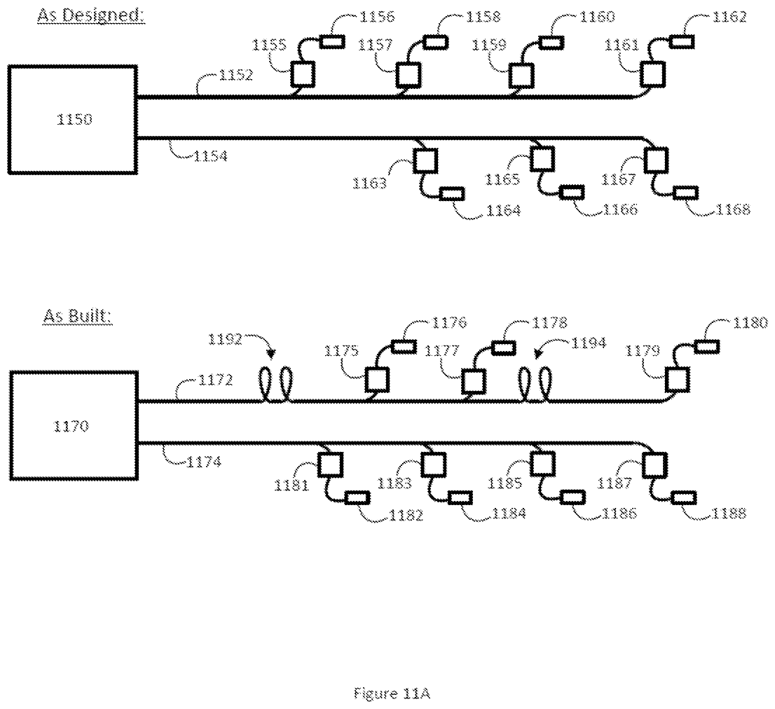

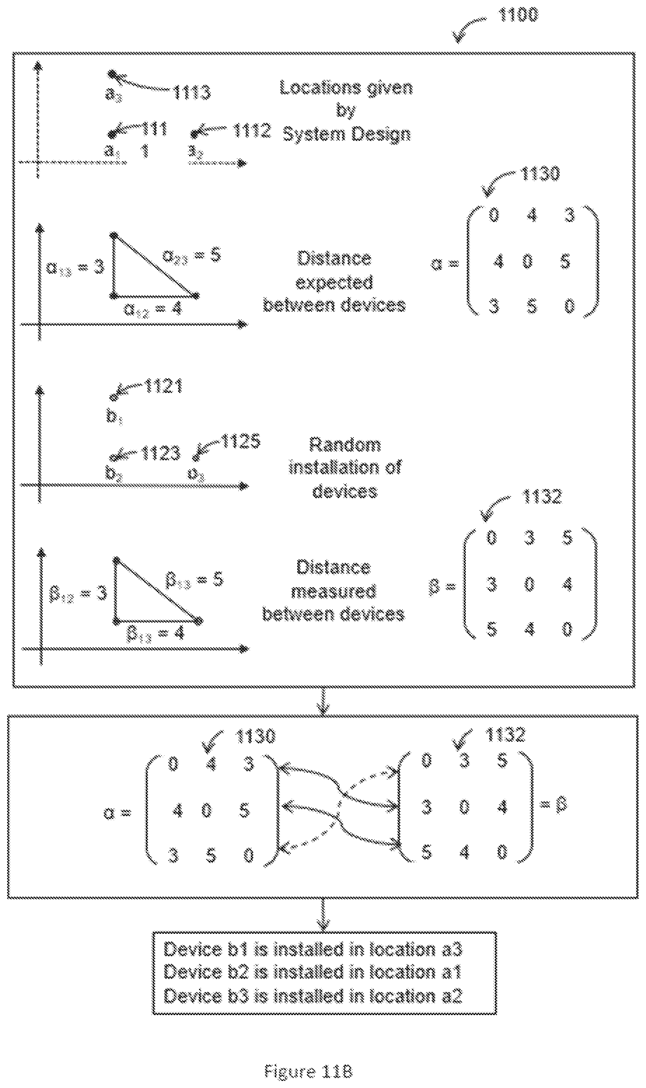

In some embodiments, a pairing of controller network IDs or other information with the physical location of a device may be facilitated using inherent network diagnostics and/or time domain reflectometry (TDR) based techniques. A better understanding of features and benefits of these techniques may be obtained by referring to FIG. 11A, which illustrates a use case example to which the techniques may be applied. Although the illustrated example includes only “window controllers” coupled with trunk lines, it will be appreciated that other devices may be contemplated, including other types of controllers, sensors, antennas, receivers, transmitters, network diagnostic devices, etc. In the illustrated example, an “As-Designed” arrangement of control panel or network controller 1150, first trunk line 1152, coupled with window controllers 1155, 1157, 1159 and 1161 and IGUs 1156, 1158, 1160 and 1162, second trunk line 1154 coupled with window controllers 1163, 1165 and 1167 and IGU's 1164, 1166 and 1168 is compared with a hypothetical “As-Built” arrangement of control panel or network controller 1170, first trunk line 1172 and second trunk line 1174. It may be observed that the hypothetical As-Built arrangement differs from the As-Designed arrangement inasmuch as first trunk line 1172 is coupled with three sets of window controllers (1175, 1177, 1179) and IGUs (1176, 1178, 1180), rather than four, as depicted in the As-Designed arrangement. Moreover, second trunk line 1174 is coupled with four sets of window controllers (1181, 1183, 1185 and 1187) and IGUs (1182, 1184, 1186 and 1188), rather than three, as depicted in the As-Designed arrangement. Finally in the “As Built” arrangement, first trunk line 1172 is shown to include extraneous lengths of cable 1192 and 1194, not foreseen by the “As-Designed” arrangement.

The illustrated examples of unintended differences between the “As-Designed” and the “As-Built” arrangements are not uncommon at a building site, and in the absence of the disclosed techniques, may adversely affect network control, if uncorrected, while also being costly to identify and correct. For example, a signal transmitted to controllers coupled to a trunk line will vary in strength as a function of distance along a cable length between the control panel/network controller and each window controller. In some embodiments, this problem is mitigated by using inherent network diagnostic tools that may, in some examples, be supplemented with TDR.

In some implementations, for example, a signal-to-interference-plus-noise ratio (SINR) of signals from two or more window controllers is measured proximate to a headend of a trunk line (e.g. by, at or proximate to the control panel/network controller). The window controller exhibiting the better (best) SINR may be determined to be closer (closest) to the headend.

Moreover, in some implementations, window controllers and the control panel are configured as networked devices compliant with the G.hn specification developed by the International Telecommunication Union. As such, network diagnostics are available with which the order, including relative distances between local controllers (e.g., window controllers) and the control panel, may be determined. In some implementations, time domain reflectometry (TDR) may be employed, separately or together with G.hn network diagnostics to obtain at least approximate relative location information for each window controller.

Returning to the use case example of FIG. 11A, it will be appreciated that the present techniques enable identifying discrepancies between the “As Designed” arrangement and the “As Built” arrangement. For example, TDR data obtained by transmitting an incident TDR signal onto an As Built trunk line and registering reflections of that signal from devices coupled with the trunk line may be used to identify the length and approximate location of the extraneous lengths of cable 1192 and 1194. Similarly, the absence of an expected controller on the As Built first trunk line 1172 and the presence of an unplanned controller on the As Built second trunk line 1174 may be detected from the TDR data. Although not illustrated in FIG. 11A, it will be appreciated that TDR data may aid in the detection of other variances between an As-Built arrangement and an As-Designed arrangement, such as the unanticipated presence of other devices, such as sensors, antennas, transceivers, or other controllers, for example, coupled with a trunk line. Similarly, the TDR data may aid in the detection of an unanticipated absence of any of such devices,

Referring still to FIG. 11A, in some implementations the control panel or network controller 1170 may be configured to transmit the incident TDR signal and/or register and/or analyze the reflections of the incident TDR signal. In some examples, other devices that may be co-located with, disposed proximate to or included in the control panel or network controller 1170 may transmit the incident TDR signal and/or register and/or analyze the reflections of the incident TDR signal. Advantageously, the incident TDR signal may be transmitted over and reflections of the incident TDR signal may be received by way of a trunk line (e.g. trunk line 1172 and/or 1174).

The present techniques facilitate and largely automate identifying discrepancies between the As-Designed and the As-Built arrangements. As a result, the discrepancies may be timely corrected at the building site, and/or the impact of the discrepancies may be mitigated by adjusting, for example, signal strength, controller algorithms and/or controller addressing.

Alternatively, or in addition, as indicated above, a window controller's network ID or other information may be paired with the physical location of the window controller. For example, a window controller's network ID may be stored on a memory device operatively coupled to the network. The physical location of each window controller may be determined, in some implementations, by comparing data from the building's BIM file and/or digital twin with the relative location information obtained by TDR and G.hn network diagnostics. As a result, an accurate mapping of the location of each window controller and its associated IGU may be obtained. FIG. 11B depicts an example of a network 1100 showing a set of requested device locations and a set of actual (e.g., real world such as installed) device locations. The set of requested device locations includes a first requested location a1 1111 for a first planned device, a second requested location a2 1112 for a second planned device, and a third requested location a3 1113 for a third planned device. In some embodiments, the first, second, and third planned devices include UWB SGCs, sensors, sensor ensembles, other types of devices, and/or any of various combinations thereof. Requested locations a1 1111, a2 1112, and a3 1113 can be specified, for example, in a system design (e.g., a Revit file). Based upon the requested locations a1 1111, a2 1112 and a3 1113, a set of expected distances between the planned devices can be determined. A first expected distance α12 is defined as the expected distance between the first requested location a1 1111 and the second requested location a2 1112. In the present example, the first expected distance α12 is equal to 4. A second expected distance α13 is defined as the expected distance between the first requested location a1 1111 and the third requested location a3 1113. In the present example, the second expected distance α13 is equal to 3. A third expected distance α23 is defined as the expected distance between the second requested location a2 1112 and the third requested location a3 1113. In the present example, the third expected distance α23 is equal to 5. An expected distances matrix α 1130 incorporates the first expected distance α12 (equal to 4 in the present example), the second expected distance α13 (equal to 3 in the present example), and the third expected distance α23 (equal to 5 in the present example).

An installer now installs devices in a random order in an enclosure. In some embodiments, the installer can use the set of requested device locations as a reference or guide during the installation process. In some embodiments, the physical installation process may result in random discrepancies or errors between requested locations and installed locations of devices. Referring again to FIG. 11B, a first installed device b1 may be installed at a first installation location 1121. A second installed device b2 may be installed at a second installation location 1123. A third installed device b3 may be installed at a third installation location 1125. Based upon the installed locations 1121, 1123 and 1123, a set of measured distances between the devices can be determined. A first measured distance β12 is defined as the measured distance between the first installation location 1121 and the second installation location 1123. A second measured distance β13 is defined as the measured distance between the first installation location 1121 and the third installation location 1125. A third measured distance β23 is defined as the measured distance between the second installation location 1123 and the third installation location 1125. In the present example, the first measured distance β12 is equal to 3, the second measured distance β13 is equal to 5, and the third measured distance β23 is equal to 4. A measured distances matrix β1132 incorporates the first measured distance β12 (equal to 3 in the present example), the second measured distance β13 (equal to 5 in the present example), and the third measured distance β23 (equal to 4 in the present example).

To map (e.g., match) the set of requested device locations to the installed device locations, each row of the requested distances matrix α 1130 is compared against each row of the measured distances matrix β1132. The comparison identifies a row of the requested distances matrix α 1130 that most closely matches a row of the measured distances matrix β 1132. These most closely matched rows are mapped to one another, and the comparison process is repeated with the remaining rows in the requested distances matrix α 1130 and the measured distances matrix β 1132.

In the present example, the first row of the requested distances matrix α 1130, setting forth distances {0,4,3}, most closely matches the second row of the measured distances matrix β 1132, setting forth distances {3,0,4}. Thus, the first row of the requested distances matrix α 1130 is mapped to the second row of the measured distances matrix β 1132. Likewise, the second row of the requested distances matrix α 1130, setting forth distances {4,0,5}, matches the third row of the measured distances matrix β 1132, setting forth distances {5,4,0}. Thus, the second row of the requested distances matrix α 1130 is mapped to the third row of the measured distances matrix β 1132. Similarly, the third row of the requested distances matrix α 1130, setting forth distances {3,5,0}, matches the first row of the measured distances matrix β 1132, setting forth distances {0,3,5}. Thus, the third row of the requested distances matrix α 1130 is mapped to the first row of the measured distances matrix β 1132. Based upon the row-to-row mapping of the requested distances matrix α 1130 to the measured distances matrix β 1132, it is determined that the first installed device b1 is installed at the third requested location a3 1113, the second installed device b2 is installed at the first requested location a1 1111, and the third installed device b3 is installed at the second requested location a2 1112.

One may face a combinatorial optimization problem to solve for random location deviations of installed devices from their requested locations (e.g., installer errors). The requested locations may be provided based at least in part on a digital twin (e.g., a Revit file) of an enclosure (e.g., a facility, building, or room that incorporates requested locations of devices and their types). An installer (e.g., field service engineer) may install devices (e.g., low-voltage electrician services). A traveler (e.g., a field service engineer or drone) may record installed locations of devices. Information about the installed locations may be fed into the digital twin. For a network that includes N devices, there are N! possible mappings. Exhaustive searches are not possible for moderate to large values of N. For example, if N=59, this yields N!=1.4×10⁸⁰ possible mappings. Thus, in some embodiments, an automatic mapping procedure is performed.

In some embodiments, the logic scheme utilizes problem-solving heuristic. The heuristic may comprise seeking local and/or global extremum. The heuristic may optimize between a best solution and a time required to reach the best solution. In some embodiments, the heuristic may compromise on time. In some embodiments, the heuristic may compromise of overall optimal solution. The heuristic may utilize logic schemes utilized for traveling salesman problem and/or for a minimum spanning tree problem, and/or knapsack (e.g., source allocation) problem of combinatorial optimization. The heuristic may utilize one or more methodologies of combinatorial optimization. For example, the heuristic may comprise making locally optimal choice (e.g., seeking for local minima). The locally optimal choice may be evaluated at least one (e.g., at each) comparison stage between requested and actual relative distances. For example, the heuristic may comprise using a Greedy Algorithm. The greedy algorithm may comprise pure greedy algorithm, orthogonal greedy algorithm, or relaxed greedy algorithm. The heuristic may not generate an optimal solution, but rather a locally optimal solutions that approximate a globally optimal solution in a reasonable amount of time. The heuristic may comprise a matroid. The logic scheme may comprise a vector space. For example, the logic scheme may comprise a submodular function. The logic scheme may comprise an operation research, algorithm theory, or a computational complexity scheme. The logic scheme may include finding an optimal solution from a finite set of solutions. The logic scheme may include optimization. e.g., in which a set of feasible solutions is discrete or can be reduced to discrete, and in which the goal is to find the best (local and/or global) solution. The logic scheme may comprise discrete optimization, combinatorial optimization, and/or mathematical optimization. The logic scheme may comprise a systematic enumeration of candidate solutions by means of state space search. The set of candidate solutions may be akin to forming a rooted tree with the full set at the root. The logic scheme may explore branches of such tree, which represent subsets of the solution set. Before enumerating the candidate solutions of a branch, the branch may be checked against upper and lower estimated bounds on the optimal solution. The branch may be discarded if it cannot produce a better solution than the best one found so far by that logic scheme module. The logic scheme may depend at least in part on efficient estimation of the lower and upper bounds of regions/branches of the solution search space. If no bounds are available, the logic scheme module may perform an exhaustive search. The logic scheme may comprise a Branch and bound, A-star (A*), B-star (B*), or alpha-beta search logic schemes. The logic scheme may comprise a graph traversal or a path search logic scheme. The logic scheme may comprise a best-first graph search logic scheme. The logic scheme may comprise a minimax logic scheme. The logic scheme may comprise one or more logic scheme modules (e.g., a combination of modules). A logic scheme module may utilize one algorithmic scheme (e.g., one heuristic scheme). The logic scheme modules may be combined. A logic scheme module may have a weight. At least two logic scheme modules may have a different weight. At least two logic scheme modules may have (e.g., substantially) the same weight. At least two logic scheme modules may form a weighted combination in the overall logic scheme, to generate a result.

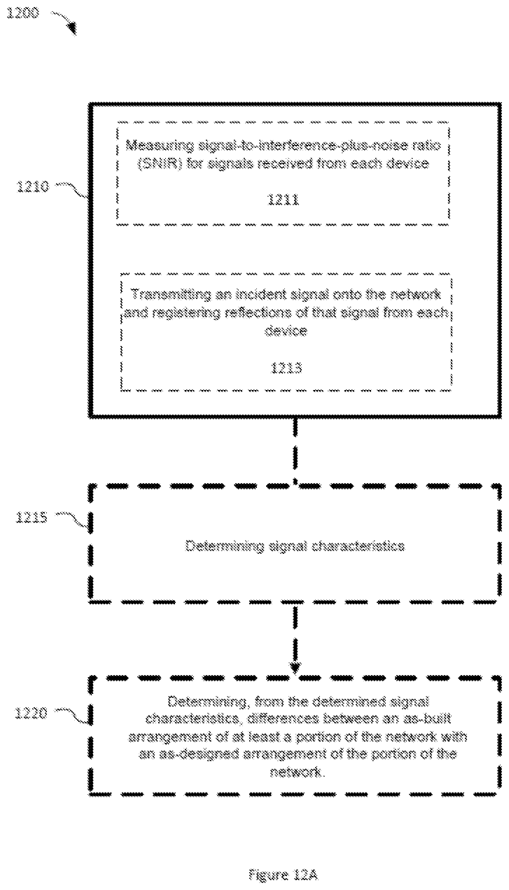

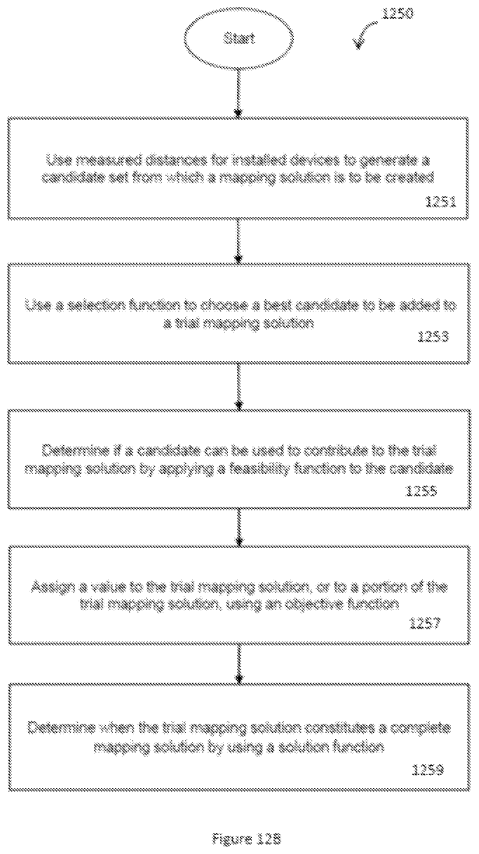

Referring now to FIG. 12A, a method 1200 for determining a relative location of each of a plurality of devices within a network will be described. As indicated above, the devices may be communicatively coupled by the network with a control panel or network controller. The method includes, at block 1210, executing the processes of one or both of blocks 1211 and/or block 1213. In accordance with block 1211, ssignal-to-interference-plus-noise ratio (SINR) for signals received from each device may be measured. In accordance with block 1213, an incident TDR signal may be transmitted onto the network and reflections of that signal from each device may be registered.

In some implementations, referring again to FIG. 11A, the processes of blocks 1211 and/or 1213 may be performed by the control panel or network controller 1170, for example, or a device associated therewith (that may be co-located with, disposed proximate to or included in the control panel or network controller 1170) in cooperation with one or more window controllers (e.g., one or more of window controllers 1175, 1177, 1179, 1181, 1183, 1185, 1187). Moreover, the signals contemplated by the present method may, advantageously be transmitted from and/or received by the control panel or network controller 1170 or associated device by way of a trunk line (in the illustrated example by trunk line 1172 and/or trunk line 1174, for example).

Optionally, in accordance with block 1215, characteristics of signals resulting from executing blocks 1211 or 1213 may be determined. For example, the relative signal strength of signals received from two or more window controllers may be analyzed to determine a relative distance of the respective window controllers from, for example the control panel or network controller 1170. As a further example, actual characteristics (e.g., of the As-Built arrangement) of the reflections of an incident TDR signal may be analyzed and/or compared to expected (e.g. of the As-Designed) configuration.

In accordance with block 1220, differences between an as-built arrangement of at least a portion of the network with an as-designed arrangement of the portion of the network may be determined. For example, as indicated in connection with FIG. 11A above, the unanticipated presence of equipment coupled with the trunk line (e.g., an additional window controller or the unanticipated presence of other devices, such as sensors, antennas, transceivers, or other controllers) may be detected. Similarly an unanticipated absence of any of such devices may be detected. The detection may result, in some implementations from comparing an actually measured “signature” of reflected signals from an incident TDR signal with an expected signature, where the signature may include one or more of signal frequency, phase and amplitude, for example.

FIG. 12B shows an example of a flowchart 1250 showing a first illustrative Greedy type procedure (e.g., procedure based at least in part on a Greedy Algorithm) for mapping a set of requested device locations to a set of installed device locations. The Greedy type procedure follows a problem-solving heuristic of making a locally-optimal choice at each of a plurality of stages. In some cases, the Greedy type procedure may not produce an optimal solution, but nonetheless a Greedy type heuristic may yield locally optimal solutions that approximate a globally optimal solution in a reasonable amount of time. Measured distances for installed devices are used to generate a candidate set from which a mapping solution is to be created (block 1251). A selection function is used to choose a best candidate to be added to a trial mapping solution (block 1253). Next, determine if a candidate can be used to contribute to the trial mapping solution by applying a feasibility function to the candidate (block 1255). Assign a value to the trial mapping solution, or to a portion of the trial mapping solution, using an objective function (block 1257). Then, determine when the trial mapping solution constitutes a complete mapping solution by using a solution function (block 1259).

The Greedy type procedure of FIG. 12B may be performed using on-site calculations, and/or remotely (e.g., in a cloud) to automatically find the installed locations of devices in a facility. The approximate locations of the devices can be determined using a mapping algorithm and adjusting the digital twin accordingly. The installed locations of the devices can be fine-tuned by updating the digital twin to form a resulting digital twin. Errors between requested locations and installed locations may occur due to incorrect (e.g., imprecise) placements of devices, resulting in a discrepancy between the digital twin and the real-world enclosure. In some embodiments, one can compare the manual and automatic mapping to locate any discrepancies, and/or to refine the automatic location computation scheme.

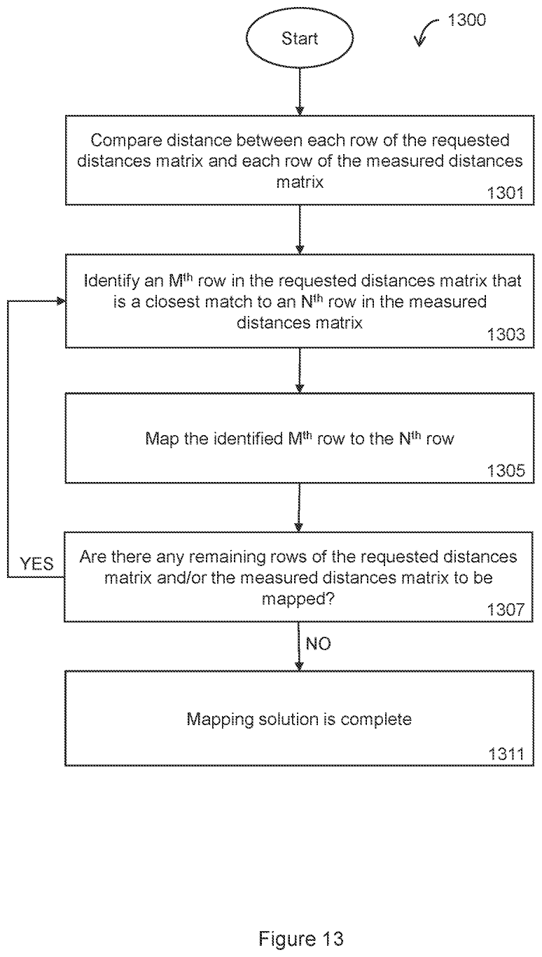

FIG. 13 is a flowchart showing a second illustrative Greedy type procedure for mapping a set of requested device locations to a set of installed device locations. At block 1301, a comparison is performed of the mathematical distance between each row of the requested distances matrix α 1130 (FIG. 11B) and each row of the measured distances matrix β 1132. An Mth row in the requested distances matrix α 1130 is identified as being the closest match to an Nth row in the measured distances matrix β 1132 (FIG. 13, block 1303). M is a positive integer equal to the number of rows in the requested distances matrix α 1130 (FIG. 11B), and N is a positive integer equal to the number of rows in the measured distances matrix β 1132. Next, at block 1305 (FIG. 13), the identified Mth row of the requested distances matrix α 1130 (FIG. 11B) is mapped to the Nth row of the measured distances matrix β 1132. Then, at block 1307 (FIG. 13), a test is performed to ascertain whether or not there are any remaining rows of the requested distances matrix α 1130 (FIG. 11B) and/or the measured distances matrix β 1132 to be mapped. If not, the mapping solution is complete (FIG. 13, block 1311). The affirmative branch from block 1307 loops back to block 1303 (described previously).

The Greedy type procedure of FIG. 13 runs in polynomial time. In some embodiments, execution may take at most a few seconds. On occasion, the Greedy type procedure can generate an error in a device mapping. However, this procedure can provide a good initial guess for installed device placement.

In some embodiments, the Greedy type procedure of FIG. 12B and/or FIG. 13 may be performed by considering a set of relative distances between (e.g., asymmetrically placed) devices that are requested in the digital twin (e.g., a Revit file), and installed device locations in the real world enclosure. The Greedy type procedure is followed to find a specific device placement signature. This approach can improve the speed of the Greedy type procedure, but it is not guaranteed to always provide a correct solution. One example of a device placement signature includes a first device that is situated at a relatively large distance from every other device (e.g., the sum of all of the device-to-device distances, and the first device having the largest distance is designated as a reference device, if this device is known from the Revit file). Another example of a device placement signature is a centrally located first device that has several equally-distanced other devices spaced from it. Yet another device placement signature is a device that is situated asymmetrically with respect to other devices, in a particular known arrangement that is easily discoverable using (e.g., relative) distance measurements. For example, the only occurrence in an enclosure where four devices (e.g., sensors) are arranged in a particular distance-series (e.g., distance-series=X, 2X, 3X, and 4X, where X is a distance).

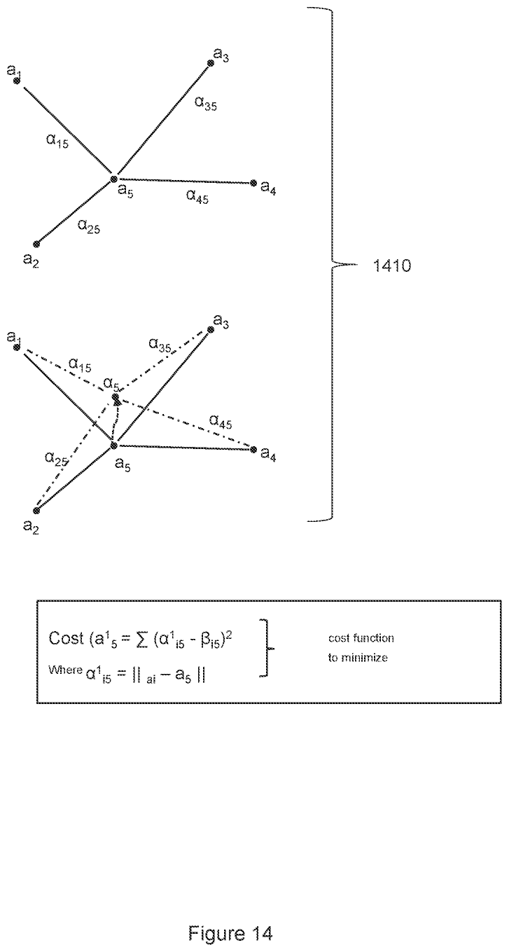

FIG. 14 is a graphical depiction illustrating an initial device location a5 before correction, and an optimized device location α5 after correction. The optimized device location α5 is determined by minimizing a cost function. In some embodiments, the cost function can be defined as: Cost (a15=Σ(α1i5−βi5)2, where α1i5=II ai-a5 II.

FIG. 14 shows an example of some device placements. In some embodiments, a device placement signature 1410 is provided by situating a device asymmetrically with respect to other devices, in a particular known arrangement that is easily discoverable using (e.g., relative) distance measurements. The device placement signature 1410 includes a set of locations a1, a2, a3, a4, and a5. The distances between these locations can be defined with reference to location a5 as follows: A first distance α15 is the distance between location a1 and location a5. Likewise, a second distance α25 is the distance between location a2 and location a5. Similarly, a third distance α35 is the distance between location a3 and location a5. A fourth distance α45 is the distance between location a4 and location a5. In some embodiments, the device placement signature can comprise a location arrangement where the only occurrence in an enclosure are four devices (e.g., sensors) arranged in a particular distance-series (e.g., distance-series=X, 2X, 3X, and 4X, where X is a distance). For example, the first distance α15 can be X, with the second distance α25 being 2X (or twice the first distance α15), the third distance α35 being 3X, and the fourth distance α45 being 4X. Note that FIG. 14 is not drawn to scale.

In some embodiments, a device placement signature 1410 is provided by situating a device symmetrically with respect to other devices, in a particular known arrangement that is easily discoverable using (e.g., relative) distance measurements. For example, the first distance α15 can be X, with the second distance α25 being X, the third distance α35 being X, and the fourth distance α45 being X. As before, note that FIG. 14 is not drawn to scale. The device placement signature 1410 can be formulated while designing and/or requesting device placements in the interconnected drawing (e.g., BIM such as Revit) file, and strategically utilized in the Greedy type procedure of FIG. 12B and/or FIG. 13.

In some embodiments, sensors are placed in a facility. The sensors can be placed in requested locations to facilitate their function. In case the arrangement of the sensors is symmetric, the sensors may be repositioned to form an asymmetric arrangement. Breaking the symmetry of the arrangement may be within a threshold that permits them to perform according to their intended (e.g., originally requested or planned) function. For example, sensors designated to sense within a certain spatial range can be repositioned to still cover, or substantially cover, that spatial range.

In some embodiments, the logic scheme utilizes Branch and Bound type scheme. Branch and Bond is a methodology for solving discrete and combinatorial optimization problems. A Branch and Bound procedure provides a systemic enumeration of candidate solutions by means of a state-space search (e.g., space of solutions). The set of candidate solutions is thought of as forming a rooted tree with the full set of solutions at the root. The procedure explores branches of the tree, where the branches represent subsets of the candidate solution set. Before enumerating the candidate solutions of a branch, the branch is checked against the estimated upper and lower bounds of the optimal solution. The branch is discarded if it cannot produce a better solution than the best solution found so far while executing the procedure. The procedure depends on an efficient estimation of the upper and lower bounds of regions/branches of the search space (e.g., presence of a solution in a set). If no bounds are available, the Branch and Bound procedure degenerates into performing an exhaustive search.

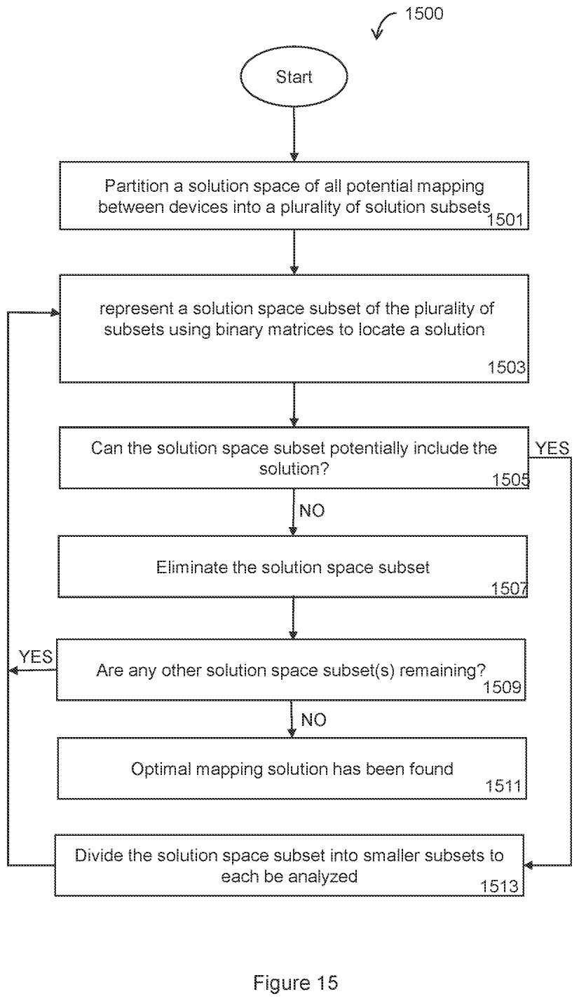

FIG. 15 shows an example of a flowchart showing a first illustrative Branch and Bound type procedure (e.g., procedure based at least in part on a Branch and Bound Algorithm) for matching a set of requested device locations to a set of installed device locations. At block 1501, a solution space of all the potential mapping between devices is partitioned into a plurality of solution space subsets to each be analyzed. A (e.g., first) solution space subset of the plurality of subsets is represented using binary matrices to locate a solution within the solution set subset, e.g., by computing the search space and applying user-recursive algorithms (block 1503). Then, at block 1505, a test is performed to probe whether the solution space subset can potentially include the solution. If so, the procedure advances to block 1513 where the analyzed solution subset is divided into smaller subsets (e.g., to generate a second solution subset and a third solution subset), and the procedure then loops back to block 1503 (described previously) where, e.g., the second solution subset is analyzed. The negative branch from block 1505 leads to block 1507 where the empty solution subset is eliminated. Then, a test is performed at block 1509 to ascertain whether or not any solution subsets are remaining. If so, the procedure loops back to block 1503 (described previously) to analyze the remaining solution subset. The negative branch from block 1509 leads to block 1511 where an optimal mapping solution has been found. The Branch and Bound type procedure may be robust, and guaranteed to locate the optimal mapping solution. However, it may be more time consuming as, e.g., the Greedy type computational scheme.

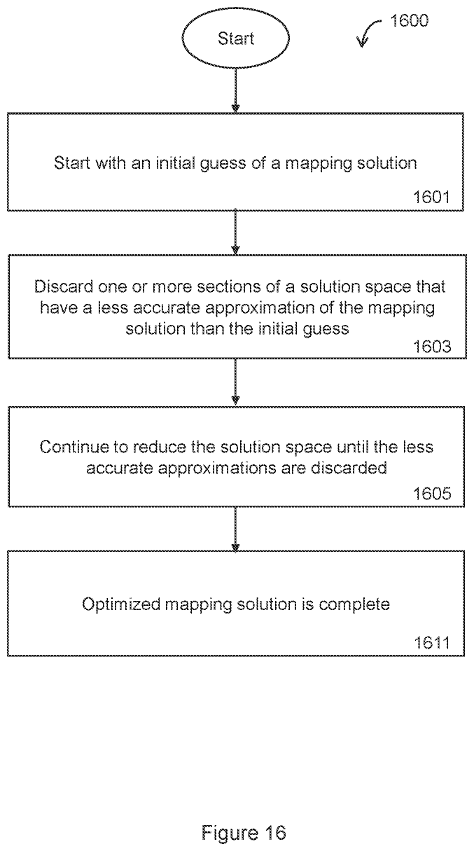

FIG. 16 shows a flowchart showing a second illustrative Branch and Bound type procedure for matching a set of requested device locations to a set of installed device locations by analyzing sections of a solution space for possible locations and/or distances. The procedure commences at block 1601 where an initial guess of a mapping solution is formulated. Then, at block 1603, one or more sections of a solution space are discarded which have a less accurate approximation of the mapping solution than the initial guess. These sections of a solution space can be conceptualized as branches of the tree, where the branches represent subsets of the candidate solution set. Before enumerating the candidate solutions of a branch, the branch is checked against an estimated upper bound of the optimal solution, and an estimated lower bound on the branch. The branch may be discarded if it cannot produce a better solution than the best solution found so far while executing the procedure. In some embodiments, this procedure depends on an efficient estimation of the upper and lower bounds of regions/branches of the search space (e.g., presence of a potential solution in a solution space subset).

The Branch and Bound type procedure of FIG. 16 advances to block 1605 where the solution space is reduced until (e.g., all of) the less accurate approximations of the optimal solution are discarded. Then, at block 1611, the optimized mapping solution is complete. The procedure of FIG. 16 is guaranteed to find the optimum mapping. In some cases, the procedure can be slow (e.g., it may take several minutes), but the procedure is faster than performing an exhaustive search. In some embodiments, the results of the Greedy procedure of FIG. 12B and/or FIG. 13 can be used to provide an initial guess of a mapping solution (FIG. 16, block 1601), to thereby bootstrap the Branch and Bound procedure of FIG. 16.

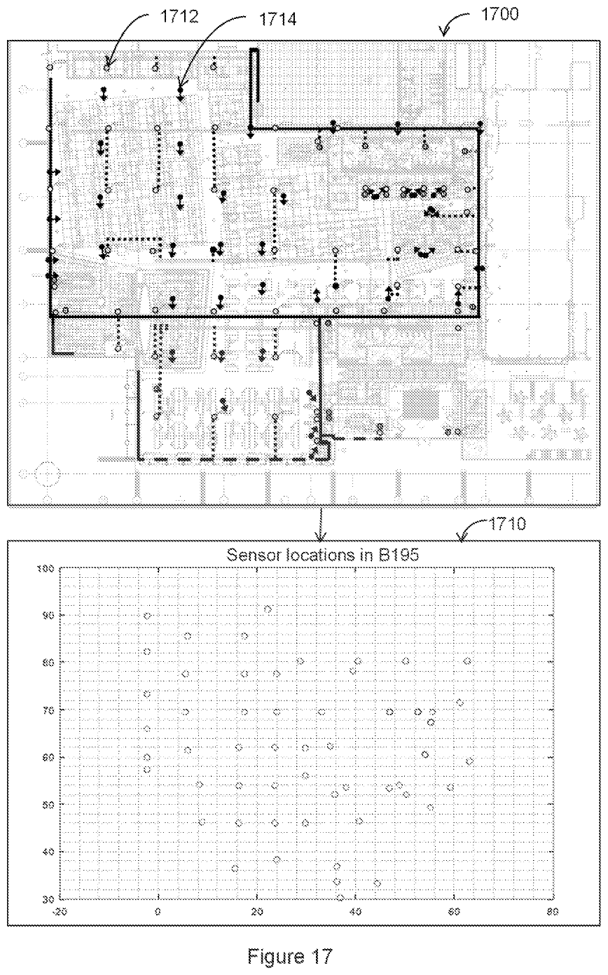

FIG. 17 depicts an example of a set of requested device locations and installed device locations for a portion of an enclosure identified as area B195. A depiction of a BIM (Revit) file 1700 for the area B195 shows a requested device location 1712 for a UWB sensor and an installed location 1714 for the UWB sensor. A normalized planar representation 1710 for the Revit file 1700 depicts requested sensor locations on an x-y graph.

In some cases, it can be difficult for the Branch and Bound procedures of FIGS. 15 and 16 to distinguish between closely-spaced pairs of devices (e.g., devices that are at most about 9 cm away from each other, according to the BIM (Revit) file). According to some embodiments, the Branch and Bound procedure may be performed using requested (e.g., planned) devices that are spaced apart by at least a minimum distance (e.g., a distance threshold), or by manually mapping devices that are too close to each other to allow for distinguishing between the devices.

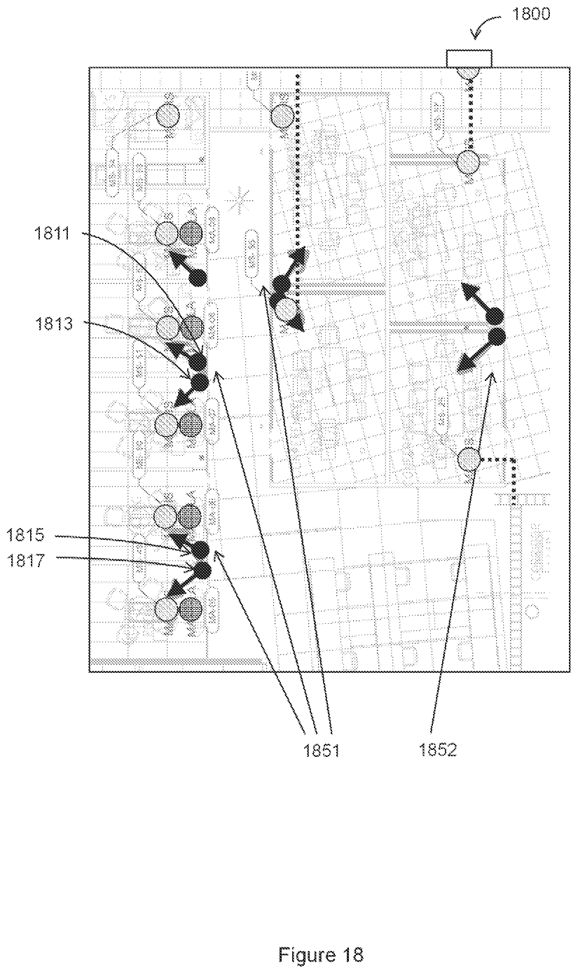

FIG. 18 depicts examples of closely-spaced device pairs 1851 in a portion of an enclosure. In some cases, it may be difficult to distinguish between individual devices within the device pairs 1851 when mapping a set of requested device locations to measured device locations. For example, a first sensor 1811 and a second sensor 1813 are spaced apart by less than approximately 9 cm according to a BIM (Revit) file. A third sensor 1815 and a fourth sensor 1817 are spaced apart by less than approximately 9 cm according to the BIM (Revit) file. In some embodiments, the requested device locations and/or the installed device locations are selected to provide at least an adequate amount of physical distance between device pairs, such that the first sensor 1811 can be distinguished from the second sensor 1813. In some embodiments, a manual mapping may be performed of the installed device locations, thereby enabling the first sensor 1811 to be distinguished from the second sensor 1813.

In some embodiments, the Greedy type procedure of FIG. 12B and/or FIG. 13 may be combined with the Branch and Bound procedure of FIG. 15 and/or FIG. 16. In some embodiments, instead of updating device locations one at a time, updating device locations can be performed simultaneously and/or contemporaneously. In some embodiments, asymmetric constraints can be imposed on certain dimensions of the device locations. For example, sensors can be in the ceiling, or wall-mounted at or near the height of a typical or average human. In some embodiments, a weight or regularization factor can be added to one or more dimensions of the device locations. In some embodiments, manual measurements of device locations are performed, and/or a drone (e.g., a traveler) is used to make measurements. In some embodiments, one or more additional constraints are added. One example of a constraint is not moving too far from a point C. Another example of a constraint is not moving outside of a bounded or defined area.

In some embodiments, a cost function is used in the logic scheme (e.g., in the Greedy type procedure and/or the Branch and Bound type procedure). One example of a cost function may be to compare L2 distances for devices, using an L2 metric such as the square root of (α-β)2, where α refers to the requested distances matrix α (FIG. 11B), and β 1130 refers to the measured distances matrix β 1132. In some embodiments, the cost function can be defined as: Cost (a15=Σ(α1i5−βi5)2, where α1i5=II ai-a5II. In some embodiments, the devices can be UWB devices (e.g., an SGC or a tag). In some embodiments, the devices can use any geolocation technology (e.g., using RF, BlueTooth, GPS, geolocation technology, and/or RFID tags). In some embodiments, a traveler (e.g., animate or inanimate) scans the (e.g., RFID) tags.

In some embodiments, the actual installed locations of devices are determined (e.g., correct device location discrepancies due to fixture placement discrepancies as compared to planned locations). This may be viewed as a location optimization problem that involves tracking an optimum location. An iterative correction process for installed location error may be performed (e.g., fixture or device location). In some embodiments, the iterative correction process commences with the location having the largest error. In some embodiments, the iterative correction process focuses on all erroneous device locations, regardless of the size of the error. Iterating over all devices and correcting their locations may have a greater success rate when one device is installed relatively close to its requested location, and other devices are disposed further away from their requested locations.

In some embodiments, at least two (e.g., all) device locations are corrected sequentially (e.g., one device location is corrected at a time). In some embodiments, at least two (e.g., all) device locations are corrected in parallel. A parallel location correction approach may result in a faster convergence time for determining an optimum mapping, as compared to sequential location correction. The minimization may occur over N×3 dimensions, instead of over three (3) dimensions.

In some embodiments, asymmetric constraints are strategically imposed on certain dimensions. For example, if we know that a vertical (z) dimension must be between zminimum and zmaximum from the floor level, we may add an additional regularization factor to the cost function to be minimized to take this z constraint into account. In some embodiments, symmetric constraints are performed on dimensions (e.g., due to enclosure structural requirements or properties). For example, when devices are arranged asymmetrically throughout a facility such as throughout a floor or an enclosure such as a room of a facility (e.g., building). Such asymmetry may reduce errors in coupling actual device location with requested device locations (e.g., eliminating any symmetric permutation on the requested device location set and on the actual device location set).

In some embodiments, measurements from a ground truth fixture/device are utilized as SGC points. Weights are added to device location errors. The weights can correspond to confidence in location errors (e.g., to the likelihood that the location error is real). The weights can be selected so that a first device proximate to a ground truth location of a fixture/device has a larger weight compared to a second device that is further away from the ground truth location of a fixture/device relative to the first device. The installed locations of one or more devices may be measured and/or verified in the field (e.g., by a traveler), with higher weights being assigned to these measured and/or verified devices relative to non-measured and/or non-verified devices. Various strategies for optimum findings can be employed to find the best approach.

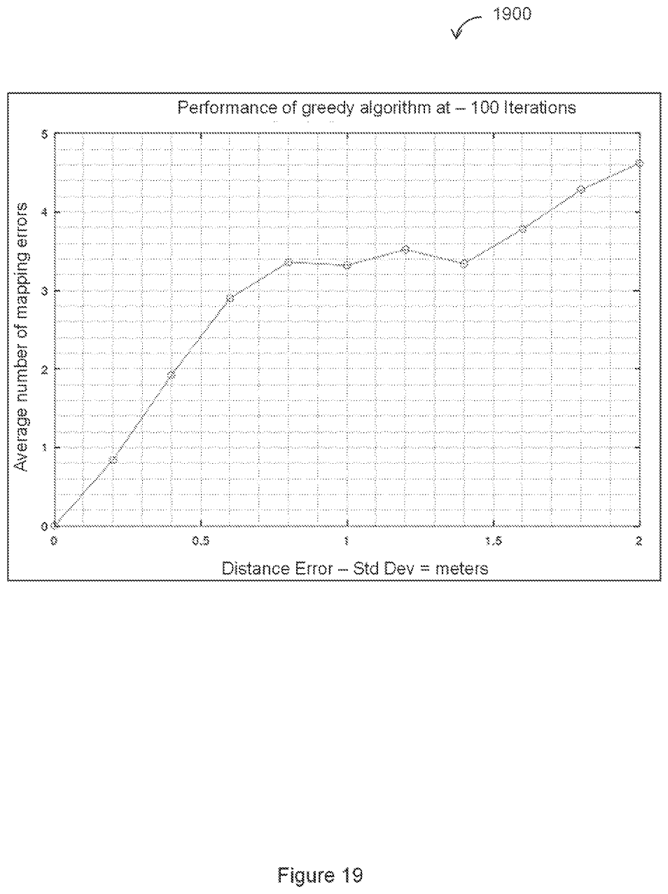

FIG. 19 shows an example of a graph 1900 showing an illustrative relationship between an average number of mapping errors and a distance error for matching a set of requested device locations to a set of installed device locations using 100 iterations of the Greedy procedure of FIG. 12B and/or FIG. 13. At a distance error of one (1) meter, the average number of mapping errors is approximately 3.3. At a distance error of two (2) meters, the average number of mapping errors increases to approximately 4.6. These mapping errors do not arise in the context of the Branch and Bound procedures of FIGS. 15 and 16. However, the Greedy procedure may be used to formulate a reasonable initial mapping guess or estimate, with the guess or estimate being used by the Branch and Bound procedure as an initial starting point for providing an optimized mapping. Thus, the logic scheme may include two or more logic scheme modules, at a certain order. For example, initially a less time consuming logic scheme module (e.g., including a mathematical scheme) is utilized to generate a first result that is used by a more time consuming logic scheme module (e.g., including a mathematical scheme) to generate a second result that provides a more accurate result than the first result generated by the first logic scheme module alone, and is less time consuming that using the second logic scheme module alone.

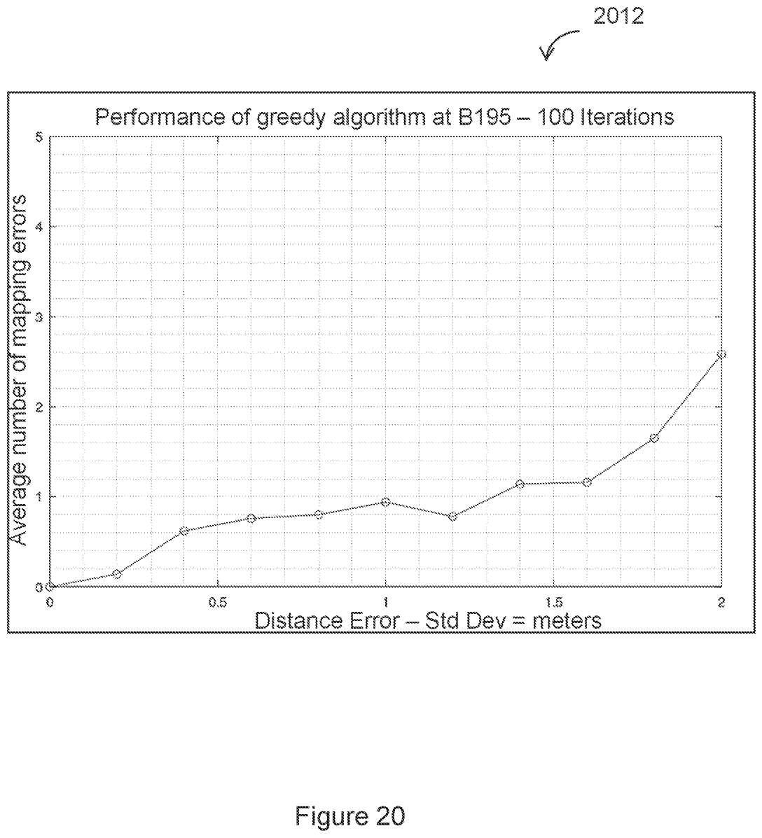

FIG. 20 shows an example of a graph showing an illustrative relationship between an average number of mapping errors and a distance error for matching a set of requested device locations to a set of installed device locations using the Greedy procedure applied to a portion of an enclosure designated as area B195 (FIG. 17). At a distance error of one (1) meter, the average number of mapping errors is approximately 1.0. At a distance error of two (2) meters, the average number of mapping errors increases to approximately 2.6.

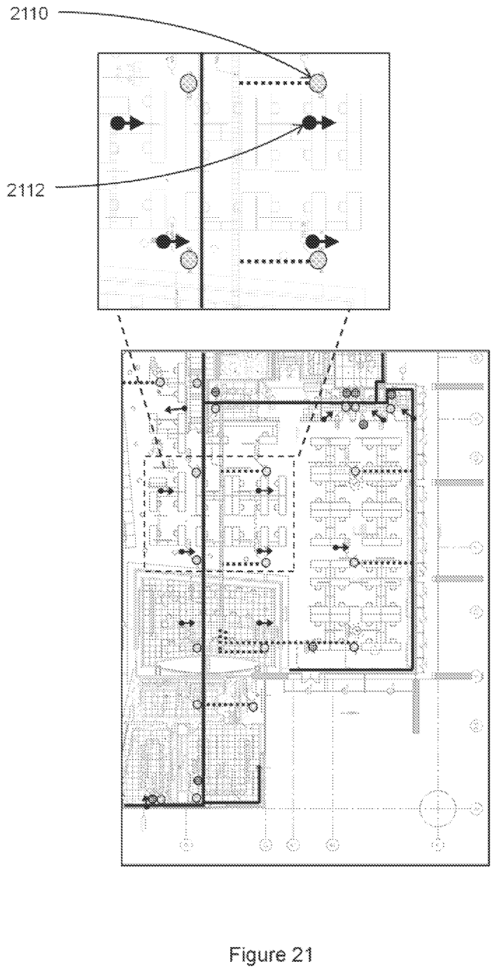

FIG. 21 shows an example of a portion of an enclosure showing requested device locations according to a system plan, and installed device locations based at least in part on visual inspection. A requested device location 2110 for a UWB SGC is shown, along with an installed device location 2112 for the UWB SGC. The installed device location 2112 may be determined based at least in part on visual inspection.

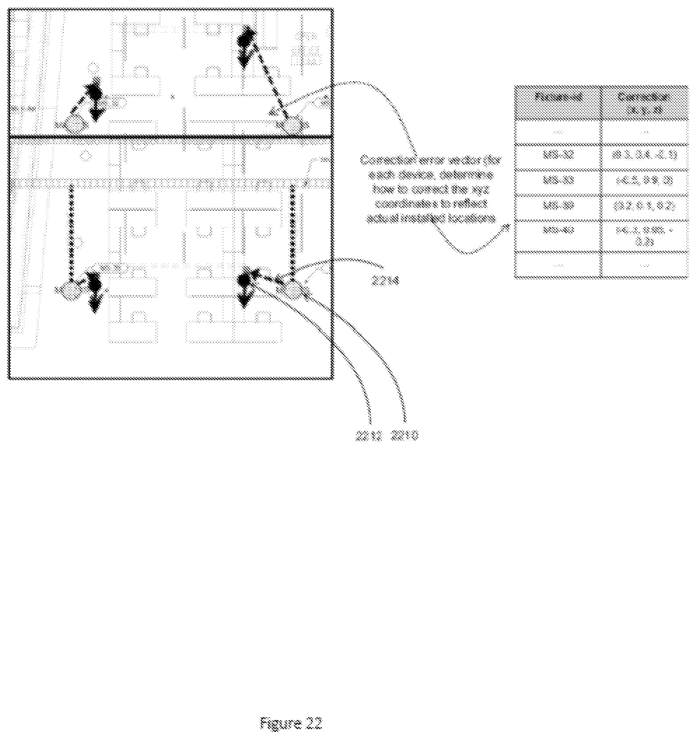

FIG. 22 shows an example of a set of correction error vectors relating requested device locations according to the system plan to device locations based at least in part on visual inspection. A requested device location 2210 for a UWB SGC is shown, along with an installed device location 2212 for the UWB SGC. The installed device location 2212 may be determined based at least in part on visual inspection. A correction error vector 2214 is determined for the UWB SGC. The correction error vector 2214 includes correction factors that are applied to the x, y, and z coordinates of the requested device location 2210 to arrive at the installed device location 2212. For example, to correct the requested device location of a fixture identified as MS-32, a correction error vector of (0.3, 0.4, −0.1) must be applied to the requested device location of fixture MS-32 to arrive at the installed device location of fixture MS-32.

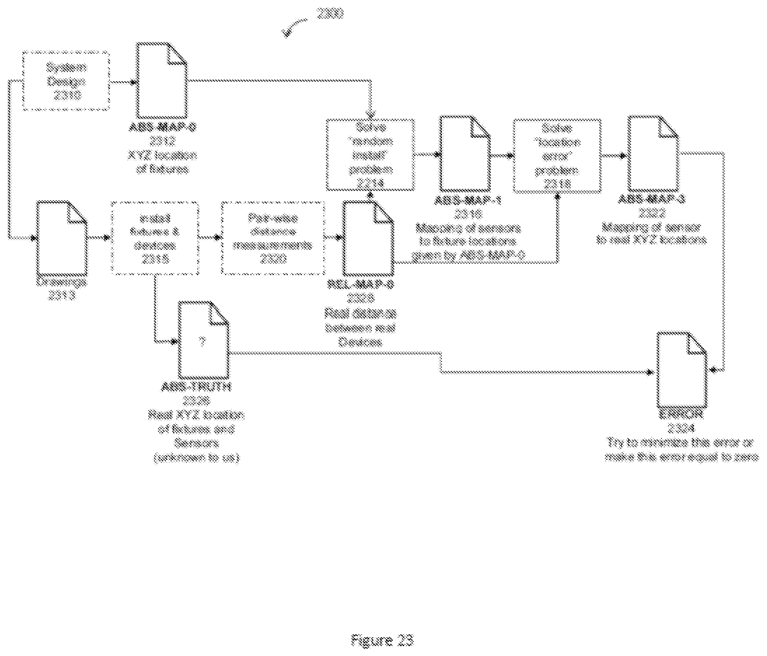

FIG. 23 shows an example of a flowchart showing an illustrative procedure 2300 for mapping a set of requested device locations to a set of actually installed device locations. The procedure commences by receiving a system design 2310. The system design 2310 includes a set of requested fixture locations for an enclosure and/or a facility. An ABS-MAP-0) 2312 file is generated from the system design 2310. The ABS-MAP-0) 2312 file includes coordinate (x, y, z) locations for the fixtures in the system design 2310. The ABS-MAP-0) 2312 file is fed to a solve ‘random install’ problem procedure 2314. The solve ‘random install’ problem procedure 2314 uses the ABS-MAP-0) 2312 file to generate an ABS-MAP-1 2316 file setting forth a mapping of sensors to the fixture locations given by the ABS-MAP-0) 2312 file. The ABS-MAP-1 2316 file is used by a solve ‘location error’ problem procedure 2318 to generate an ABS-MAP-3 2322 file. The ABS-MAP-3 2322 file includes a mapping of sensors to real x, y, z locations.

A set of drawings 2313 is extracted from the system design 2310. The set of drawings 2313 is used to install fixtures and devices at block 2315. A set of pairwise distance measurements 2320 is prepared and used to produce a REL-MAP-0) 2328 file. The REL-MAP-0 2328 file includes real distances between actually installed devices. The REL-MAP-0 2328 file is used by the solve ‘random install’ problem procedure 2314 to generate the ABS-MAP-1 2316 file. The REL-MAP-0 2328 file is also used by the solve ‘location error’ problem procedure 2318 to generate the ABS-MAP-3 2322 file.

An ABS-TRUTH 2326 file is prepared using the installed fixtures and devices 2315. The ABS-TRUTH 2326 file includes real x, y, z locations of fixtures and sensors (that may be unknown to us). The ABS-TRUTH 2326 file and the ABS-MAP-3 2322 file are used to minimize an Error 2324, and/or to make the Error 2324 equal to zero. In some embodiments, the solve ‘random install’ problem procedure 2314 and/or the solve ‘location error’ problem procedure 2318 may be performed using a first logic scheme module, e.g., any of the Greedy procedures of FIGS. 12 and 13, and/or any of a second logic scheme module, e.g., the Branch and Bound procedures of FIGS. 15 and 16.

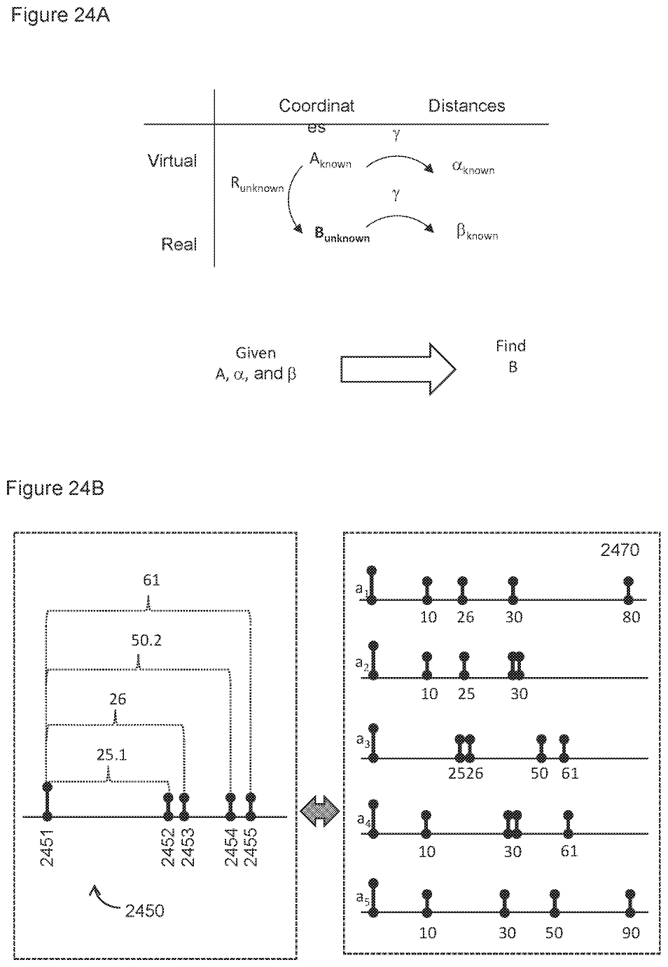

FIG. 24A shows an example of mathematical operations that utilize known distances between devices to determine unknown coordinates (e.g., locations) of devices. For example, when the requested distances between the virtual devices are known (represented as matrix α), the requested distances between the real devices are known (represented as matrix β), and the coordinates between the requested virtual devices are known (e.g., from the BIM file), the coordinates of the real devices can be determined, e.g., by finding a suitable permutation operation R. The relation between the coordinates and the distance is represented by operation y.

FIG. 24B shows an example of device located in real 2450 positions 2451, 2452, 2453, 2454, and 2455. The real distance between the devices are enumerated as: (i) distance between 2451 and 2452=25.1 units, (ii) distance between 2451 and 2453=26.0 units, (iii) distance between 2451 and 2454=50.2 units, and (iv) distance between 2451 and 2455=61.0 units. A possible solution space is represented as a set 2470 of solutions a1, a2, a3, a4, and a5, each representing a possible arrangement of the devices. The best match between the real devices and the solution space is shown in a3.

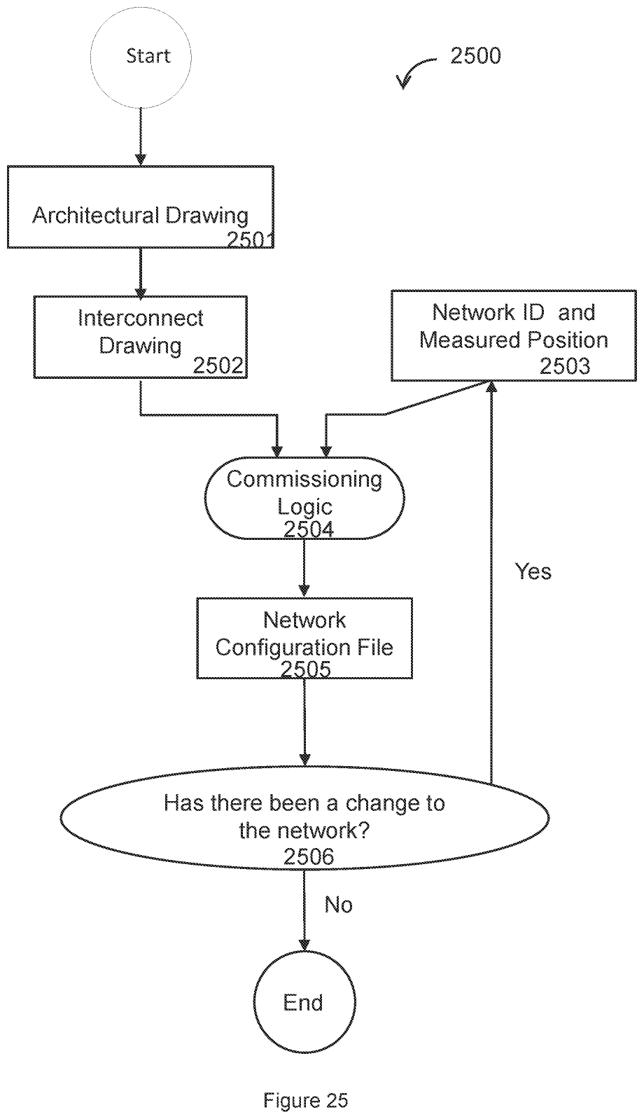

FIG. 25 shows an example of a process 2500 involving logic scheme 2504 (part of a commissioning system) and a network configuration file 2505. Process 2500 begins by gathering building information from architectural drawings 2501. Using the building information provided by architectural drawings, a designer or design team creates interconnect drawings 2502 which include plans for a network at a particular site. Once network components such as IGUs and controllers are installed, the relative positions between devices can be measured by analysis of electromagnetic transmissions as has been described herein. The measured positions and network ID information 2503 is then passed to logic scheme 2504 which pairs the network ID (or other unique information) of a component (e.g., device) with its place within a (e.g., hierarchal) network as depicted in the interconnect drawings 2502. The location of an associated device, as taken or derived from the interconnect drawing, is paired with the network ID or other unique information. The paired information is stored in a network configuration file 2505. As long as no changes are made to the network or device installations, no changes are needed to the network configuration file. If, however, a change is made, for example an IGU is replaced with one having a different window controller, then logic scheme 2504 is used to determine the change and update the network configuration file 2505 accordingly.

As a teaching example, consider an interconnect drawing having window controllers located at three positions (each associated with the lower left corner of an associated window) along the wall of the building: a first position intended to have a first window controller at (0) ft, 0 ft, 0 ft), a second position intended to have a second window controller at (5 ft, 0 ft, 0 ft), and a third position intended to have a third window controller at (5 ft, 4 ft, 0 ft). The measurement metric of “feet” is abbreviated as “ft”. When measuring coordinates of the three controllers, one of the controllers may be set as a reference location (e.g., the controller personnel responsible for commissioning sets the controller in the first position as a reference point). From this reference point the coordinates of the other two windows are measured resulting in window coordinates of (5.1 ft, 0.2 ft., 1 ft) and (5.0 ft, 3.9 ft, −0.1 ft). The logic scheme (e.g., commissioning logic) then perceives the window having coordinates (5.1 ft, 0.2 ft. 0.1 ft) to be in the second position and a window having coordinates (5.0 ft, 3.9 ft, −. 1 ft) to be in the third position. Information describing the physical and hierarchical position of each component from interconnect drawings may then be paired with the network ID information (or other unique information) which may be transmitted to the logic scheme over the network when the position of network components is determined.

In some embodiments, the logic scheme includes one or more logic modules, each comprising a mathematical methodology (e.g., method). For example, the logic scheme may incorporate a range of statistical methods to match physical device coordinates with coordinates listed on an interconnect drawing. In one embodiment, matching is performed by iterating through the various permutations of assigning a device to each of the possible interconnect locations and then observing how closely the location of other components, as determined using relative distance measurements, correspond to the locations of other network component locations as specified on the interconnect drawing. In some embodiments, network components are matched with coordinates listed on an interconnect drawing by selecting the permutation that minimizes the mean squared error of the distance of one or more components (e.g., each component) to the respective closest component location specified by the interconnect drawing.

This automatic (e.g., auto commissioning) method may be useful if, for example, when a new component (e.g., device) is added to the network, an old component is removed from a network, or an old component is replaced by a new component on the network. In the case of a new component, the component may be recognized by the network and its location may be determined by one of the previously described methods. The logic scheme may then update the network configuration file to reflect the new component. The logic scheme may update a network configuration file when a component is removed and/or otherwise no longer recognized by the network. In cases where a component is replaced, the logic scheme may notice an absence of a component on the network and the presence of a new component reporting from the same, or substantially the same, coordinates of the missing component. The logic scheme may conclude that a component has been replaced, and thus updates the network configuration file with the network ID of the new component.

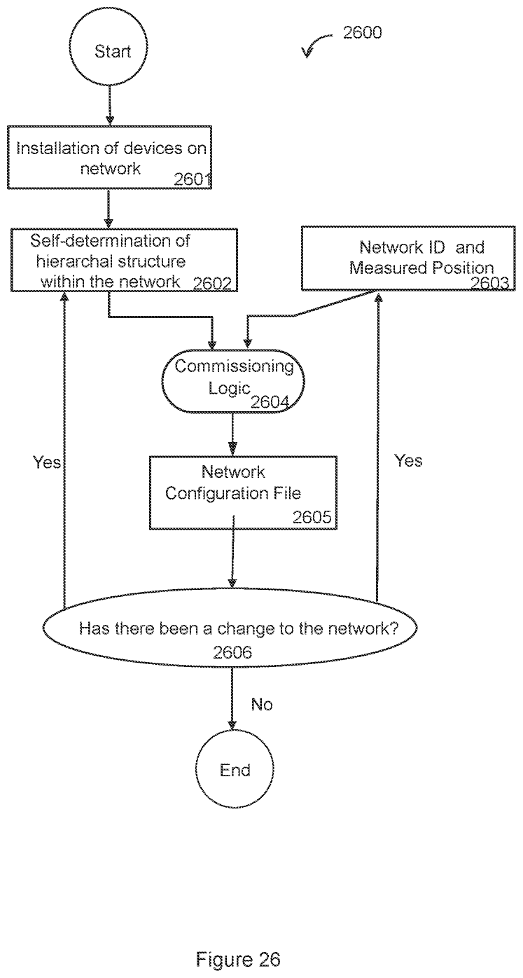

FIG. 26 shows a process 2600 in which the logic scheme generates the network topology portion of a network configuration file. Window devices (or other network-connected devices) are installed at a site 2601 and network components self-determine the (e.g., hierarchical) structure of the network at least in part by communicating with each other 2602. The hieratical structure of a network may be determined when each component self-reports to the network component above it reporting its network ID (or other ID) information as well the network ID (or other ID) information of any devices below it in the hierarchy. For example, a device (e.g., a sensor or an IGU) may report to a local controller (e.g., WC), which may report to an NC, which may report to a MC. When this pattern is repeated for every component on the network, then the system hierarchy may be self-determined. Thus, a network may avoid network topology errors that may easily be introduced by deviations from an interconnect drawing that occur during installation. This self-determined structure is then passed to logic scheme 2604 which may use the measured positions 2603 of devices when creating a network configuration file 2605.

The instructions and logic for performing commissioning procedures described herein may be deployed on any suitable processing apparatus including any controller on the network with sufficient memory and processing capability. Examples include master controllers, network controllers, and local controllers. In other embodiments, the logic scheme (e.g., of a commissioning system) executes on a dedicated administrative processing machine. The dedicated administrative processing machine may perform (e.g., only) commissioning or related administrative functions, and/or may communicate with the associated network. In some embodiments, the logic scheme resides outside the facility having the devices to be deployed, commissioned, or otherwise connected to the network. For example, the logic scheme may reside in a network of a remote monitoring site, console, or any ancillary system such as a building lighting system, a BMS, a building thermostat system (e.g., NEST (Nest Labs of Palo Alto, California), or the like. Examples of such systems, methods of their use, and related software are described in International Patent Application Serial No. PCT/US15/64555, filed Dec. 8, 2015, titled “MULTIPLE INTERACTING SYSTEMS AT A SITE” and International Patent Application Serial No. PCT/US15/19031, filed Mar. 5, 2015, titled “MONITORING SITES CONTAINING SWITCHABLE OPTICAL DEVICES AND CONTROLLERS,” each of which incorporated herein by reference in its entirety. In some embodiments, the commissioning system executes in a shared computational resource such as a leased server farm or the cloud.

In some embodiments, the network of the facility is operatively coupled to a “digital twin” of a facility. In some embodiments, a control system and/or control interface comprises, or is operatively coupled to, the “digital twin” of a facility. For example, the digital twin may comprise a representative model (e.g., a two-dimensional or three-dimensional virtual depiction) containing structural elements (e.g., walls and doors), building fixtures, non-fixtures (e.g., furnishings), and/or one or more interactive target devices (e.g., optically switchable windows, sensors, emitters, and/or media displays). The digital twin may reside on a server which is accessible via a graphical user interface or which can be accessed using a virtual reality (VR) user interface. The VR interface may include an augmented reality (AR) aspect. The digital twin may be utilized in connection with monitoring and servicing of the building infrastructure and/or in connection with controlling any interactive target devices, for example. When a new device is installed in the facility (e.g., in a room thereof) and is operatively coupled to the network, the new device may be detected (e.g., and included into the digital twin). The detection of the new device and/or inclusion of the new device into the digital twin may be done automatically and/or manually. For example, the detection of the new device and/or inclusion of the new device into the digital twin may be without requiring (e.g., any) manual intervention. Whether present in the original design plans of the enclosure or added at a later time, full details regarding (e.g., each) device (including any unique identification codes) may be stored in the digital twin, network configuration file, interconnect drawing, and/or architectural drawing (e.g., BIM file such as a Revit file) to facilitate the monitoring, servicing, and/or control functions.

In some embodiments, a digital twin comprises a digital model of the facility. The digital twin may be comprised of a virtual three dimensional (3D) model of the facility. The facility may include static and/or dynamic elements. For example, the static elements may include representations of a structural feature of the facility (e.g., fixtures) and the dynamic elements may include representations of an interactive device with a controllable feature. The 3D model may include visual elements. The visual elements may represent facility fixture(s). The fixture may comprise a wall, a floor, wall, door, shelf, a structural (e.g., walk-in) closet, a fixed lamp, electrical panel, elevator shaft, or a window. The fixtures may be affixed to the structure. The visual elements may represent non-fixture(s). The non-fixtures may comprise a person, a chair, a movable lamp, a table, a sofa, a movable closet or a media projection. The non-fixtures may comprise mobile elements. The visual elements may represent facility features comprising a floor, wall, door, window, furniture, appliance, people, and/or interactive device(s)). The digital twin may be similar to virtual worlds used in computer gaming and simulations, representing the environment of the real facility. Creation of a 3D model may include the analysis of a Building Information Modeling (BIM) model (e.g., an Autodesk Revit file), e.g., to derive a representation of (e.g., basic) fixed structures and movable items such as doors, windows, and elevators. In some embodiments, the digital twin (e.g., 3D model of the facility) is defined at least in part by using one or more sensors (e.g., optical, acoustic, pressure, gas velocity, and/or distance measuring sensor(s)), to determine the layout of the real facility. Usage of sensor data can be used (e.g., exclusively) to model the environment of the enclosure. Usage of sensor data can be used in conjunction with a 3D model of the facility (e.g., (BIM model) to model and/or control the environment of the enclosure. The BIM model of the facility may be obtained before, during (e.g., in real time), and/or after the facility has been constructed. The BIM model of the facility can be updated (e.g., manually and/or using the sensor data) during operation and/or commissioning of the facility (e.g., in real time).

In some embodiments, dynamic elements in the digital twin include device settings. The device setting may comprise (e.g., existing and/or predetermined): tint values, temperature settings, and/or light switch settings. The device settings may comprise available actions in media displays. The available actions may comprise menu items or hotspots in displayed content. The digital twin may include virtual representation of the device and/or of movable objects (e.g., chairs or doors), and/or occupants (actual images from a camera or from stored avatars). In some embodiments, the dynamic elements can be devices that are newly plugged into the network, and/or disappear from the network (e.g., due to a malfunction or relocation). The digital twin can reside in any circuitry (e.g., processor) operatively coupled to the network. The circuitry in which the digital circuitry resides may be in the facility, outside of the facility, and/or in the cloud. In some embodiments, a two-way (e.g., bidirectional) link is maintained between the digital twin and a real circuitry. The real circuitry may be part of the control system. The real circuitry may be included in the master controller, network controller, floor controller, local controller, or in any other node in a processing system (e.g., in the facility or outside of the facility). For example, the two-way link can be used by the real circuitry to inform the digital twin of changes in the dynamic and/or static elements so that the 3D representation of the enclosure can be updated, e.g., in real time or at a later (e.g., designated) time. The two-way link may be used by the digital twin to inform the real circuitry of manipulative (e.g., control) actions entered by a user on a mobile circuitry. The mobile circuitry can be a remote controller (e.g., comprising a handheld pointer, manual input buttons, or touchscreen).

The methods, systems and/or the apparatus described herein may comprise a control system. The control system can be in communication with any of the apparatuses (e.g., sensors) described herein. The sensors may be of the same type or of different types, e.g., as described herein. For example, the control system may be in communication with the first sensor and/or with the second sensor. The control system may control the one or more sensors. The control system may control one or more components of a building management system (e.g., lightening, security, and/or air conditioning system). The controller may regulate at least one (e.g., environmental) characteristic of the enclosure. The control system may regulate the enclosure environment using any component of the building management system. For example, the control system may regulate the energy supplied by a heating element and/or by a cooling element. For example, the control system may regulate velocity of an air flowing through a vent to and/or from the enclosure. The control system may comprise a processor. The processor may be a processing unit. The controller may comprise a processing unit. The processing unit may be central. The processing unit may comprise a central processing unit (abbreviated herein as “CPU”). The processing unit may be a graphic processing unit (abbreviated herein as “GPU”). The controller(s) or control mechanisms (e.g., comprising a computer system) may be programmed to implement one or more methods of the disclosure. The processor may be programmed to implement methods of the disclosure. The controller may control at least one component of the forming systems and/or apparatuses disclosed herein.

The controller may monitor and/or direct (e.g., physical) alteration of the operating conditions of the apparatuses, software, and/or methods described herein. Control may comprise regulate, manipulate, restrict, direct, monitor, adjust, modulate, vary, alter, restrain, check, guide, or manage. Controlled (e.g., by a controller) may include attenuated, modulated, varied, managed, curbed, disciplined, regulated, restrained, supervised, manipulated, and/or guided. The control may comprise controlling a control variable (e.g., temperature, power, voltage, and/or profile). The control can comprise real time or off-line control. A calculation utilized by the controller can be done in real time, and/or off

In some embodiments, a plurality of devices may be operatively (e.g., communicatively) coupled to the control system. The plurality of devices may be disposed in a facility (e.g., including a building and/or room). The control system may comprise the hierarchy of controllers. The devices may comprise an emitter, a sensor, or a window (e.g., IGU). The device may be any device as disclosed herein. At least two of the plurality of devices may be of the same type. For example, two or more IGUs may be coupled to the control system. At least two of the plurality of devices may be of different types. For example, a sensor and an emitter may be coupled to the control system. At times, the plurality of devices may comprise at least 20, 50, 100, 500, 1000, 2500, 5000, 7500, 10000, 50000, 100000, or 500000 devices. The plurality of devices may be of any number between the aforementioned numbers (e.g., from 20 devices to 500000 devices, from 20 devices to 50 devices, from 50 devices to 500 devices, from 500 devices to 2500 devices, from 1000 devices to 5000 devices, from 5000 devices to 10000 devices, from 10000 devices to 100000 devices, or from 100000 devices to 500000 devices). For example, the number of windows in a floor may be at least 5, 10, 15, 20, 25, 30, 40, or 50. The number of windows in a floor can be any number between the aforementioned numbers (e.g., from 5 to 50, from 5 to 25, or from 25 to 50). At times the devices may be in a multi-story building. At least a portion of the floors of the multi-story building may have devices controlled by the control system (e.g., at least a portion of the floors of the multi-story building may be controlled by the control system). For example, the multi-story building may have at least 2, 8, 10, 25, 50, 80, 100, 120, 140, or 160 floors that are controlled by the control system. The number of floors (e.g., devices therein) controlled by the control system may be any number between the aforementioned numbers (e.g., from 2 to 50, from 25 to 100, or from 80 to 160). The floor may be of an area of at least about 150 m2, 250 m2, 500 m2, 1000 m2, 1500 m2, or 2000 square meters (m2). The floor may have an area between any of the aforementioned floor area values (e.g., from about 150 m2 to about 2000 m2, from about 150 m2 to about 500 m2, from about 250 m2 to about 1000 m2, or from about 1000 m2 to about 2000 m2). The building may comprise an area of at least about 1000 square feet (sqft), 2000 sqft, 5000 sqft, 10000 sqft, 100000 sqft, 150000 sqft, 200000 sqft, or 500000 sqft. The building may comprise an area between any of the above mentioned areas (e.g., from about 1000 sqft to about 5000 sqft, from about 5000 sqft to about 500000 sqft, or from about 1000 sqft to about 500000 sqft). The building may comprise an area of at least about 100 m2, 200 m2, 500 m2, 1000 m2, 5000 m2, 10000 m2, 25000 m2, or 50000 m2. The building may comprise an area between any of the above mentioned areas (e.g., from about 100 m2 to about 1000 m2, from about 500 m2 to about 25000 m2, from about 100 m2 to about 50000 m2). The facility may comprise a commercial or a residential building. The commercial building may include tenant(s) and/or owner(s). The residential facility may comprise a multi or a single family building. The residential facility may comprise an apartment complex. The residential facility may comprise a single family home. The residential facility may comprise multifamily homes (e.g., apartments). The residential facility may comprise townhouses. The facility may comprise residential and commercial portions. The facility may comprise at least about 1, 2, 5, 10, 50, 100, 150, 200, 250, 300, 350, 400, 420, 450, 500, or 550 windows (e.g., tintable windows). The windows may be divided into zones (e.g., based at least in part on the location, façade, floor, ownership, utilization of the enclosure (e.g., room) in which they are disposed, any other assignment metric, random assignment, or any combination thereof. Allocation of windows to the zone may be static or dynamic (e.g., based on a heuristic). There may be at least about 2, 5, 10, 12, 15, 30, 40, or 46 windows per zone.

In some embodiments, the sensor(s) are operatively coupled to at least one controller and/or processor. Sensor readings may be obtained by one or more processors and/or controllers. A controller may comprise a processing unit (e.g., CPU or GPU). A controller may receive an input (e.g., from at least one sensor). The controller may include circuitry, electrical wiring, optical wiring, socket, and/or outlet. A controller may deliver an output. A controller may comprise multiple (e.g., sub-) controllers. The controller may be a part of a control system. A control system may comprise a master controller, floor (e.g., comprising network controller) controller, or a local controller. The local controller may be a window controller (e.g., controlling an optically switchable window), enclosure controller, or component controller. The controller can be a device controller (e.g., any device disclosed herein). For example, a controller may be a part of a hierarchal control system (e.g., comprising a main controller that directs one or more controllers, e.g., floor controllers, local controllers (e.g., window controllers), enclosure controllers, and/or component controllers). A physical location of the controller type in the hierarchal control system may be changing. For example, at a first time: a first processor may assume a role of a main controller, a second processor may assume a role of a floor controller, and a third processor may assume the role of a local controller. At a second time: the second processor may assume a role of a main controller, the first processor may assume a role of a floor controller, and the third processor may remain with the role of a local controller. At a third time: the third processor may assume a role of a main controller, the second processor may assume a role of a floor controller, and the first processor may assume the role of a local controller. A controller may control one or more devices (e.g., be directly coupled to the devices). A controller may be disposed proximal to the one or more devices it is controlling. For example, a controller may control an optically switchable device (e.g., IGU), an antenna, a sensor, and/or an output device (e.g., a light source, sounds source, smell source, gas source, HVAC outlet, or heater). In one embodiment, a floor controller may direct one or more window controllers, one or more enclosure controllers, one or more component controllers, or any combination thereof. The floor controller may comprise a floor controller. For example, the floor (e.g., comprising network) controller may control a plurality of local (e.g., comprising window) controllers. A plurality of local controllers may be disposed in a portion of a facility (e.g., in a portion of a building). The portion of the facility may be a floor of a facility. For example, a floor controller may be assigned to a floor. In some embodiments, a floor may comprise a plurality of floor controllers, e.g., depending on the floor size and/or the number of local controllers coupled to the floor controller. For example, a floor controller may be assigned to a portion of a floor. For example, a floor controller may be assigned to a portion of the local controllers disposed in the facility. For example, a floor controller may be assigned to a portion of the floors of a facility. A master controller may be coupled to one or more floor controllers. The floor controller may be disposed in the facility. The master controller may be disposed in the facility, or external to the facility. The master controller may be disposed in the cloud. A controller may be a part of, or be operatively coupled to, a building management system. A controller may receive one or more inputs. A controller may generate one or more outputs. The controller may be a single input single output controller (SISO) or a multiple input multiple output controller (MIMO). A controller may interpret an input signal received. A controller may acquire data from the one or more components (e.g., sensors). Acquire may comprise receive or extract. The data may comprise measurement, estimation, determination, generation, or any combination thereof. A controller may comprise feedback control. A controller may comprise feed-forward control. Control may comprise on-off control, proportional control, proportional-integral (PI) control, or proportional-integral-derivative (PID) control. Control may comprise open loop control, or closed loop control. A controller may comprise closed loop control. A controller may comprise open loop control. A controller may comprise a user interface. A user interface may comprise (or operatively coupled to) a keyboard, keypad, mouse, touch screen, microphone, speech recognition package, camera, imaging system, or any combination thereof. Outputs may include a display (e.g., screen), speaker, or printer. The controller may be a manual or a non-manual controller. The controller may be an automatic controller. The controller may operate upon request. The controller may be a programmable controller. The controller may be programed. The controller may comprise a processing unit (e.g., CPU or GPU). The controller may receive an input (e.g., from at least one sensor). The controller may deliver an output. The controller may comprise multiple (e.g., sub-) controllers. The controller may be a part of a control system. The control system may comprise a master controller, floor controller, local controller (e.g., enclosure controller, or window controller). The controller may receive one or more inputs. The controller may generate one or more outputs. The controller may be a single input single output controller (SISO) or a multiple input multiple output controller (MIMO). The controller may interpret the input signal received. The controller may acquire data from the one or more sensors. Acquire may comprise receive or extract. The data may comprise measurement, estimation, determination, generation, or any combination thereof. The controller may comprise feedback control. The controller may comprise feed-forward control. The control may comprise on-off control, proportional control, proportional-integral (PI) control, or proportional-integral-derivative (PID) control. The control may comprise open loop control, or closed loop control. The controller may comprise closed loop control. The controller may comprise open loop control. The controller may comprise a user interface. The user interface may comprise (or operatively coupled to) a keyboard, keypad, mouse, touch screen, microphone, speech recognition package, camera, imaging system, or any combination thereof. The outputs may include a display (e.g., screen), speaker, or printer.

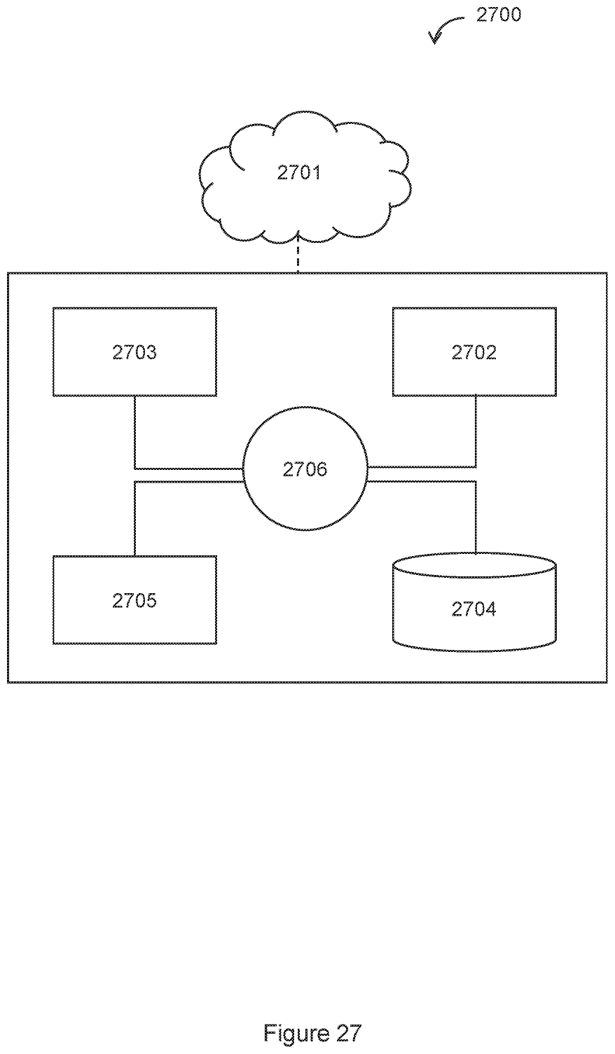

FIG. 27 shows a schematic example of a computer system 2700 that is programmed or otherwise configured to one or more operations of any of the methods provided herein. The computer system can control (e.g., direct, monitor, and/or regulate) various features of the methods, apparatuses and systems of the present disclosure, such as, for example, control heating, cooling, lightening, and/or venting of an enclosure, or any combination thereof. The computer system can be part of, or be in communication with, any sensor or sensor ensemble disclosed herein. The computer may be coupled to one or more mechanisms disclosed herein, and/or any parts thereof. For example, the computer may be coupled to one or more sensors, valves, switches, lights, windows (e.g., IGUs), motors, pumps, optical components, or any combination thereof.

The computer system can include a processing unit (e.g., 2706) (also “processor,” “computer” and “computer processor” used herein). The computer system may include memory or memory location (e.g., 2702) (e.g., random-access memory, read-only memory, flash memory), electronic storage unit (e.g., 2704) (e.g., hard disk), communication interface (e.g., 2703) (e.g., network adapter) for communicating with one or more other systems, and peripheral devices (e.g., 2705), such as cache, other memory, data storage and/or electronic display adapters. In the example shown in FIG. 27, the memory 2702, storage unit 2704, interface 2703, and peripheral devices 2705 are in communication with the processing unit 2706 through a communication bus (solid lines), such as a motherboard. The storage unit can be a data storage unit (or data repository) for storing data. The computer system can be operatively coupled to a computer network (“network”) (e.g., 2701) with the aid of the communication interface. The network can be the Internet, an internet and/or extranet, or an intranet and/or extranet that is in communication with the Internet. In some cases, the network is a telecommunication and/or data network. The network can include one or more computer servers, which can enable distributed computing, such as cloud computing. The network, in some cases with the aid of the computer system, can implement a peer-to-peer network, which may enable devices coupled to the computer system to behave as a client or a server.

The processing unit can execute a sequence of machine-readable instructions, which can be embodied in a program or software. The instructions may be stored in a memory location, such as the memory 2702. The instructions can be directed to the processing unit, which can subsequently program or otherwise configure the processing unit to implement methods of the present disclosure. Examples of operations performed by the processing unit can include fetch, decode, execute, and write back. The processing unit may interpret and/or execute instructions. The processor may include a microprocessor, a data processor, a central processing unit (CPU), a graphical processing unit (GPU), a system-on-chip (SOC), a co-processor, a network processor, an application specific integrated circuit (ASIC), an application specific instruction-set processor (ASIPs), a controller, a programmable logic device (PLD), a chipset, a field programmable gate array (FPGA), or any combination thereof. The processing unit can be part of a circuit, such as an integrated circuit. One or more other components of the system 2700 can be included in the circuit.

The storage unit can store files, such as drivers, libraries and saved programs. The storage unit can store user data (e.g., user preferences and user programs). In some cases, the computer system can include one or more additional data storage units that are external to the computer system, such as located on a remote server that is in communication with the computer system through an intranet or the Internet.

The processing unit (e.g., computer system) can communicate with one or more remote computer systems through a network. For instance, the computer system can communicate with a remote computer system of a user (e.g., operator). Examples of remote computer systems include personal computers (e.g., portable PC), slate or tablet PC's (e.g., Apple R: iPad, Samsung R Galaxy Tab), telephones, Smart phones (e.g., Apple R iPhone, Android-enabled device, Blackberry®), or personal digital assistants. A user can access the computer system via the network. The processing unit may comprise a CPU or a GPU. The processing unit may comprise a media player. The processing unit may be included in a circuit board. The circuit board may comprise a Jetson Nano™ Developer Kit by NVIDIA®, (e.g., 2 GB or 4 GB developer kit) or Raspberry-Pi kit (e.g., 1 GB, 2 GB, 4 GB, or 8 GB developer kit). The processing unit may be operatively coupled to a plurality of ports comprising at least one media port (e.g., a Display Port, HDMI, and/or micro-HDMI), USB, or an audio-video jack, e.g., that may be included in the circuit board. The processing unit may be operatively coupled to a Camera Serial Interface (CSI), or a Display Serial Interface (DSI), e.g., as part of the circuit board. The processing unit is configured to support communication such as ethernet (e.g., Gigabit Ethernet). The circuitry board may comprise a Wi-Fi functionality, a Bluetooth functionality, or a wireless adapter. The wireless adapter may be configured to comply with a wireless networking standard in the 802.11 set of protocols (e.g., USB 802.11ac). The wireless adapter may be configured to provide a high-throughput wireless local area networks (WLANs), e.g., on at least about a 5 GHz band. The USB port may have a transfer speed of at least about 480 megabits per second (Mbps), 4,800 Mbps, or 10,000 Mbps. The at least one processor may comprise a synchronous (e.g., clocked) processor. The clock speed of the processor may be of at least about 1.2 GigaHertz (GHz), 1.3 GHZ, 1.4 GHz, 1.5 GHZ, or 1.6 GHZ. The processing unit may comprise a random access memory (RAM). The RAM may comprise a double data rate synchronous dynamic RAM (SDRAM). The RAM may be configured for mobile devices (e.g., laptop, pad, or mobile phone such as cellular phone). The RAM may comprise a Low-Power Double Data Rate (LPDDR) RAM. The RAM may be configured to permit a channel that is at least about 16, 32, or 64 bit wide.

Methods as described herein can be implemented by way of machine (e.g., computer processor) executable code stored on an electronic storage location of the computer system, such as, for example, on the memory 2702 or electronic storage unit 2704. The machine executable or machine-readable code can be provided in the form of software. During use, the processor 2706 can execute the code. In some cases, the code can be retrieved from the storage unit and stored on the memory for ready access by the processor. In some situations, the electronic storage unit can be precluded, and machine-executable instructions are stored on memory.

The code can be pre-compiled and configured for use with a machine have a processer adapted to execute the code or can be compiled during runtime. The code can be supplied in a programming language that can be selected to enable the code to execute in a pre-compiled or as-compiled fashion.

In some embodiments, the processor comprises a code. The code can be program instructions. The program instructions may cause the at least one processor (e.g., computer) to direct a feed forward and/or feedback control loop. In some embodiments, the program instructions cause the at least one processor to direct a closed loop and/or open loop control scheme. The control may be based at least in part on one or more sensor readings (e.g., sensor data). One controller may direct a plurality of operations. At least two operations may be directed by different controllers. In some embodiments, a different controller may direct at least two of operations (a), (b) and (c). In some embodiments, different controllers may direct at least two of operations (a), (b) and (c). In some embodiments, a non-transitory computer-readable medium cause each a different computer to direct at least two of operations (a), (b) and (c). In some embodiments, different non-transitory computer-readable mediums cause each a different computer to direct at least two of operations (a), (b) and (c). The controller and/or computer readable media may direct any of the apparatuses or components thereof disclosed herein. The controller and/or computer readable media may direct any operations of the methods disclosed herein.

In some embodiments, the at least one sensor is operatively coupled to a control system (e.g., computer control system). The sensor may comprise an accelerometer. The sensor may comprise light sensor, acoustic sensor, vibration sensor, chemical sensor, electrical sensor, magnetic sensor, fluidity sensor, movement sensor, speed sensor, position sensor, pressure sensor, force sensor, density sensor, distance sensor, or proximity sensor. The sensor may include temperature sensor, weight sensor, material (e.g., powder) level sensor, metrology sensor, gas sensor, or humidity sensor. The metrology sensor may comprise measurement sensor (e.g., height, length, width, angle, and/or volume). The metrology sensor may comprise a magnetic, acceleration, orientation, or optical sensor. The sensor may transmit and/or receive sound (e.g., echo), magnetic, electronic, or electromagnetic signal. The electromagnetic signal may comprise a visible, infrared, ultraviolet, ultrasound, radio wave, or microwave signal. The gas sensor may sense any of the gas delineated herein. The distance sensor can be a type of metrology sensor. The distance sensor may comprise an optical sensor, or capacitance sensor. The temperature sensor can comprise Bolometer, Bimetallic strip, calorimeter, Exhaust gas temperature gauge, Flame detection, Gardon gauge, Golay cell, Heat flux sensor, Infrared thermometer, Microbolometer, Microwave radiometer, Net radiometer, Quartz thermometer, Resistance temperature detector, Resistance thermometer, Silicon band gap temperature sensor, Special sensor microwave/imager, Temperature gauge, Thermistor, Thermocouple, Thermometer (e.g., resistance thermometer), or Pyrometer. The temperature sensor may comprise an optical sensor. The temperature sensor may comprise image processing. The temperature sensor may comprise a camera (e.g., IR camera, CCD camera). The pressure sensor may comprise Barograph, Barometer, Boost gauge, Bourdon gauge, Hot filament ionization gauge, Ionization gauge, McLeod gauge, Oscillating U-tube, Permanent Downhole Gauge, Piezometer, Pirani gauge, Pressure sensor, Pressure gauge, Tactile sensor, or Time pressure gauge. The position sensor may comprise Auxanometer, Capacitive displacement sensor, Capacitive sensing, Free fall sensor, Gravimeter, Gyroscopic sensor, Impact sensor, Inclinometer, Integrated circuit piezoelectric sensor, Laser rangefinder, Laser surface velocimeter, LIDAR, Linear encoder, Linear variable differential transformer (LVDT), Liquid capacitive inclinometers, Odometer, Photoelectric sensor, Piezoelectric accelerometer, Rate sensor, Rotary encoder, Rotary variable differential transformer, Selsyn, Shock detector, Shock data logger, Tilt sensor, Tachometer, Ultrasonic thickness gauge, Variable reluctance sensor, or Velocity receiver. The optical sensor may comprise a Charge-coupled device, Colorimeter, Contact image sensor, Electro-optical sensor, Infra-red sensor, Kinetic inductance detector, light emitting diode (e.g., light sensor), Light-addressable potentiometric sensor, Nichols radiometer, Fiber optic sensor, Optical position sensor, Photo detector, Photodiode, Photomultiplier tubes, Phototransistor, Photoelectric sensor, Photoionization detector, Photomultiplier, Photo resistor, Photo switch, Phototube, Scintillometer, Shack-Hartmann, Single-photon avalanche diode, Superconducting nanowire single-photon detector, Transition edge sensor, Visible light photon counter, or Wave front sensor. The one or more sensors may be connected to a control system (e.g., to a processor, to a computer).

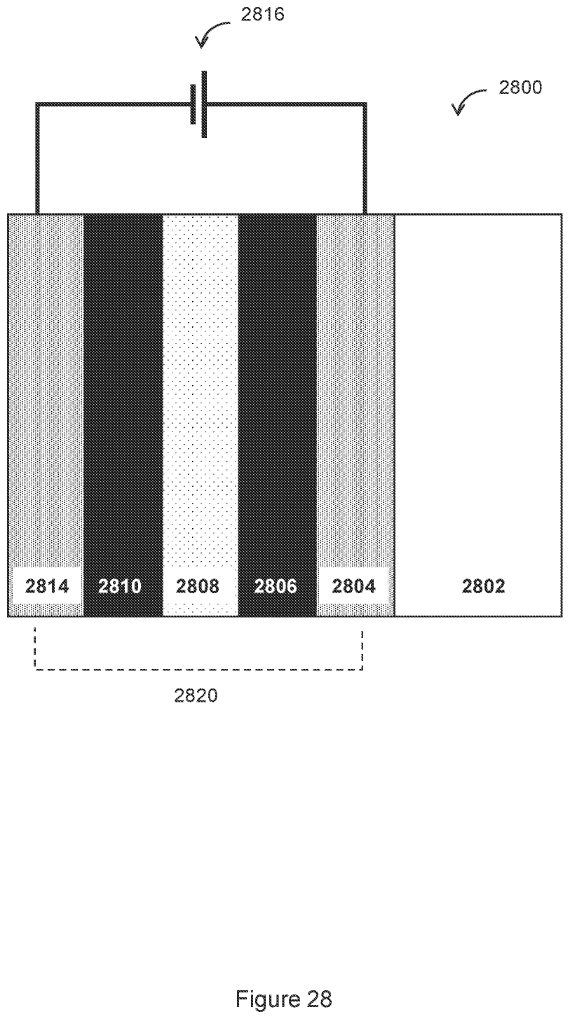

FIG. 28 shows an example of a schematic cross-section of an electrochromic device 2800 in accordance with some embodiments. The EC device coating is attached to a substrate 2802, a transparent conductive layer (TCL) 2804, an electrochromic layer (EC) 2806 (sometimes also referred to as a cathodically coloring layer or a cathodically tinting layer), an ion conducting layer or region (IC) 2808, a counter electrode layer (CE) 2830 (sometimes also referred to as an anodically coloring layer or anodically tinting layer), and a second TCL 2814. Elements 2804, 2806, 2808, 2810, and 2814 are collectively referred to as an electrochromic stack 2820. A voltage source 2816 operable to apply an electric potential across the electrochromic stack 2820 effects the transition of the electrochromic coating from, e.g., a clear state to a tinted state. In other embodiments, the order of layers is reversed with respect to the substrate. That is, the layers are in the following order: substrate, TCL, counter electrode layer, ion conducting layer, electrochromic material layer, TCL.

In various embodiments, the ion conductor region (e.g., 2808) may form from a portion of the EC layer (e.g., 2806) and/or from a portion of the CE layer (e.g., 2810). In such embodiments, the electrochromic stack (e.g., 2820) may be deposited to include cathodically coloring electrochromic material (the EC layer) in direct physical contact with an anodically coloring counter electrode material (the CE layer). The ion conductor region (sometimes referred to as an interfacial region, or as an ion conducting substantially electronically insulating layer or region) may form where the EC layer and the CE layer meet, for example through heating and/or other processing steps. Examples of electrochromic devices fabricated without depositing a distinct ion conductor material can be found in U.S. patent application Ser. No. 13/462,725 filed May 2, 2012, and titled “ELECTROCHROMIC DEVICES,” which is herein incorporated by reference in its entirety. In some embodiments, an EC device coating may include one or more additional layers such as one or more passive layers. Passive layers can be used to improve certain optical properties, to provide moisture, and/or to provide scratch resistance. These and/or other passive layers can serve to hermetically seal the EC stack 2820. Various layers, including transparent conducting layers (such as 2804 and 2814), can be treated with anti-reflective and/or protective layers (e.g., oxide and/or nitride layers).

In certain embodiments, the electrochromic device is configured to (e.g., substantially) reversibly cycle between a clear state and a tinted state. Reversible may be within an expected lifetime of the ECD. The expected lifetime can be at least about 5, 10, 15, 25, 50, 75, or 100 years. The expected lifetime can be any value between the aforementioned values (e.g., from about 5 years to about 100 years, from about 5 years to about 50 years, or from about 50 years to about 100 years). A potential can be applied to the electrochromic stack (e.g., 2820) such that available ions in the stack that can cause the electrochromic material (e.g., 2806) to be in the tinted state reside primarily in the counter electrode (e.g., 2810) when the window is in a first tint state (e.g., clear). When the potential applied to the electrochromic stack is reversed, the ions can be transported across the ion conducting layer (e.g., 2808) to the electrochromic material and cause the material to enter the second tint state (e.g., tinted state).

It should be understood that the reference to a transition between a clear state and tinted state is non-limiting and suggests only one example, among many, of an electrochromic transition that may be implemented. Unless otherwise specified herein, whenever reference is made to a clear-tinted transition, the corresponding device or process encompasses other optical state transitions such as non-reflective-reflective, and/or transparent-opaque. In some embodiments, the terms “clear” and “bleached” refer to an optically neutral state, e.g., untinted, transparent and/or translucent. In some embodiments, the “color” or “tint” of an electrochromic transition is not limited to any wavelength or range of wavelengths. The choice of appropriate electrochromic material and counter electrode materials may govern the relevant optical transition (e.g., from tinted to untinted state).

In certain embodiments, at least a portion (e.g., all of) the materials making up electrochromic stack are inorganic, solid (i.e., in the solid state), or both inorganic and solid. Because various organic materials tend to degrade over time, particularly when exposed to heat and UV light as tinted building windows are, inorganic materials offer an advantage of a reliable electrochromic stack that can function for extended periods of time. In some embodiments, materials in the solid state can offer the advantage of being minimally contaminated and minimizing leakage issues, as materials in the liquid state sometimes do. One or more of the layers in the stack may contain some amount of organic material (e.g., that is measurable). The ECD or any portion thereof (e.g., one or more of the layers) may contain little or no measurable organic matter. The ECD or any portion thereof (e.g., one or more of the layers) may contain one or more liquids that may be present in little amounts. Little may be of at most about 100 ppm, 10 ppm, or Ippm of the ECD. Solid state material may be deposited (or otherwise formed) using one or more processes employing liquid components, such as certain processes employing sol-gels, physical vapor deposition, and/or chemical vapor deposition.

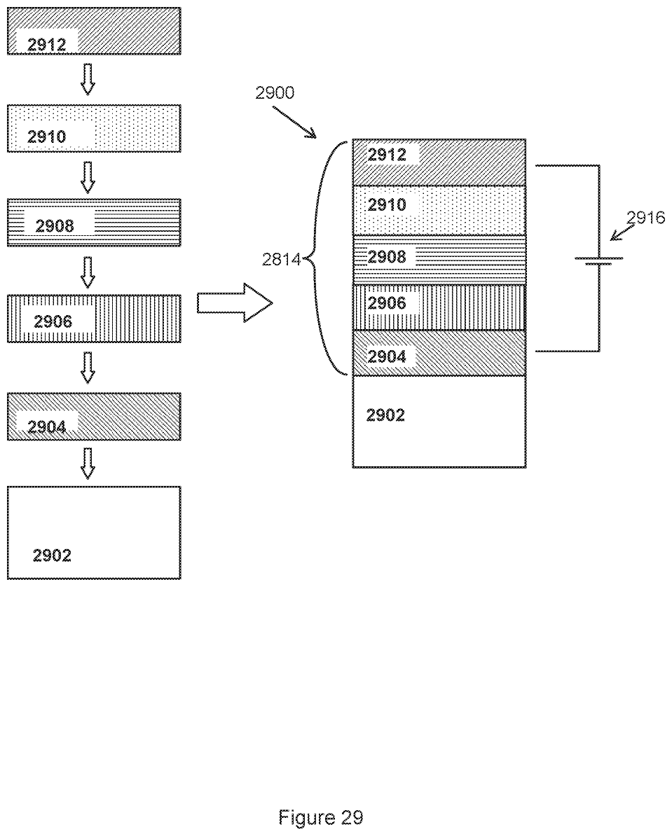

FIG. 29 shows an example of a schematic cross-section of an electrochromic device 2900 in accordance with some embodiments. The EC device coating is attached to a substrate 2902, a transparent conductive layer (TCL) 2904, an electrochromic layer (EC) 2906 (sometimes also referred to as a cathodically coloring layer or a cathodically tinting layer), an ion conducting layer or region (IC) 2908, a counter electrode layer (CE) 2930 (sometimes also referred to as an anodically coloring layer or anodically tinting layer), and a second TCL 2914. Elements 2904, 2906, 2908, 2910, and 2914 are collectively referred to as an electrochromic stack 2920. A voltage source 2916 operable to apply an electric potential across the electrochromic stack 2920 effects the transition of the electrochromic coating from, e.g., a clear state to a tinted state. In other embodiments, the order of layers is reversed with respect to the substrate. That is, the layers are in the following order: substrate, TCL, counter electrode layer, ion conducting layer, electrochromic material layer, TCL.

In various embodiments, the ion conductor region (e.g., 2908) may form from a portion of the EC layer (e.g., 2906) and/or from a portion of the CE layer (e.g., 2910). In such embodiments, the electrochromic stack (e.g., 2920) may be deposited to include cathodically coloring electrochromic material (the EC layer) in direct physical contact with an anodically coloring counter electrode material (the CE layer). The ion conductor region (sometimes referred to as an interfacial region, or as an ion conducting substantially electronically insulating layer or region) may form where the EC layer and the CE layer meet, for example through heating and/or other processing steps. Examples of electrochromic devices fabricated without depositing a distinct ion conductor material can be found in U.S. patent application Ser. No. 13/462,725 filed May 2, 2012, and titled “ELECTROCHROMIC DEVICES,” which is herein incorporated by reference in its entirety. In some embodiments, an EC device coating may include one or more additional layers such as one or more passive layers. Passive layers can be used to improve certain optical properties, to provide moisture, and/or to provide scratch resistance. These and/or other passive layers can serve to hermetically seal the EC stack 2920. Various layers, including transparent conducting layers (such as 2904 and 2914), can be treated with anti-reflective and/or protective layers (e.g., oxide and/or nitride layers).

In certain embodiments, the electrochromic device is configured to (e.g., substantially) reversibly cycle between a clear state and a tinted state. Reversible may be within an expected lifetime of the ECD. The expected lifetime can be at least about 5, 10, 15, 25, 50, 75, or 100 years. The expected lifetime can be any value between the aforementioned values (e.g., from about 5 years to about 100 years, from about 5 years to about 50 years, or from about 50 years to about 100 years). A potential can be applied to the electrochromic stack (e.g., 2920)) such that available ions in the stack that can cause the electrochromic material (e.g., 2906) to be in the tinted state reside primarily in the counter electrode (e.g., 2910) when the window is in a first tint state (e.g., clear). When the potential applied to the electrochromic stack is reversed, the ions can be transported across the ion conducting layer (e.g., 2908) to the electrochromic material and cause the material to enter the second tint state (e.g., tinted state).

It should be understood that the reference to a transition between a clear state and tinted state is non-limiting and suggests only one example, among many, of an electrochromic transition that may be implemented. Unless otherwise specified herein, whenever reference is made to a clear-tinted transition, the corresponding device or process encompasses other optical state transitions such as non-reflective-reflective, and/or transparent-opaque. In some embodiments, the terms “clear” and “bleached” refer to an optically neutral state, e.g., untinted, transparent and/or translucent. In some embodiments, the “color” or “tint” of an electrochromic transition is not limited to any wavelength or range of wavelengths. The choice of appropriate electrochromic material and counter electrode materials may govern the relevant optical transition (e.g., from tinted to untinted state).

In certain embodiments, at least a portion (e.g., all of) the materials making up electrochromic stack are inorganic, solid (i.e., in the solid state), or both inorganic and solid. Because various organic materials tend to degrade over time, particularly when exposed to heat and UV light as tinted building windows are, inorganic materials offer an advantage of a reliable electrochromic stack that can function for extended periods of time. In some embodiments, materials in the solid state can offer the advantage of being minimally contaminated and minimizing leakage issues, as materials in the liquid state sometimes do. One or more of the layers in the stack may contain some amount of organic material (e.g., that is measurable). The ECD or any portion thereof (e.g., one or more of the layers) may contain little or no measurable organic matter. The ECD or any portion thereof (e.g., one or more of the layers) may contain one or more liquids that may be present in little amounts. Little may be of at most about 100 ppm, 10 ppm, or 1 ppm of the ECD. Solid state material may be deposited (or otherwise formed) using one or more processes employing liquid components, such as certain processes employing sol-gels, physical vapor deposition, and/or chemical vapor deposition.

Examples of embodiments contemplated by the present disclosure are listed below:

Embodiment 1: A method of locating real devices installed in a facility, the method comprising: (a) using a virtual model of the facility, the virtual model comprising virtual devices disposed in virtual locations in the virtual model of the facility, which virtual locations correspond to planned locations of the real devices in the facility, which virtual devices represent the real devices: (b) identifying real distances between the real devices installed in the facility: (c) applying the real distances identified to the virtual locations using a heuristic; and (d) matching between the virtual locations and a guess of the real locations of the devices at least in part by using the heuristic.

Embodiment 2: The method of embodiment 1, wherein the facility comprises one or more buildings.

Embodiment 3: The method of embodiment 1 or embodiment 2, wherein the facility comprises one or more enclosures.

Embodiment 4: The method of any of embodiments 1-3, further comprising using the matching to identify the real locations of the real devices.

Embodiment 5: The method of embodiment 4, further comprising comparing the real device pair distances to identify at least one characteristic real distance among the real device pair distances.

Embodiment 6: The method of embodiment 5, wherein the at least one characteristic real distance comprises a longest distance or a shortest distance among the real device pair distances.

Embodiment 7: The method of embodiment 5 or embodiment 6, wherein the at least one characteristic real distance is a distance that occurs at least two times in the real device pair distances.

Embodiment 8: The method of any of embodiments 1-7, further comprising using virtual device pair distances to identify a characteristic virtual distance, and using the virtual distances between each of pairs of the virtual devices to compute a real location.

Embodiment 9: The method of embodiment 8, further comprising utilizing the characteristic virtual distance to match a real distance with a virtual distance.

Embodiment 10: The method of embodiment 8 or embodiment 9, further comprising utilizing the characteristic virtual distance to identify a match between (i) two real devices located at a distance that is precisely or substantially equal to the characteristic virtual distance, and (ii) two virtual devices located at a distance of the characteristic virtual distance.

Embodiment 11: The method of any of embodiments 1-10, wherein aspects (a), (c) and (d) of the method are performed automatically.

Embodiment 12: The method of embodiment 11, wherein aspect (b) of the method is performed automatically.

Embodiment 13: The method of any of embodiments 1-12, wherein the planned location includes at least one identifiable distance between the virtual devices.

Embodiment 14: The method of any of embodiments 1-13, wherein the planned locations of the real devices in the virtual model are asymmetric.

Embodiment 15: The method of embodiment 14, wherein the planned locations of the real devices in the virtual model are comprise a portion of the virtual model in which the virtual devices are symmetrically located with respect to each other.

Embodiment 16: The method of any of embodiments 1-10, further comprising using the real distances identified between each of pairs of the real devices to calculate real locations of pairs of the real devices.

Embodiment 17: The method of embodiment 16, further comprising comparing among the real device pair distances to identify a characteristic real distance.

Embodiment 18: The method of embodiment 17, wherein the characteristic real distance is a longest or a shortest distance among the real device pair distances.

Embodiment 19: The method of embodiment 17, wherein the characteristic real distance is a distance that occurs at least two times in the real device pair distances.

Embodiment 20: The method of embodiment 17, further comprising using the virtual distances between each of pairs of the virtual devices to compute virtual locations of each of pairs of the virtual devices.

Embodiment 21: The method of embodiment 20, further comprising using the virtual device pair distances to identify a characteristic virtual distance.

Embodiment 22: The method of embodiment 21, further comprising using the characteristic virtual distance to match a real distance of the real device pair distances with a virtual distance of the virtual device pair distances.

Embodiment 23: The method of embodiment 21, further comprising using the characteristic virtual distance to identify a match between (i) two real devices installed in the facility and (ii) two virtual devices of the virtual model of the facility.

Embodiment 24: The method of embodiment 23, wherein the two real devices are located at a distance that is substantially equal to the characteristic virtual distance.

Embodiment 25: The method of embodiment 24, wherein the method is performed automatically the two virtual devices are located at a distance that is substantially equal to the characteristic virtual distance.

Embodiment 26: The method of any of embodiments 1-25, wherein one or more distances between planned locations include at least one identifiable distance between the virtual devices.

Embodiment 27: The method of embodiment 26, wherein the one or more distances are asymmetric.

Embodiment 28: The method of embodiment 27, wherein the one or more distances comprise a portion of the virtual model in which the virtual devices are symmetrically located with respect to each other.

Embodiment 29: The method of any of embodiments 1-28, wherein the heuristic comprises a computational scheme that utilizes matrices.

Embodiment 30: The method of embodiment 29, wherein the matrices are digital matrices.

Embodiment 31: The method of any of embodiments 1-30, wherein the heuristic comprises a computational scheme that includes a combinatorial solution, a discrete solution, recursive computation, mathematical induction, and/or mathematical optimization.

Embodiment 32: The method of any of embodiments 1-31, wherein the heuristic comprises a computational scheme including (i) a decision tree, (ii) finding a best solution, (iii) finding an optimal solution, and/or (iv) finding a discrete solution.

Embodiment 33: The method of any of embodiments 1-32, wherein the heuristic comprises using a computational scheme that includes computing sub-solutions for providing a solution for matching between the virtual distances and the real distances of the devices by (i) utilizing computational stages each computing the sub-solutions to determine the solution, and (ii) making an optimal choice in each of the computational stages to compute the respective sub-solutions of the solution.

Embodiment 34: The method of embodiment 33, wherein the computational scheme includes a candidate set from which the solution is created.

Embodiment 35: The method of embodiment 34, wherein the candidate set identifies real distances for the real devices installed in the facility.

Embodiment 36: The method of embodiment 35, wherein the candidate set comprises Building Information Modeling data.

Embodiment 37: The method of any of embodiments 34-36, wherein the computational scheme includes a selection function for choosing the optimal choice for each of the sub-solutions that are to be added to the solution.

Embodiment 38: The method of embodiment 37, wherein the computational scheme further comprises a feasibility function for determining when a candidate of the candidate set can be used to contribute to the solution.

Embodiment 39: The method of embodiment 38, wherein the computational scheme further comprises an objective function for assigning a value to each of the sub-solutions.

Embodiment 40: The method of embodiment 39, wherein the computational scheme further comprises an objective function for assigning a value to the solution.

Embodiment 41: The method of embodiment 40, wherein the computational scheme further comprises a solution function for indicating when the solution comprises a complete solution.

Embodiment 42: The method of any of embodiments 33-41, further comprising locating a specific signature corresponding to a virtual device of the virtual devices or a real device of the real devices.

Embodiment 43: The method of embodiment 42, wherein the specific signature comprises the virtual device being situated at a relatively large distance from every other device of the virtual devices and/or of the real devices.

Embodiment 44: The method of embodiment 42, wherein the specific signature comprises the virtual device being centrally located with reference to one or more other virtual devices and/or one or more other real devices.

Embodiment 45: The method of embodiment 42, wherein the specific signature comprises the virtual device being situated asymmetrically with reference to one or more other virtual devices and/or one or more other real devices.

Embodiment 46: The method of embodiment 42, wherein the specific signature comprises the virtual device being situated symmetrically with reference to one or more other virtual devices and/or one or more other real devices.

Embodiment 47: The method of embodiment 42, wherein the specific signature comprises the virtual device being situated in a recognizable pattern with reference to one or more other virtual devices and/or one or more other real devices.

Embodiment 48: The method of embodiment 42, wherein the specific signature comprises the virtual device being situated to form a numerical series with reference to distances of one or more other virtual devices and/or one or more other real devices.

Embodiment 49: The method of embodiment 48, wherein the numerical series comprises a Fibonacci, square, cubed, telescopic, triangular, geometric, twin, or an arithmetic series.

Embodiment 50: The method of embodiment 33, further comprising using the identified real distances between each of pairs of the real devices to compute the real locations, and using the virtual distances between each of pairs of the virtual devices to compute the virtual locations.

Embodiment 51: The method of embodiment 50, wherein the computational scheme determines a mathematical distance between all rows of a first matrix of distances representing the virtual device pair distances, and all rows of a second matrix of distances representing the real device pair distances.

Embodiment 52: The method of embodiment 51, further comprising finding a first row in the first matrix that is closest to a first row in the second matrix, and mapping the first row in the first matrix to the first row in the second matrix.

Embodiment 53: The method of embodiment 52, further comprising finding a second row in the first matrix that is closest to a second row in the second matrix, and mapping the second row in the first matrix to the second row in the second matrix.

Embodiment 54: The method of any of embodiments 1-53, wherein the heuristic comprises a computational scheme for providing a solution for matching between the virtual distances and the real distances of the devices by performing a systematic enumeration of a set of candidate solutions for the solution.

Embodiment 55: The method of embodiment 54, further comprising representing the set of candidate solutions using a decision tree structure having a plurality of branches comprising a solution space.

Embodiment 56: The method of embodiment 55, further comprising checking a branch of the plurality of branches against an upper estimated bound for the solution and a lower estimated bound of the branch.

Embodiment 57: The method of embodiment 56, further comprising discarding a branch of the plurality of branches when the branch cannot include a better solution as compared to a best solution of the solution space found by the computational scheme.

Embodiment 58: The method of embodiment 55, further comprising (i) partitioning the solution space into a plurality of subsets, and (ii) analyzing a subset of the plurality of subsets to locate a target solution.

Embodiment 59: The method of embodiment 58, further comprising eliminating the subset when the target solution does not exist in the subset.

Embodiment 60: The method of embodiment 58, further comprising dividing the subset into at least two smaller subsets when the target solution can potentially exist in the subset.

Embodiment 61: The method of embodiment 58, further comprising using matrices to locate the target solution at least in part by computing a search space and applying at least one recursive computational scheme.

Embodiment 62: The method of embodiment 55, further comprising (i) partitioning the solution space into a plurality of subsets, and (ii) analyzing a subset of the plurality of subsets to locate a target solution.

Embodiment 63: The method of embodiment 62, further comprising eliminating the subset when the target solution does not exist in the subset.

Embodiment 64: The method of embodiment 62, further comprising dividing the subset into at least two smaller subsets when the target solution may potentially exist in the subset.

Embodiment 65: The method of embodiment 62, further comprising using binary matrices to represent subsets in the search space and applying at least one recursive computational scheme.

Embodiment 66: The method of embodiment 55, further comprising formulating an initial guess for a solution.

Embodiment 67: The method of embodiment 66, wherein the initial guess is a random guess or a logical guess.

Embodiment 68: The method of embodiment 66, further comprising partitioning a solution space into a plurality of subsets, and discarding all subsets that have a less accurate approximation for the solution than the initial guess.

Embodiment 69: The method of embodiment 58, further comprising using target virtual devices that are spaced apart by at least a minimum distance threshold.

Embodiment 70: The method of embodiment 69, wherein the minimum distance threshold is at least nine (9) centimeters.

Embodiment 71: The method of embodiment 62, further comprising using target real devices that are spaced apart by at least a minimum distance threshold.

Embodiment 72: The method of embodiment 71, wherein the minimum distance threshold is at least nine (9) centimeters.

Embodiment 73: The method of any of embodiments 1-72, wherein the heuristic comprises a combination of computational schemes, the combination providing a solution for matching between the virtual distances and the real distances of the devices by making a local best choice for each of a plurality of sub-solutions of the solution, and performing a systematic enumeration of a set of candidate solutions for the solution.

Embodiment 74: The method of embodiment 73, wherein the computational schemes include a first computational scheme that includes (i) utilizing computational stages each computing the sub-solutions to determine the solution, and (ii) making an optimal choice in each of the computational stages to compute the respective sub-solutions of the solution, and a second computational scheme that includes performing a systematic enumeration of a set of candidate solutions for the solution.

Embodiment 75: The method of embodiment 74, wherein the second computational scheme follows the first computational scheme.

Embodiment 76: The method of embodiment 73, further comprising updating the real distances for the real devices one at a time.

Embodiment 77: The method of embodiment 73, further comprising imposing one or more asymmetric constraints on the virtual locations and/or the real locations.

Embodiment 78: The method of embodiment 77, wherein the one or more asymmetric constraints comprise the virtual locations and/or the real locations being in or on a ceiling of the facility.

Embodiment 79: The method of embodiment 77, wherein the one or more asymmetric constraints comprise the virtual locations and/or the real locations being in or on a wall of the facility.

Embodiment 80: The method of embodiment 79, wherein the one or more asymmetric constraints comprise the virtual locations and/or the real locations being at or near the height of a typical human in or on the wall.

Embodiment 81: The method of embodiment 73, wherein a weight is added to at least one dimension of the virtual distances and/or the real distances.

Embodiment 82: The method of embodiment 73, further comprising measuring the real distances manually.

Embodiment 83: The method of embodiment 73, further comprising measuring the real distances using a drone and/or using a traveler.

Embodiment 84: The method of embodiment 73, further comprising imposing one or more distance constraints on the virtual distances and/or the real distances.

Embodiment 85: The method of embodiment 84, wherein the one or more distance constraints comprise a constraint on not moving more than a specified distance from a reference point.

Embodiment 86: The method of embodiment 84, wherein the one or more distance constraints comprise a constraint on not moving outside of a bounded area.

Embodiment 87: The method of embodiment 73, further comprising using a cost function to provide the solution.

Embodiment 88: The method of embodiment 73, further comprising measuring the real distances using Ultra Wideband (UWB), Global Positioning System (GPS), Radio Frequency Identification (RFID), a communication link that operates in the frequency of from about 2.4 Gigahertz (GHz) to 2.48 GHz radio band, and/or any other geolocation technology.

Embodiment 89: The method of embodiment 88, wherein the geolocation technology may be utilized for industrial, scientific and/or medical applications.

Embodiment 90: The method of embodiment 73, further comprising iteratively correcting the solution to correct for one or more positional errors of one or more of the real distances.

Embodiment 91: The method of embodiment 73, further comprising finding the solution by considering one of the real devices at a time.

Embodiment 92: The method of embodiment 73, further comprising finding the solution by contemporaneously or simultaneously considering the real devices.

Embodiment 93: A non-transitory computer readable program instructions for locating real devices in a facility, which non-transitory computer readable program instructions comprises instructions stored thereon, which when executed by one or more processors operatively couples to a virtual model of the facility, and causes the one or more processors to execute operations comprising: (a) using, or directing usage of, a virtual model of the facility, the virtual model comprising virtual devices disposed in virtual locations in the virtual model of the facility, which virtual locations correspond to planned locations of the real devices in the facility, which virtual devices represent the real devices: (b) identifying, or directing identification of, real distances between real devices installed in the facility; (c) applying, or direct applying, the real distances identified to the virtual locations using a heuristic: and (d) matching, or directing matching, between the virtual locations and a guess of the real locations of the devices at least in part by using the heuristic.

Embodiment 94: The non-transitory computer readable program instructions of embodiment 93, wherein the one or more processors are operatively coupled to geo-location sensors.

Embodiment 95: The non-transitory computer readable program instructions of embodiment 93 or embodiment 94, wherein the one or more processors are operatively coupled to a network to which the real devices are operatively coupled.

Embodiment 96: The non-transitory computer readable program instructions of any of embodiments 93-95, wherein operatively coupled comprises communicatively coupled.

Embodiment 97: The non-transitory computer readable program instructions of embodiment 94, wherein the geo-location sensors comprise Ultra Wideband (UWB) sensors.

Embodiment 98: The non-transitory computer readable program instructions of embodiment 93, wherein at least one of the real devices comprises an Ultra Wideband (UWB) sensor, emitter, or radio.

Embodiment 99: The non-transitory computer readable program instructions of embodiment 93, wherein at least one of the real devices comprises an accelerometer.

Embodiment 100: The non-transitory computer readable program instructions of embodiment 95, wherein the network comprises a cabling system configured to transmit communication and power on one cable.

Embodiment 101: The non-transitory computer readable program instructions of embodiment 95, wherein the network is a local network of the facility.

Embodiment 102: The non-transitory computer readable program instructions of embodiment 93, wherein at least one of the real devices comprises (i) sensors, or (ii) a sensor and an emitter.

Embodiment 103: The non-transitory computer readable program instructions of embodiment 93, wherein the at least one controller is configured to facilitate adjustment of an environment of the facility.

Embodiment 104: The non-transitory computer readable program instructions of embodiment 93, wherein the at least one controller is configured to adjust one or more other device of the facility.

Embodiment 105: The non-transitory computer readable program instructions of embodiment 93, wherein the facility comprises one or more buildings.

Embodiment 106: The non-transitory computer readable program instructions of embodiment 93, wherein the facility comprises one or more enclosures.

Embodiment 107: The non-transitory computer readable program instructions of embodiment 93, wherein the operations comprise using, or directing usage of, the real distances between each of pairs of the real devices identified to compute a real location of the real devices.

Embodiment 108: The non-transitory computer readable program instructions of embodiment 107, wherein the operations further comprise comparing, or directing comparison, among the real device pair distances to identify at least one characteristic real distance.

Embodiment 109: The non-transitory computer readable program instructions of embodiment 108, wherein the at least one characteristic real distance is a longest and/or a shortest distance among the real device pair distances.

Embodiment 110: The non-transitory computer readable program instructions of embodiment 108, wherein the at least one characteristic real distance is a distance that occurs at least two times in the real device pair distances.

Embodiment 111: The non-transitory computer readable program instructions of embodiment 108, wherein the operations further comprise using, or directing usage of, the virtual device pair distances to identify a characteristic virtual distance, and using, or directing usage of, the virtual distances between each of pairs of the virtual devices to compute a real location.

Embodiment 112: The non-transitory computer readable program instructions of embodiment 111, wherein the operations further comprise using, or directing usage of, the virtual device pair distances to identify a characteristic virtual distance.

Embodiment 113: The non-transitory computer readable program instructions of embodiment 112, wherein the operations further comprise using, or directing usage of, the characteristic virtual distance to match a real distance of the real device pair distances with a virtual distance of the virtual device pair distances.

Embodiment 114: The non-transitory computer readable program instructions of embodiment 112, wherein the operations further comprise using, or directing usage of, the characteristic virtual distance to identify a match between (i) two real devices installed in the facility and located at a distance that is precisely or substantially equal to the characteristic virtual distance, and (ii) two virtual devices of the virtual model of the facility that are located at a distance of the characteristic virtual distance.

Embodiment 115: The non-transitory computer readable program instructions of embodiment 93, wherein the program instructions further comprise instructions for being executed automatically without human intervention.

Embodiment 116: The non-transitory computer readable program instructions of embodiment 93, wherein the program instructions further comprise instructions for being executed automatically, with the exception of identifying real locations for the real devices installed in the facility.

Embodiment 117: The non-transitory computer readable program instructions of embodiment 93, wherein the program instructions further comprise instructions for being executed automatically.

Embodiment 118: The non-transitory computer readable program instructions of embodiment 93, wherein the one or more distances between planned locations include at least one identifiable distance between the virtual devices.

Embodiment 119: The non-transitory computer readable program instructions of embodiment 93, wherein the one or more distances of the virtual devices in the virtual model are asymmetric.

Embodiment 120: The non-transitory computer readable program instructions of embodiment 93, wherein the one or more distances are asymmetric and comprise a portion of the virtual model in which the virtual devices are symmetrically located with respect to each other.

Embodiment 121: The non-transitory computer readable program instructions of embodiment 93, wherein the heuristic comprises a computational scheme that utilizes matrices.

Embodiment 122: The non-transitory computer readable program instructions of embodiment 121, wherein the matrices are digital matrices.

Embodiment 123: The non-transitory computer readable program instructions of embodiment 93, wherein the heuristic comprises a computational scheme that includes a combinatorial solution, a discrete solution, recursive computation, mathematical induction, and/or mathematical optimization.

Embodiment 124: The non-transitory computer readable program instructions of embodiment 93, wherein the heuristic comprises a computational scheme including (i) a decision tree, (ii) finding a best solution, (iii) finding an optimal solution, and/or (iv) finding a discrete solution.

Embodiment 125: The non-transitory computer readable program instructions of embodiment 93, wherein the heuristic comprises using a computational scheme that includes computing sub-solutions for providing a solution for matching between the virtual distances and the real distances of the devices by (i) utilizing computational stages each computing the sub-solutions to determine the solution, and (ii) making an optimal choice in each of the computational stages to compute the respective sub-solutions of the solution.

Embodiment 126: The non-transitory computer readable program instructions of embodiment 93, wherein the heuristic comprises a computational scheme for providing a solution for matching between the virtual distances and the real distances of the devices at least in part by making a local best choice for each of a plurality of sub-solutions of the solution.

Embodiment 127: The non-transitory computer readable program instructions of embodiment 93, wherein the heuristic comprises a computational scheme including a candidate set from which the solution is created.

Embodiment 128: The non-transitory computer readable program instructions of embodiment 127, wherein the candidate set identifies real distances for the real devices installed in the facility.

Embodiment 129: The non-transitory computer readable program instructions of embodiment 128, wherein the candidate set comprises a Building Information Modeling file.

Embodiment 130: The non-transitory computer readable program instructions of embodiment 127, wherein the computational scheme includes a selection function for choosing the local best choice for each of the plurality of sub-solutions that are to be added to the solution.

Embodiment 131: The non-transitory computer readable program instructions of embodiment 130, wherein the computational scheme further comprises a feasibility function for determining when a candidate of the candidate set can be used to contribute to the solution.

Embodiment 132: The non-transitory computer readable program instructions of embodiment 131, wherein the computational scheme further comprises an objective function for assigning a value to each of the plurality of sub-solutions.

Embodiment 133: The non-transitory computer readable program instructions of embodiment 132, wherein the computational scheme further comprises an objective function for assigning a value to the solution.

Embodiment 134: The non-transitory computer readable program instructions of embodiment 133, wherein the computational scheme further comprises a solution function for indicating when the solution comprises a complete solution.

Embodiment 135: The non-transitory computer readable program instructions of embodiment 126, wherein the computational scheme further comprises locating a specific signature corresponding to a virtual device of the virtual devices or a real device of the real devices.

Embodiment 136: The non-transitory computer readable program instructions of embodiment 135, wherein the specific signature comprises the virtual device being situated at a relatively large distance from every other device of the virtual devices.

Embodiment 137: The non-transitory computer readable program instructions of embodiment 135, wherein the specific signature comprises the real device being situated at a relatively large distance from every other device of the real devices.

Embodiment 138: The non-transitory computer readable program instructions of embodiment 135, wherein the specific signature comprises the virtual device being centrally located with reference to other virtual devices.

Embodiment 139: The non-transitory computer readable program instructions of embodiment 135, wherein the specific signature comprises the real device being centrally located with reference to other real devices.

Embodiment 140: The non-transitory computer readable program instructions of embodiment 135, wherein the specific signature comprises the virtual device being situated asymmetrically with reference to other one or more virtual devices and/or one or more other real devices.

Embodiment 141: The non-transitory computer readable program instructions of embodiment 135, wherein the specific signature comprises the virtual device being situated symmetrically with reference to one or more other virtual devices and/or one or more other real devices.

Embodiment 142: The non-transitory computer readable program instructions of embodiment 135, wherein the specific signature comprises the virtual device being situated in a recognizable pattern with reference to other one or more virtual devices and/or one or more other real devices.

Embodiment 143: The non-transitory computer readable program instructions of embodiment 135, wherein the specific signature comprises the virtual device being situated to form a numerical series with reference to distances of other virtual devices and/or other real devices.

Embodiment 144: The non-transitory computer readable program instructions of embodiment 143, wherein the numerical series comprises a Fibonacci, square, cubed, telescopic, triangular, geometric, twin, or an arithmetic series.

Embodiment 145: The non-transitory computer readable program instructions of embodiment 126, wherein the computational scheme further comprises using the identified real distances between each of pairs of the real devices to estimate the real device locations, and using the virtual locations of the virtual devices to generate virtual device distances between the each of the pairs.

Embodiment 146: The non-transitory computer readable program instructions of embodiment 145, wherein the computational scheme determines a mathematical distance between all rows of a first matrix of distances representing the virtual device pair distances, and all rows of a second matrix of distances representing the real device pair distances.

Embodiment 147: The non-transitory computer readable program instructions of embodiment 146, wherein the computational scheme finds a first row in the first matrix that is closest to a first row in the second matrix, and maps the first row in the first matrix to the first row in the second matrix.

Embodiment 148: The non-transitory computer readable program instructions of embodiment 147, wherein the computational scheme finds a second row in the first matrix that is closest to a second row in the second matrix, and map the second row in the first matrix to the second row in the second matrix.

Embodiment 149: The non-transitory computer readable program instructions of embodiment 93, wherein the problem-solving heuristic comprises a computational scheme for providing a solution for matching between the virtual distances and the real distances of the devices by performing a systematic enumeration of a set of candidate solutions for the solution.

Embodiment 150: The non-transitory computer readable program instructions of embodiment 149, wherein the computational scheme further comprises representing the set of candidate solutions using a tree structure having a plurality of branches.

Embodiment 151: The non-transitory computer readable program instructions of embodiment 150, wherein the computational scheme further comprises checking a branch of the tree structure against an upper estimated bound for the solution and a lower estimated bound of the branch.

Embodiment 152: The non-transitory computer readable program instructions of embodiment 151, wherein the computational scheme further comprises discarding the branch of the tree structure when the first branch cannot find a better solution than a best solution found so far by the computational scheme.

Embodiment 153: The non-transitory computer readable program instructions of embodiment 150, wherein the computational scheme further comprises partitioning the virtual devices into a plurality of subsets, and analyzing a subset of the plurality of subsets to locate a target solution.

Embodiment 154: The non-transitory computer readable program instructions of embodiment 153, wherein the computational scheme further comprises eliminating the subset when the target solution does not exist in the subset.

Embodiment 155: The non-transitory computer readable program instructions of embodiment 153, wherein the computational scheme further comprises dividing the subset into at least two smaller subsets when the target solution may potentially exist in the subset.

Embodiment 156: The non-transitory computer readable program instructions of embodiment 153, wherein the computational scheme further comprises using binary matrices to represent subsets in the solution space by computing a search space and applying user-recursive algorithms.

Embodiment 157: The non-transitory computer readable program instructions of embodiment 150, wherein the computational scheme further comprises partitioning the solution space into a plurality of subsets, and analyzing a subset of the plurality of subsets to locate a target solution.

Embodiment 158: The non-transitory computer readable program instructions of embodiment 157, wherein the computational scheme further comprises eliminating the subset when the target solution does not exist in the subset.

Embodiment 159: The non-transitory computer readable program instructions of embodiment 157, wherein the computational scheme further comprises dividing the subset into at least two smaller subsets when the target solution may potentially exist in the subset.

Embodiment 160: The non-transitory computer readable program instructions of embodiment 157, wherein the computational scheme further comprises using binary matrices to represent subsets in the solution space by computing a search space and applying user-recursive algorithms.

Embodiment 161: The non-transitory computer readable program instructions of embodiment 150, wherein the computational scheme further comprises formulating an initial guess for a solution.

Embodiment 162: The non-transitory computer readable program instructions of embodiment 161, wherein the computational scheme further comprises partitioning a solution space into a plurality of subsets, and discarding all subsets that have a less accurate approximation for the solution than the initial guess.

Embodiment 163: The non-transitory computer readable program instructions of embodiment 153, wherein the computational scheme further comprises using only target virtual devices that are spaced apart by at least a minimum distance threshold.

Embodiment 164: The non-transitory computer readable program instructions of embodiment 163, wherein the minimum distance threshold is at least nine (9) centimeters.

Embodiment 165: The non-transitory computer readable program instructions of embodiment 157, wherein the computational scheme further comprises using only target real devices that are spaced apart by at least a minimum distance threshold.

Embodiment 166: The non-transitory computer readable program instructions of embodiment 165, wherein the minimum distance threshold is at least nine (9) centimeters.

Embodiment 167: The non-transitory computer readable program instructions of embodiment 93, wherein the heuristic comprises a combination of a first computational scheme and a second computational scheme, the combination providing a solution for matching between the virtual distances and the real distances of the devices by making a local best choice for each of a plurality of sub-solutions of the solution, and performing a systematic enumeration of a set of candidate solutions for the solution.

Embodiment 168: The non-transitory computer readable program instructions of embodiment 167, wherein the heuristic further comprises updating the real distances for the real devices one at a time.

Embodiment 169: The non-transitory computer readable program instructions of embodiment 167, wherein the heuristic further comprises imposing one or more asymmetric constraints on the virtual locations and/or the real locations.

Embodiment 170: The non-transitory computer readable program instructions of embodiment 169, wherein the one or more asymmetric constraints comprise the virtual locations and/or the real locations being in or on a ceiling of the facility.

Embodiment 171: The non-transitory computer readable program instructions of embodiment 169, wherein the one or more asymmetric constraints comprise the virtual locations and/or the real locations being in or on a wall of the facility.

Embodiment 172: The non-transitory computer readable program instructions of embodiment 171, wherein the one or more asymmetric constraints comprise the virtual locations and/or the real locations being at or near the height of a typical human in or on the wall.

Embodiment 173: The non-transitory computer readable program instructions of embodiment 167, wherein a weight is added to at least one dimension of the virtual distances and/or the real distances.

Embodiment 174: The non-transitory computer readable program instructions of embodiment 167, wherein the heuristic further comprises measuring the real locations manually.

Embodiment 175: The non-transitory computer readable program instructions of embodiment 167, wherein the heuristic further comprises measuring the real locations using a drone and/or using a traveler.

Embodiment 176: The non-transitory computer readable program instructions of embodiment 167, wherein the heuristic further comprises imposing one or more distance constraints on the virtual distances and/or the real distances.

Embodiment 177: The non-transitory computer readable program instructions of embodiment 176, wherein the one or more distance constraints comprise a constraint on not moving more than a specified distance from a reference point.

Embodiment 178: The non-transitory computer readable program instructions of embodiment 176, wherein the one or more distance constraints comprise a constraint on not moving outside of a bounded area.

Embodiment 179: The non-transitory computer readable program instructions of embodiment 167, wherein the heuristic further comprises using a cost function to provide the solution.

Embodiment 180: The non-transitory computer readable program instructions of embodiment 167, wherein the heuristic further comprises measuring the real distances using any of Ultra Wideband (UWB), Bluetooth, a communication link that operates in the frequency of from about 2.4 Gigahertz (GHz) to 2.48 GHz radio band, Global Positioning System (GPS), RFID, and/or geolocation technology.

Embodiment 181: The non-transitory computer readable program instructions of embodiment 167, wherein the heuristic further comprises iteratively correcting the solution to correct for positional errors of the real locations.

Embodiment 182: The non-transitory computer readable program instructions of embodiment 167, wherein the heuristic further comprises finding the solution by considering one of the real devices at a time.

Embodiment 183: The non-transitory computer readable program instructions of embodiment 167, wherein the heuristic further comprises finding the solution by contemporaneously or simultaneously considering all of the real devices.

Embodiment 184: An apparatus for locating real devices in a facility, the apparatus comprising at least one controller having circuitry, wherein the at least one controller is configured to: (a) operatively couple to a virtual model of the facility: (b) use, or direct usage of, a virtual model of the facility, the virtual model comprising virtual devices disposed in virtual locations in the virtual model of the facility, which virtual locations correspond to planned locations of the real devices in the facility, which virtual devices represent the real devices: (c) identify, or direct identification of, real distances of the devices installed in the facility: (d) apply, or direct application of, the real distances identified to the virtual locations using a heuristic; and (e) match, or direct matching, between the virtual locations and a guess of the real locations of the devices at least in part by using the heuristic.

Embodiment 185: The apparatus of embodiment 184, wherein the at least one controller is configured to operatively couple to geo-location sensors.

Embodiment 186: The apparatus of embodiment 184, wherein the at least one controller is configured to operatively couple to a network to which the real devices are operatively coupled.

Embodiment 187: The apparatus of embodiment 184, wherein operatively couple comprises communicatively couple.

Embodiment 188: The apparatus of embodiment 185, wherein the geo-location sensors comprise Ultra Wideband (UWB) sensors.

Embodiment 189: The apparatus of embodiment 184, wherein at least one of the real devices comprises an Ultra Wideband (UWB) sensor, emitter, or radio.

Embodiment 190: The apparatus of embodiment 184, wherein at least one of the real devices comprises an accelerometer.

Embodiment 191: The apparatus of embodiment 186, wherein the network comprises a cabling system configured to transmit communication and power on one cable.

Embodiment 192: The apparatus of embodiment 186, wherein the network is a local network of the facility.

Embodiment 193: The apparatus of embodiment 184, wherein at least one of the real devices comprises (i) sensors, or (ii) a sensor and an emitter.

Embodiment 194: The apparatus of embodiment 184, wherein the at least one controller is configured to facilitate adjustment of an environment of the facility.

Embodiment 195: The apparatus of embodiment 184, wherein the at least one controller is configured to adjust, or direct adjustment of, one or more other device of the facility.

Embodiment 196: The apparatus of embodiment 184, wherein the facility comprises one or more buildings.

Embodiment 197: The apparatus of embodiment 184, wherein the facility comprises one or more enclosures.

Embodiment 198: The apparatus of embodiment 184, wherein the at least one controller is further configured to use, or direct usage of, the real distances between each of pairs of the real devices to generate real device locations.

Embodiment 199: The apparatus of embodiment 198, wherein the at least one controller is further configured to compare, or direct comparison, among the real device pair distances to identify a characteristic real distance.

Embodiment 200: The apparatus of embodiment 199, wherein the characteristic real distance is a longest or a shortest distance among the real device pair distances.

Embodiment 201: The apparatus of embodiment 199, wherein the characteristic real distance is a distance that occurs at least two times in the real device pair distances.

Embodiment 202: The apparatus of embodiment 199, wherein the at least one controller is configured to use, or direct usage of, the virtual locations to compute a virtual distance between each of pairs of the virtual devices.

Embodiment 203: The apparatus of embodiment 202, wherein the at least one controller is configured to use, or direct usage of, the virtual device pair distances to identify a characteristic virtual distance.

Embodiment 204: The apparatus of embodiment 203, wherein the at least one controller is configured to use, or direct usage of, the characteristic virtual distance to match a real distance of the real device pair distances with a virtual distance of the virtual device pair distances.

Embodiment 205: The apparatus of embodiment 203, wherein the at least one controller is configured to use, or direct usage of, the characteristic virtual distance to identify a match between (i) two real devices installed in the facility and located at a distance that is precisely or substantially equal to the characteristic virtual distance, and (ii) two virtual devices of the virtual model of the facility that are located at a distance of the characteristic virtual distance.

Embodiment 206: The apparatus of embodiment 184, further comprising instructions for being executed automatically without human intervention.

Embodiment 207: The apparatus of embodiment 184, wherein location and/or distance identification of the real devices in a facility is performed automatically, with the exception of identifying real locations for the real devices installed in the facility.

Embodiment 208: The apparatus of embodiment 184, wherein location and/or distance identification of the real devices in a facility is performed automatically.

Embodiment 209: The apparatus of embodiment 184, wherein the at least one controller is configured to locate, or direct location of, the real devices in a facility automatically, with the exception of identifying real locations for the real devices installed in the facility.

Embodiment 210: The apparatus of embodiment 184, wherein the at least one controller is configured to locate, or direct location of, the real devices in a facility automatically.

Embodiment 211: The apparatus of embodiment 184, wherein the planned distances include at least one identifiable distance between the virtual devices.

Embodiment 212: The apparatus of embodiment 184, wherein the planned distances of the virtual devices in the virtual model are asymmetric.

Embodiment 213: The apparatus of embodiment 184, wherein the planned distances of the virtual devices in the virtual model are asymmetric and comprise a portion of the virtual model in which the virtual devices are symmetrically located with respect to each other.

Embodiment 214: The apparatus of embodiment 184, wherein the heuristic comprises a computational scheme that utilizes matrices.

Embodiment 215: The apparatus of embodiment 214, wherein the matrices are digital matrices.

Embodiment 216: The apparatus of embodiment 184, wherein the heuristic comprises a computational scheme that includes a combinatorial solution, a discrete solution, recursive computation, mathematical induction, and/or mathematical optimization.

Embodiment 217: The apparatus of embodiment 184, wherein the heuristic comprises a computational scheme including (i) a decision tree, (ii) finding a best solution, (iii) finding an optimal solution, and/or (iv) finding a discrete solution.

Embodiment 218: The apparatus of embodiment 184, wherein the heuristic comprises using a computational scheme that includes computing sub-solutions for providing a solution for matching between the virtual distances and the real distances of the devices by (i) utilizing computational stages each computing the sub-solutions to determine the solution, and (ii) making an optimal choice in each of the computational stages to compute the respective sub-solutions of the solution.

Embodiment 219: The apparatus of embodiment 184, wherein the heuristic comprises a computational scheme for providing a solution for matching between the virtual distances and the real distances of the devices by making a local best choice for each of a plurality of sub-solutions of the solution.

Embodiment 220: The apparatus of embodiment 184, wherein the heuristic comprises a computational scheme including a candidate set from which the solution is created.

Embodiment 221: The apparatus of embodiment 220, wherein the candidate set identifies real distances for the real devices installed in the facility.

Embodiment 222: The apparatus of embodiment 221, wherein the candidate set comprises a Building Information Modeling file.

Embodiment 223: The apparatus of embodiment 218, wherein the computational scheme includes a selection function for choosing the local best choice for each of the plurality of sub-solutions that are to be added to the solution.

Embodiment 224: The apparatus of embodiment 223, wherein the computational scheme further comprises a feasibility function for determining when a candidate of the candidate set can be used to contribute to the solution.

Embodiment 225: The apparatus of embodiment 224, wherein the computational scheme further comprises an objective function for assigning a value to each of the plurality of sub-solutions.

Embodiment 226: The apparatus of embodiment 225, wherein the computational scheme further comprises an objective function for assigning a value to the solution.

Embodiment 227: The apparatus of embodiment 226, wherein the computational scheme further comprises a solution function for indicating when the solution comprises a complete solution.

Embodiment 228: The apparatus of embodiment 214, wherein the at least one controller is configured to locate, or direct locating of, a specific signature corresponding to a virtual device of the virtual devices or a real device of the real devices.

Embodiment 229: The apparatus of embodiment 228, wherein the specific signature comprises the virtual device being situated at a relatively large distance from every other device of the virtual devices.

Embodiment 230: The apparatus of embodiment 228, wherein the specific signature comprises the real device being situated at a relatively large distance from every other device of the real devices.

Embodiment 231: The apparatus of embodiment 228, wherein the specific signature comprises the virtual device being centrally located with reference to other virtual devices.

Embodiment 232: The apparatus of embodiment 228, wherein the specific signature comprises the real device being centrally located with reference to other real devices.

Embodiment 233: The apparatus of embodiment 228, wherein the specific signature comprises the virtual device being situated asymmetrically with reference to at least one other virtual devices and/or at least one other real devices.

Embodiment 234: The apparatus of embodiment 228, wherein the specific signature comprises the virtual device being situated symmetrically with reference to other virtual devices and/or other real devices.

Embodiment 235: The apparatus of embodiment 228, wherein the specific signature comprises the virtual device being situated in a recognizable pattern with reference to one or more other virtual devices and/or one or more other real devices.

Embodiment 236: The apparatus of embodiment 228, wherein the specific signature comprises the virtual device being situated to form a numerical series with reference to distances of other virtual devices and/or other real devices.

Embodiment 237: The apparatus of embodiment 236, wherein the numerical series comprises a Fibonacci, square, cubed, telescopic, triangular, geometric, twin, or an arithmetic series.

Embodiment 238: The apparatus of embodiment 214, wherein the at least one controller is configured to use, or direct usage of, the identified real distances between each of pairs of the real devices to compute real locations, and to use, or direct usage of, the virtual locations to compute virtual distances between each of pairs of the virtual devices.

Embodiment 239: The apparatus of embodiment 238, wherein the heuristic determines a mathematical location in rows of a first matrix corresponding to distances representing the virtual device pair distances, and all rows of a second matrix of locations corresponding to the real device pair distances.

Embodiment 240: The apparatus of embodiment 239, wherein the heuristic finds a first row in the first matrix that is closest to a first row in the second matrix, and maps the first row in the first matrix to the first row in the second matrix.

Embodiment 241: The apparatus of embodiment 240, wherein the heuristic finds a second row in the first matrix that is closest to a second row in the second matrix, and maps the second row in the first matrix to the second row in the second matrix.

Embodiment 242: The apparatus of embodiment 184, wherein the heuristic comprises a computational scheme for providing a solution for matching between the virtual distances and the real distances of the devices by performing a systematic enumeration of a set of candidate solutions for the solution.

Embodiment 243: The apparatus of embodiment 242, wherein the at least one controller is configured to represent, or direct representation of, the set of candidate solutions using a tree structure having a plurality of branches.

Embodiment 244: The apparatus of embodiment 243, wherein the at least one controller is configured to check, or direct checking of, a branch of the tree structure against an upper estimated bound for the solution and a lower estimated bound of the branch.

Embodiment 245: The apparatus of embodiment 244, wherein the at least one controller is configured to discard, or direct discarding of, the branch of the tree structure when the first branch cannot find a better solution than a best solution found so far by the computational scheme.

Embodiment 246: The apparatus of embodiment 243, wherein the at least one controller is configured to: (i) partition, or direct partitioning of, the virtual devices into a plurality of subsets, and analyze, or (ii) direct analysis of, a subset of the plurality of subsets to locate a target solution.

Embodiment 247: The apparatus of embodiment 246, wherein the at least one controller is configured to eliminate, or direct elimination of, the subset when the target solution does not exist in the subset.

Embodiment 248: The apparatus of embodiment 246, wherein the at least one controller is configured to divide, or direct division of, the subset into at least two smaller subsets when the target solution may potentially exist in the subset.

Embodiment 249: The apparatus of embodiment 246, wherein the at least one controller is configured to use, or direct usage of, binary matrices to represent subsets of the solution space at least in part by computing a search space and applying user-recursive algorithms.

Embodiment 250: The apparatus of embodiment 243, wherein the at least one controller is configured to: (i) partition, or directing partitioning of, the real devices into a plurality of subsets, and (ii) analyze, or direct analysis of, a subset of the plurality of subsets to locate a target solution.

Embodiment 251: The apparatus of embodiment 250, wherein the at least one controller is configured to eliminate, or direct elimination of, the subset when the target solution does not exist in the subset.

Embodiment 252: The apparatus of embodiment 250, wherein the at least one controller is configured to divide, or direct dividing of, the subset into at least two smaller subsets when the solution may potentially exist in the subset.

Embodiment 253: The apparatus of embodiment 250, wherein the at least one controller is configured to use, or direct usage of, binary matrices to represent the solution subsets by computing a search space and applying user-recursive algorithms.

Embodiment 254: The apparatus of embodiment 243, wherein the at least one controller is configured to formulate, or direct formulating, an initial guess for a solution.

Embodiment 255: The apparatus of embodiment 254, wherein the at least one controller is configured to partition, or direct partitioning, a solution space into a plurality of subsets, and discard all subsets that have a less accurate approximation for the solution than the initial guess.

Embodiment 256: The apparatus of embodiment 246, wherein the at least one controller is configured to use, or direct usage of, target virtual devices that are spaced apart by at least a minimum distance threshold.

Embodiment 257: The apparatus of embodiment 256, wherein the minimum distance threshold is at least nine (9) centimeters.

Embodiment 258: The apparatus of embodiment 250, wherein the at least one controller is configured to use, or direct usage of, only target real devices that are spaced apart by at least a minimum distance threshold.

Embodiment 259: The apparatus of embodiment 258, wherein the minimum distance threshold is at least nine (9) centimeters.

Embodiment 260: The apparatus of embodiment 184, wherein the heuristic comprises a combination of a first computational scheme and a second computational scheme, the combination providing a solution for matching between the virtual distances and the real distances of the devices by making a local best choice for each of a plurality of sub-solutions of the solution, and performing a systematic enumeration of a set of candidate solutions for the solution.

Embodiment 261: The apparatus of embodiment 260, wherein the at least one controller is configured to update, or direct updating of, the real distances for the real devices one at a time.

Embodiment 262: The apparatus of embodiment 260, wherein the at least one controller is configured to impose, or direct imposition of, one or more asymmetric constraints on the virtual locations and/or the real locations.

Embodiment 263: The apparatus of embodiment 262, wherein the one or more asymmetric constraints comprise the virtual locations and/or the real locations being in or on a ceiling of the facility.

Embodiment 264: The apparatus of embodiment 262, wherein the one or more asymmetric constraints comprise the virtual locations and/or the real locations being in or on a wall of the facility.

Embodiment 265: The apparatus of embodiment 264, wherein the one or more asymmetric constraints comprise the virtual locations and/or the real locations being at or near the height of a typical human in or on the wall.

Embodiment 266: The apparatus of embodiment 260, wherein a weight is added to at least one dimension of the virtual locations and/or the real locations.

Embodiment 267: The apparatus of embodiment 260, wherein the at least one controller is configured to measure, or direct measurement of, the real locations manually.

Embodiment 268: The apparatus of embodiment 260, wherein the at least one controller is configured to measure, or direct measurement of, the real locations and/or real distances using a drone and/or using a traveler.

Embodiment 269: The apparatus of embodiment 260, wherein the at least one controller is configured to impose, or direct imposition of, one or more distance constraints on the virtual distances and/or the real distances.

Embodiment 270: The apparatus of embodiment 269, wherein the one or more distance constraints comprise a constraint on not moving more than a specified distance from a reference point.

Embodiment 271: The apparatus of embodiment 269, wherein the one or more distance constraints comprise a constraint on not moving outside of a bounded area.

Embodiment 272: The apparatus of embodiment 260, wherein the at least one controller is configured to use, or direct usage of, a cost function to provide the solution.

Embodiment 273: The apparatus of embodiment 260, wherein the at least one controller is configured to measure, or direct measurement of, the real locations and/or real distances using any of UltraWideband (UWB), Bluetooth, a communication link that operates in the 2.4-GHz Industrial, Scientific, and Medical (ISM) radio band, Global Positioning System (GPS), RFID, and/or geolocation technology.

Embodiment 274: The apparatus of embodiment 260, wherein the at least one controller is configured to iteratively correct, or direct iterative correction of, the solution to correct for positional errors of the real locations.

Embodiment 275: The apparatus of embodiment 260, wherein the at least one controller is configured to find, or direct finding of, the solution by considering one of the real devices at a time.

Embodiment 276: The apparatus of embodiment 260, wherein the at least one controller is configured to find, or direct finding of, the solution by contemporaneously or simultaneously considering all of the real devices.

While preferred embodiments of the present invention have been shown, and described herein, it will be obvious to those skilled in the art that such embodiments are provided by way of example only. It is not intended that the invention be limited by the specific examples provided within the specification. While the invention has been described with reference to the afore-mentioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations, or relative proportions set forth herein which depend upon a variety of conditions and variables. It should be understood that various alternatives to the embodiments of the invention described herein might be employed in practicing the invention. It is therefore contemplated that the invention shall also cover any such alternatives, modifications, variations, or equivalents. It is intended that the following claims define the scope of the invention and that methods and structures within the scope of these claims and their equivalents be covered thereby.

1. A method of locating devices installed in a facility, the method comprising:
a process (A), the process (A) including measuring signal-to-interference-plus-noise ratio (SINR) for signals received from each device and using the measured SINR to determine a relative location of each of the devices;
a process (B), the process (B) including transmitting an incident signal onto a network comprising the devices and analyzing reflections of that signal from each of the devices using time domain reflectometry (TDR) and using the analyzed reflections to determine the relative location of each of the devices; and/or
a process (C), the process (C) including (i) using a virtual model of the facility, the virtual model comprising virtual devices disposed in virtual locations corresponding to planned locations of the devices in the facility, wherein each virtual device corresponds to a respective installed device; (ii) identifying actual distances between one or more pairs of installed devices; (iii) comparing the actual distances identified to the virtual locations using a heuristic; and (iv) matching between the virtual locations and an estimate of real locations of the devices at least in part by using the heuristic.

2. The method of claim 1, wherein one or more of the devices is a window controller for a tintable window.

3. The method of claim 2, further comprising determining differences between an as-built arrangement of at least a portion of the network with an as-designed arrangement of the portion of the network.

4. The method of claim 3, wherein the determining differences includes using network diagnostics available from the window controller.

5. The method of claim 1, wherein the method includes process (C) and one or both of process (A) and/or process (B).

6. The method of claim 5, wherein the signals received from each device are received by way of a trunk line that couples each device in a network.

7. The method of claim 5, further comprising:
using virtual device pair distances to identify a characteristic virtual distance and
utilizing the characteristic virtual distance to identify a match between (i) two real devices located at a distance that is precisely or substantially equal to the characteristic virtual distance, and (ii) two virtual devices located at a distance of the characteristic virtual distance.

8. The method of claim 5, further comprising using the actual distances identified between each pair of the installed devices to calculate real locations of each pair of the installed devices.

9. The method of claim 5, wherein the heuristic comprises:
a computation scheme utilizing digital matrices; and/or
a computational scheme that includes a combinatorial solution, a discrete solution, recursive computation, mathematical induction, mathematical optimization, and/or a decision tree; and/or
using a computational scheme that includes computing sub-solutions for providing a solution for matching between the virtual distances and the actual distances of the devices by (i) utilizing computational stages each computing the sub-solutions to determine the solution, and (ii) making an optimal choice in each of the computational stages to compute a corresponding sub-solution of the solution; and/or
a combination of computational schemes, the combination providing a solution for matching between the virtual locations and the actual distances of the devices by making a local best choice for each of a plurality of sub-solutions of the solution.

10. (canceled)

11. The method of claim 5, wherein the heuristic comprises using a computational scheme that includes computing sub-solutions for providing a solution for matching between the virtual distances and the actual distances of the devices by (i) utilizing computational stages each computing the sub-solutions to determine the solution, and (ii) making an optimal choice in each of the computational stages to compute a corresponding sub-solution of the solution.

12. The method of claim 11, wherein the computational scheme includes;
a candidate set from which the solution is created, the candidate set comprising Building Information Modeling data; and/or
providing a solution for matching between the virtual locations and the actual distances of the devices, the providing a solution including representing a set of candidate solutions using a decision tree structure having a plurality of branches comprising a solution space.

13-15. (canceled)

16. The method of claim 1, further comprising measuring the actual distances using Ultra Wideband (UWB), Global Positioning System (GPS), Radio Frequency Identification (RFID), a communication link that operates in the frequency of from about 2.4 Gigahertz (GHz) to 2.48 GHz radio band, and/or any other geolocation technology.

17. The method of claim 1, wherein the method includes one or both of process (A) and/or process (B).

18. The method of claim 17, wherein the devices are communicatively coupled by a network with a control panel or network controller, the network comprising a trunk line that couples the control panel and/or the network controller with each device.

19. The method of claim 18, wherein the method includes process (A) and process (B).

20. The method of claim 1, wherein the facility comprises one or more buildings.

21. A system for locating devices installed in a facility, the system comprising a plurality of devices within a network and a processor configured to:
control, or direct control of, a process (A), the process (A) including measuring signal-to-interference-plus-noise ratio (SINR) for signals received from each device and using the measured SINR to determine a relative location of each of the devices;
control, or direct control of, a process (B), the process (B) including transmitting an incident signal onto a network comprising the devices and analyzing reflections of that signal from each of the devices using time domain reflectometry (TDR) and using the analyzed reflections to determine the relative location of each of the devices; and/or
control, or direct control of, a process (C), the process (C) including (i) using a virtual model of the facility, the virtual model comprising virtual devices disposed in virtual locations corresponding to planned locations of the devices in the facility, wherein each virtual device corresponds to a respective installed device; (ii) identifying actual distances between one or more pairs of installed devices; (iii) comparing the actual distances identified to the virtual locations using a heuristic; and (iv) matching between the virtual locations and an estimate of the locations of the devices at least in part by using the heuristic.

22. The system of claim 21, wherein one or more of the plurality of devices is a window controller for a tintable window.

23. (canceled)

24. The system of claim 21, wherein the processor is configured to control, or direct control of, process (C) and one or both of process (A) and/or process (B).

25. The system of claim 24, wherein the processor is further configured to use virtual device pair distances to identify a characteristic virtual distance and to utilize the characteristic virtual distance to identify a match between (i) two real devices located at a distance that is precisely or substantially equal to the characteristic virtual distance, and (ii) two virtual devices located at a distance of the characteristic virtual distance.

26-27. (canceled)

28. The system of claim 24, wherein the heuristic comprises using a computational scheme that includes computing sub-solutions for providing a solution for matching between the virtual distances and the actual distances of the devices by (i) utilizing computational stages each computing the sub-solutions to determine the solution, and (ii) making an optimal choice in each of the computational stages to compute a corresponding sub-solution of the solution.

29. The system of claim 28, wherein the computational scheme includes one or both of:
a feasibility function for determining when a candidate of the candidate set can be used to contribute to the solution and/or
an objective function for assigning a value to each of the sub-solutions.

30. The system of claim 24, wherein:
the processor is further configured to locate a specific signature corresponding to a respective one of the virtual devices; and
the specific signature comprises the respective one of the virtual devices being situated to form a numerical series with reference to distances of one or more other virtual devices and/or one or more other real devices; and
the numerical series comprises a Fibonacci, square, cubed, telescopic, triangular, geometric, twin, or an arithmetic series.

31-32. (canceled)

33. The system of claim 21, wherein the processor is configured to control, or direct control of, one or both of process (A) and/or process (B).

34. The system of claim 21, wherein the processor is configured to control, or direct control or, process (A) and process (B).

35. An apparatus for locating devices in a facility, the apparatus comprising at least one controller having circuitry, wherein the at least one controller is configured to:
control, or direct control of, a process (A), the process (A) including measuring signal-to-interference-plus-noise ratio (SINR) for signals received from each device and using the measured SINR to determine a relative location of each of the devices;
control, or direct control of, a process (B), the process (B) including transmitting an incident signal onto a network comprising the devices and analyzing reflections of that signal from each of the devices using time domain reflectometry (TDR) and using the analyzed reflections to determine the relative location of each of the devices; and/or
control, or direct control of, a process (C), the process (C) including (i) using a virtual model of the facility, the virtual model comprising virtual devices disposed in virtual locations corresponding to planned locations of the devices in the facility, wherein each virtual device corresponds to a respective installed device; (ii) identifying actual distances between one or more pairs of installed devices; (iii) comparing the actual distances identified to the virtual locations using a heuristic; and (iv) matching between the virtual locations and an estimate of real locations of the devices at least in part by using the heuristic.

36. The apparatus of claim 35, wherein one or more of the devices is a window controller for a tintable window.

37. (canceled)

38. The apparatus of claim 35, wherein the at least one controller is configured to control, or direct control of, process (C) and one or both of process (A) and/or process (B).

39-41. (canceled)

42. The apparatus of claim 35, wherein the at least one controller is further configured to control, or direct control of, one or both of process (A) and/or process (B).

43. The apparatus of claim 35, wherein the at least one controller is further configured to control, or direct control of, process (A) and process (B).

44-49. (canceled)
